(19) United States
(12) Patent Application Publication
(10) Pub. No.: US 2022/0013733 A1
(43) Pub. Date: Jan. 13, 2022

(54) WHITE OLEDS EMPLOYING BLUE FLUORESCENT EMITTERS AND ORANGE PHOSPHORESCENT EXCIMERS

(71) Applicant: ARIZONA BOARD OF REGENTS ON BEHALF OF ARIZONA STATE UNIVERSITY, Scottsdale, AZ (US)

(72) Inventor: Jian Li, Tempe, AZ (US)

(21) Appl. No.: 17/347,716

(22) Filed: Jun. 15, 2021

Related U.S. Application Data
(60) Provisional application No. 63/039,787, filed on Jun. 16, 2020.

(51) Int. Cl. H01L 51/00; C09K 11/06

(52) U.S. Cl. CPC H01L 51/0084; H01L 51/5056; H01L 51/008; C09K 11/06

(57) ABSTRACT

A white organic light emitting device comprises a first electrode; a hole transporting layer in contact with the first electrode; a second electrode; an electron transporting layer in contact with the second electrode; and an emissive layer between the hole transporting layer and the electron transporting layer. The emissive layer comprises a host, a fluorescent emitter, and a phosphorescent emitter. The fluorescent emitter harvests singlet excitons and emits blue light, and the phosphorescent emitter harvests triplet excitons and emits yellow-amber light.

### CROSS-REFERENCE TO RELATED APPLICATIONS

The present application claims priority under 35 U.S.C. § 119(e) to U.S. Provisional Application No. 63/039,787, filed Jun. 16, 2020, which is incorporated by reference herein in its entirety. the invention.

### STATEMENT REGARDING FEDERALLY SPONSORED RESEARCH OR DEVELOPMENT

This invention was made with government support under Grant No. EE0008721 awarded by the U.S. Department of Energy. The government has certain rights in

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

In recent years, organic light emitting diodes (OLEDs) have attracted great attention from both academic and industrial areas due to their outstanding merits, like high color quality, wide-viewing angle, low cost fabrication, low power consumption, fast respond speed and high electron to photon conversion efficiency. Most of the organic light emitting diodes (OLEDs) are phosphorescent OLEDs using Iridium (Ir), palladium (Pd) and platinum (Pt) complexes, as these metal complexes have strong Spin-Orbital Coupling, they can efficiently emit light from their triplet exited state and reach nearly 100% internal efficiency.

The development of efficient white OLED can have significant applications for general lighting purpose. However, the current short operational lifetime of blue phosphorescent emitters will limit the overall performance of white OLED consisting of all phosphorescent emitters.

There remains a need in the art for efficient and stable white organic light-emitting diodes. This invention addresses this unmet need.

### SUMMARY OF THE INVENTION

In one aspect, the present disclosure relates to a white organic light emitting device comprising: a first electrode; a hole transporting layer in contact with the first electrode; a second electrode; an electron transporting layer in contact with the second electrode; and an emissive layer between the hole transporting layer and the electron transporting layer, the emissive layer comprising a host, a fluorescent emitter, and a phosphorescent emitter, wherein the fluorescent emitter harvests singlet excitons and emits blue light and wherein the phosphorescent emitter harvests triplet excitons and emits yellow-amber light.

In one embodiment, the phosphorescent emitter is a compound of General Formula I:

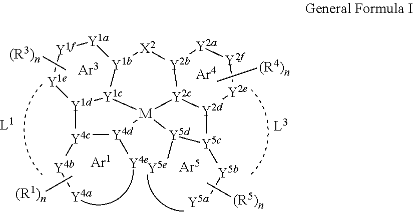

wherein, in General Formula I:

M represents Pt(II) or Pd(II);

R¹, R³, R⁴, and R⁵ each independently represents hydrogen, halogen, hydroxyl, nitro, cyanide, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;

X² represents NR, PR, CRR′, SiRR′, CRR′, SiRR′, O, S, S═O, O=S═O, Se, Se═O, or O=Se═O, wherein R and R′ each independently represents hydrogen, halogen, hydroxyl, nitro, cyanide, thiol, or optionally substituted C₁-C₄ alkyl, alkoxy, amino, aryl, or heteroaryl;

each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;

Ar³ and Ar⁴ each independently represents a 6-membered aryl group; and

Ar¹ and Ar⁵ each independently represents a 5- to 10-membered aryl, heteroaryl, fused aryl, or fused heteroaryl.

### BRIEF DESCRIPTION OF THE DRAWINGS

The following detailed description of preferred embodiments of the disclosure will be better understood when read in conjunction with the appended drawings. For the purpose of illustrating the invention, there are shown in the drawings embodiments which are presently preferred. It should be understood, however, that the invention is not limited to the precise arrangements and instrumentalities of the embodiments shown in the drawings.

FIG. 1 is a schematic diagram of an organic light emitting device.

FIG. 2 is a schematic energy diagram for an exemplary white OLED employing blue fluorescent emitters and orange phosphorescent excimers.

FIG. 3 is a plot of current density vs voltage for Device 1, where the device active area is 2×2 mm.

FIG. 4 is a plot of EL spectra before and after lifetime testing for Device 1, where the device active area is 2×2 mm.

FIG. 5 is a plot of EQE vs luminance for Device 1, where the device active area is 2×2 mm.

FIG. 6 is a plot of the electroluminescence (EL) spectra for Devices 2 and 3.

FIG. 7 is a plot of EQE vs Luminance for Devices 2 and 3.

FIG. 8 is a plot of relative luminance versus operation time at a current density of 20 mA cm⁻² for Devices 2 and 3.

FIG. 9 is a plot of EQE vs Luminance for Devices 1-3.

FIG. 10 is a plot of EL spectra for Devices 1-3.

FIG. 11 is a plot of normalized EL intensity vs device operational time at the constant current of 20 mA cm⁻² for Devices 1-3.

FIG. 12 is a plot of EL spectra at driving currents of 1-10 mA cm⁻² for Device 1.

FIG. 13 is a plot of EL spectra at driving currents of 1-10 mA cm⁻² for Device 2.

FIG. 14 is a plot of EL spectra at driving currents of 1-10 mA cm⁻² for Device 3.

FIG. 15 is a plot of Electroluminescent (EL) spectra at 1 mA/cm² for Devices 1-5.

FIG. 16 shows an energy level diagram and proposed charge carrier distribution in the EML and EBL layers for Devices 1, 3, and 4.

FIG. 17 is a plot of EQE vs Luminance for devices having and lacking a 20 nm BH2 layer.

FIG. 18 is a plot of EL spectra, for devices having and lacking a 20 nm BH2 layer.

### DETAILED DESCRIPTION

The present disclosure relates in part to the unexpected discovery that an efficient white OLED can be constructed in which a blue fluorescent emitter harvests singlet excitons and an orange phosphorescent emitter harvests triplet excitons.

### Definitions

It is to be understood that the figures and descriptions in the present disclosure have been simplified to illustrate elements that are relevant for a clear understanding of the present invention, while eliminating, for the purpose of clarity, many other elements found in the art related to phosphorescent organic light emitting devices and the like. Those of ordinary skill in the art may recognize that other elements and/or steps are desirable and/or required in implementing the disclosed embodiments. However, because such elements and steps are well known in the art, and because they do not facilitate a better understanding of the present disclosure, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this disclosure belongs. Although any methods, materials and components similar or equivalent to those described herein can be used in the practice or testing of the disclosed embodiments, the preferred methods, and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, or ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

As referred to herein, a linking atom or a linking group can connect two groups such as, for example, an N and C group. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include, but are not limited to, hydrogen, hydroxyl, alkyl, alkoxy, ═O, halogen, nitro, amine, amide, thiol, aryl, heteroaryl, cycloalkyl, and heterocyclyl.

The term “cyclic structure” or the like terms used herein refer to any cyclic chemical structure which includes, but is not limited to, aryl, heteroaryl, cycloalkyl, cycloalkenyl, and heterocyclyl.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbomyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula —(CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA¹ where A¹ is alkyl or cycloalkyl as defined above. “Alkoxy” also includes polymers of alkoxy groups as just described; that is, an alkoxy can be a poly ether such as —OA¹-OA² or —OA¹-(OA²)ₐ-OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C═C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bond, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbomenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “aldehyde” as used herein is represented by the formula —C(O)H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula-NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butyl)amino group, pentylamino group, isopentylamino group, (tert-pentyl)amino group, hexylamino group, and the like.

The term “dialkylamino” as used herein is represented by the formula-N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula-C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula-(A¹O(O)C-A²-C(O)O), or -(A¹O(O)C-A²-OC(O))ₐ—, where A¹ and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of poly ether groups include polyethylene oxide, polypropylene oxide, and polybutylene oxide.

The term “halide” as used herein refers to the halogens fluorine, chlorine, bromine, and iodine.

The term “heterocyclyl,” as used herein refers to single and multi-cyclic non-aromatic ring systems and “heteroaryl” as used herein refers to single and multi-cyclic aromatic ring systems: in which at least one of the ring members is other than carbon. The term “heterocyclyl” includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula-OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula-N3.

The term “nitro” as used herein is represented by the formula —NO₂.

The term “nitrile” as used herein is represented by the formula-CN.

The term “ureido” as used herein refers to a urea group of the formula-NHC(O)NH₂ or —NHC(O)NH—.

The term “phosphoramide” as used herein refers to a group of the formula —P(O)(NA¹A²)₂, where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “carbamoyl” as used herein refers to an amide group of the formula —CONA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “sulfamoyl” as used herein refers to a group of the formula-S(O)₂NA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “silyl” as used herein is represented by the formula-SiA1A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas-S(O)A¹, —S(O)₂A¹, —OS(O)₂A¹, or —OS(O)₂OA¹, where A¹ is hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ is hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)₂A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A¹S(O)A², where A¹ and A² can be, independently, an alkyl, cycloalkyl, alkenyl, cycloalkenyl, alkynyl, cycloalkynyl, aryl, or heteroaryl group as described herein.

The term “thiol” as used herein is represented by the formula-SH.

The term “polymeric” includes polyalkylene, polyether, polyester, and other groups with repeating units, such as, but not limited to —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COOCH₂CH₃)]ₙ—CH₃, and —CH₂CH(COO^{t}Bu)ₙ—CH₃, where n is an integer (e.g., n>1 or n>2).

“R,” “R¹,” “R²,” “R³,” “Rⁿ,” where n is an integer, as used herein can, independently, include hydrogen or one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within a second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

As described herein, compounds of the disclosure may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. It is also contemplated that, in certain aspects, unless expressly indicated to the contrary, individual substituents can be further optionally substituted (i.e., further substituted or unsubstituted).

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

In some aspects, a structure of a compound can be represented by a formula:

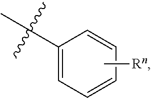

which is understood to be equivalent to a formula:

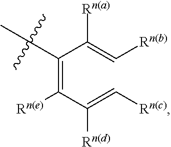

wherein n is typically an integer. That is, Rⁿ is understood to represent five independent substituents, R^{n(a)}, R^{n(b)}, R^{n(c)}, R^{n(d)}, R^{n(e)}. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R¹, R², R³, R⁴, R⁵, R⁶, etc. in the specification is applicable to any structure or moiety reciting R, R¹, R², R³, R⁴, R⁵, R⁶, etc. respectively.

Compounds disclosed herein are suited for use in a wide variety of optical and electro-optical devices, including, but not limited to, photo-absorbing devices such as solar- and photo-sensitive devices, organic light emitting devices (OLEDs), photo-emitting devices, or devices capable of both photo-absorption and emission and as markers for bio-applications.

The compounds disclosed herein are useful in a variety of applications. As light emitting materials, the compounds can be useful in organic light emitting devices (OLEDs), luminescent devices and displays, and other light emitting devices.

In another aspect, the compounds can provide improved efficiency, improved operational lifetimes, or both in lighting devices, such as, for example, organic light emitting devices, as compared to conventional materials.

The compounds of the disclosure can be made using a variety of methods, including, but not limited to those recited in the examples provided herein.

In any compound used in any layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

In yet another aspect of the present disclosure, a formulation that comprises any compound disclosed herein is described. The formulation can include one or more components selected from the group consisting of a solvent, a phosphorescent and/or fluorescent emitter, a host, a hole injection material, hole transport material, and/or an electron transport layer material, disclosed herein.

### Devices of the Invention

Disclosed herein are organic emitting diodes or light emitting devices comprising one or more compound and/or compositions disclosed herein.

In one aspect, the present invention relates to a white organic light emitting device comprising: a first electrode; a hole transporting layer in contact with the first electrode; a second electrode; an electron transporting layer in contact with the second electrode; and an emissive layer between the hole transporting layer and the electron transporting layer, the emissive layer comprising a host, a fluorescent emitter, and a phosphorescent emitter, wherein the fluorescent emitter harvests singlet excitons and emits blue light and wherein the phosphorescent emitter harvests triplet excitons and emits yellow-amber light.

In one embodiment, the phosphorescent emitter is an excimer emitter. In one embodiment, the phosphorescent emitter is a square planar complex. In one embodiment, the phosphorescent emitter is a tetradentate platinum or palladium complex.

In one embodiment, the phosphorescent emitter emits light in the range of about 480 nm to about 700 nm. In one embodiment, the phosphorescent emitter emits yellow, amber, or orange light.

In one embodiment, the phosphorescent emitter is a compound of General Formula I:

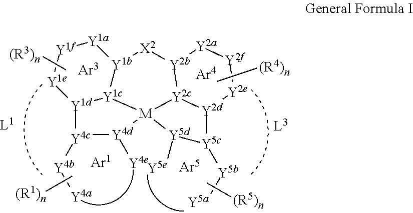

wherein, in General Formula I:

M represents Pt(II) or Pd(II);

R¹, R³, R⁴, and R⁵ each independently represents hydrogen, halogen, hydroxyl, nitro, cyanide, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;

X² represents NR, PR, CRR′, SiRR′, CRR′, SiRR′, O, S, S═O, O=S═O, Se, Se═O, or O=Se═O, wherein R and R′ each independently represents hydrogen, halogen, hydroxyl, nitro, cyanide, thiol, or optionally substituted C₁-C₄ alkyl, alkoxy, amino, aryl, or heteroaryl; each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;

Ar³ and Ar⁴ each independently represents a 6-membered aryl group; and

Ar¹ and Ar⁵ each independently represents a 5- to 10-membered aryl, heteroaryl, fused aryl, or fused heteroaryl.

In one embodiment, M represents Pd(II).

In one embodiment, the phosphorescent emitter is a compound of General Formula II;

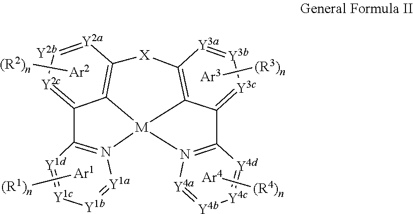

wherein, in General Formula II:

M represents Pt(II) or Pd(II);

R¹, R², R³, and R⁴ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{2c}, Y^{3a}, Y^{3b}, Y^{3c}, Y^{4a}, Y^{4b}, Y^{4c}, and Y^{4d} each independently represents C, N, or Si; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula III:

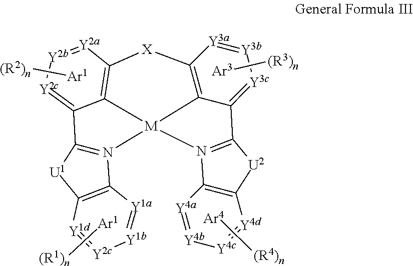

wherein, in General Formula III:

M represents Pt(II) or Pd(II);

R¹, R², R³, and R⁴ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{2c}, Y^{3a}, Y^{3b}, Y^{3c}, Y^{4a}, Y^{4b}, Y^{4c}, and Y^{4d}, each independently represents C, N, or Si;

U¹ and U² each independently represents NR, O or S, wherein R represents hydrogen, halogen, hydroxyl, nitro, nitrile, thiol, or optionally substituted C₁-C₄ alkyl, alkoxy, amino, or aryl; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula IV;

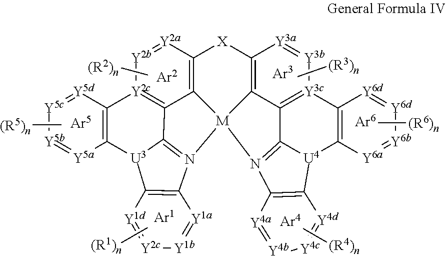

wherein, in General Formula IV:

M represents Pt(II) or Pd(II);

R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{3a}, Y^{3b}, Y^{3c}, Y^{4a}, Y^{4b}, Y^{4c}, Y^{4d}, Y^{5a}, Y^{5b}, Y^{5c}, Y^{5d}, Y^{6a}, Y^{6b}, Y^{6c}, and Y^{6d} each independently represents C, N, or Si;

Y^{2c} and Y^{3c} each independently represents C or Si;

U³ and U⁴ each independently represents N or P; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula V;

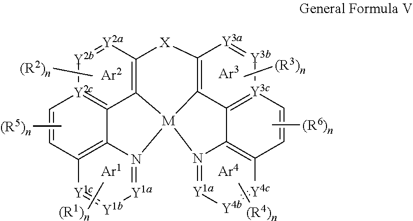

wherein, in General Formula V:

M represents Pt(II) or Pd(II);

R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{2a}, Y^{2b}, Y^{3a}, Y^{3b}, Y^{4a}, Y^{4b}, and Y^{4c} each independently represents C, N, or Si;

Y^{2c} and Y^{3c} each independently represents C or Si; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula VI;

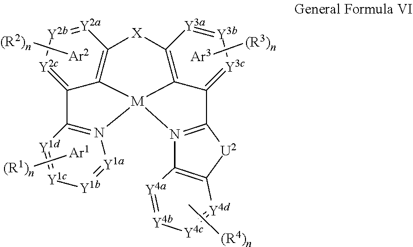

wherein, in General Formula VI:

M represents Pt(II) or Pd(II);

R¹, R², R³, and R⁴ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{2c}, Y^{3a}, Y^{3b}, Y^{3c}, Y^{4a}, Y^{4b}, Y^{4c}, and Y^{4d} each independently represents C, N, or Si;

U² represents NR, O or S, wherein R represents hydrogen, halogen, hydroxyl, nitro, nitrile, thiol, or optionally substituted C₁-C₄ alkyl, alkoxy, amino, or aryl;

U³ and U⁴ each independently represents N or P; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula VII;

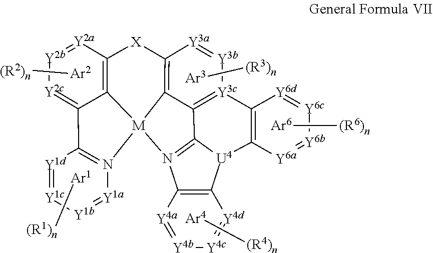

wherein, in General Formula VII:

M represents Pt(II) or Pd(II);

R¹, R², R³, R⁴, and R⁶ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{2c}, Y^{3a}, Y^{3b}, Y^{4a}, Y^{4b}, Y^{4c}, Y^{4d}, Y^{6a}, Y^{6b}, Y^{6c}, and Y^{6d} each independently represents C, N, or Si;

Y^{3c} represents C or Si;

U⁴ represents N or P; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula VIII;

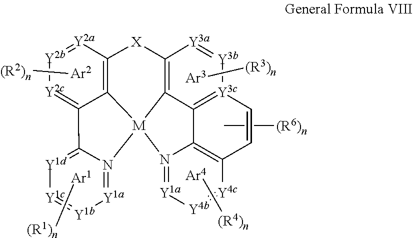

wherein, in General Formula VIII:

M represents Pt(II) or Pd(II);

R¹, R², R³, R⁴, and R⁶ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{2c}, Y^{3a}, Y^{3b}, Y^{4a}, Y^{4b}, Y^{4c}, and Y^{4d} each independently represents C, N, or Si;

Y^{3c} represents C or Si; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is a compound of General Formula IX:

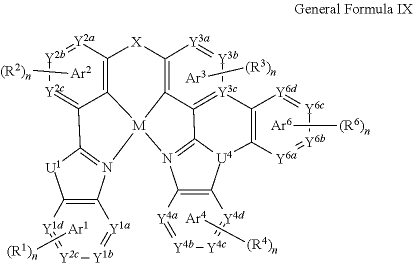

wherein, in General Formula IX:

M represents Pt(II) or Pd(II);

R¹, R², R³, R⁴, and R⁶ each independently represents hydrogen, halogen, hydroxyl, nitro, nitrile, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{2a}, Y^{2b}, Y^{2c}, Y^{3a}, Y^{3b}, Y^{4a}, Y^{4b}, Y^{4c}, Y^{4d}, Y^{6a}, Y^{6b}, Y^{6c} and Y^{6d} each independently represents C, N, or Si;

Y^{3C} represents C or Si;

U¹ represents NR, O or S, wherein R represents hydrogen, halogen, hydroxyl, nitro, nitrile, thiol, or optionally substituted C₁-C₄ alkyl, alkoxy, amino, or aryl;

U⁴ represents N or P; and

X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

In one embodiment, the phosphorescent emitter is represented by one of the following compounds:

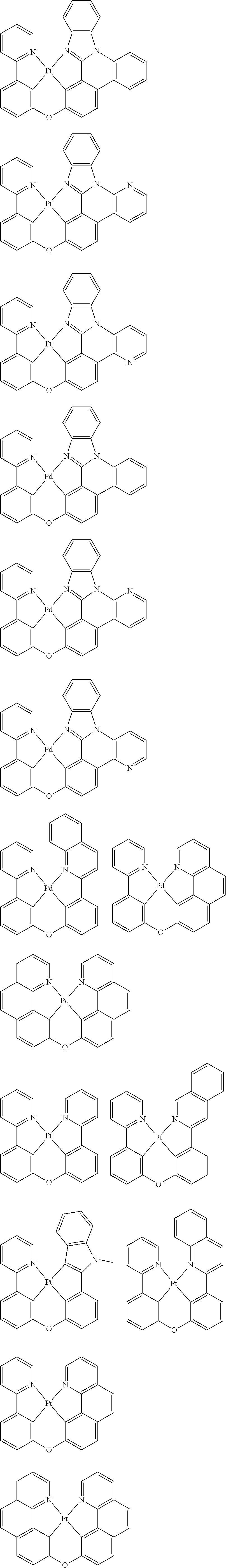

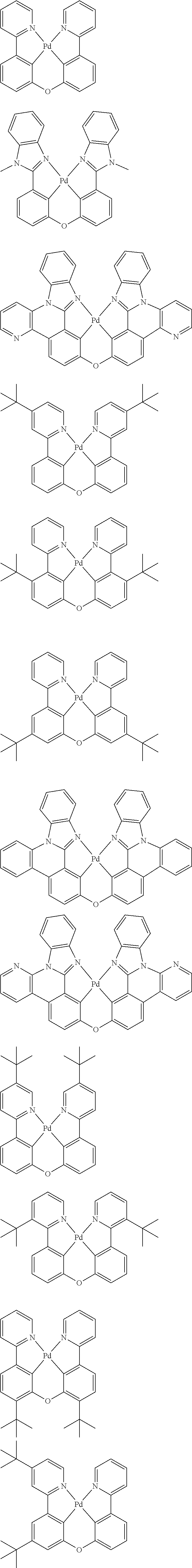

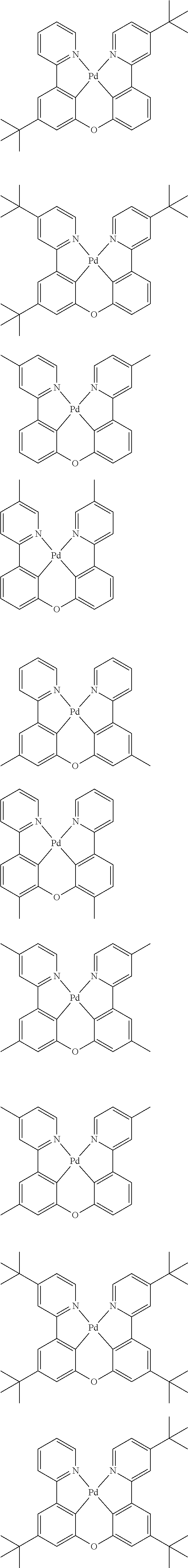

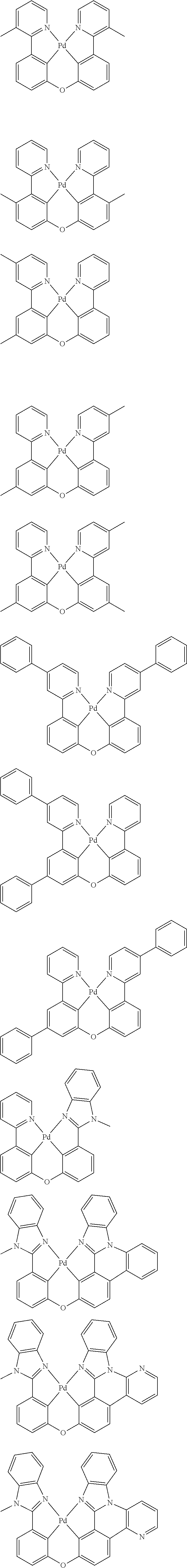

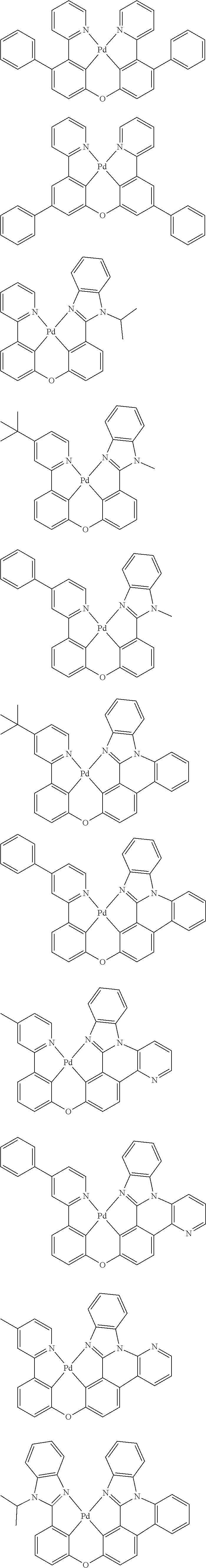

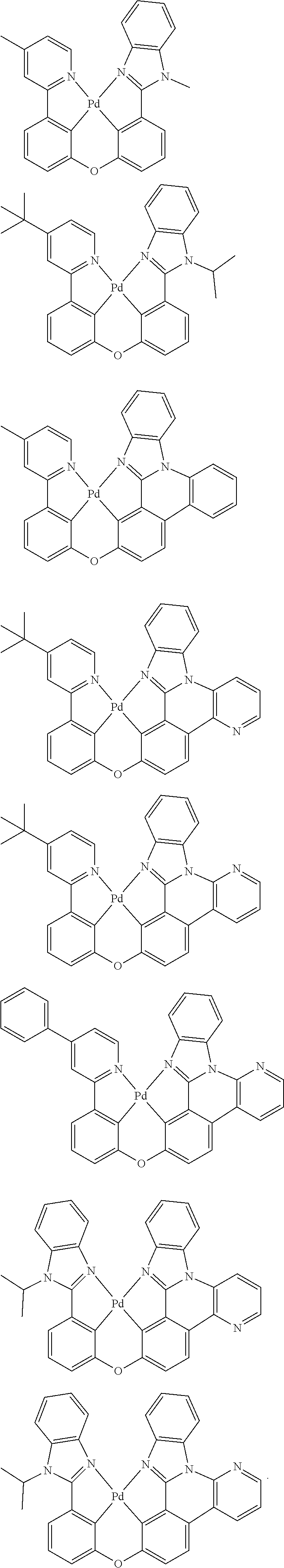

In one embodiment, the fluorescent emitter comprises one of the following compounds:

### 1. Aromatic Hydrocarbons and Their Derivatives

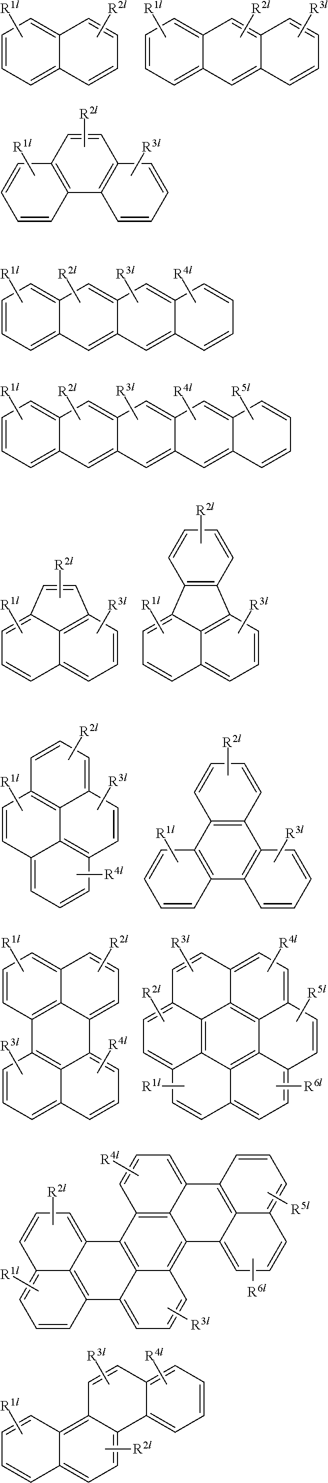

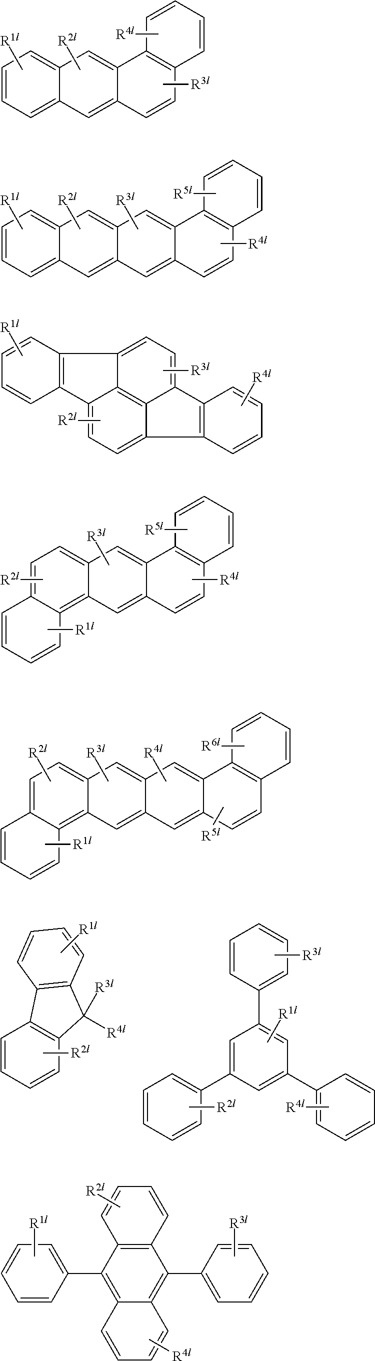

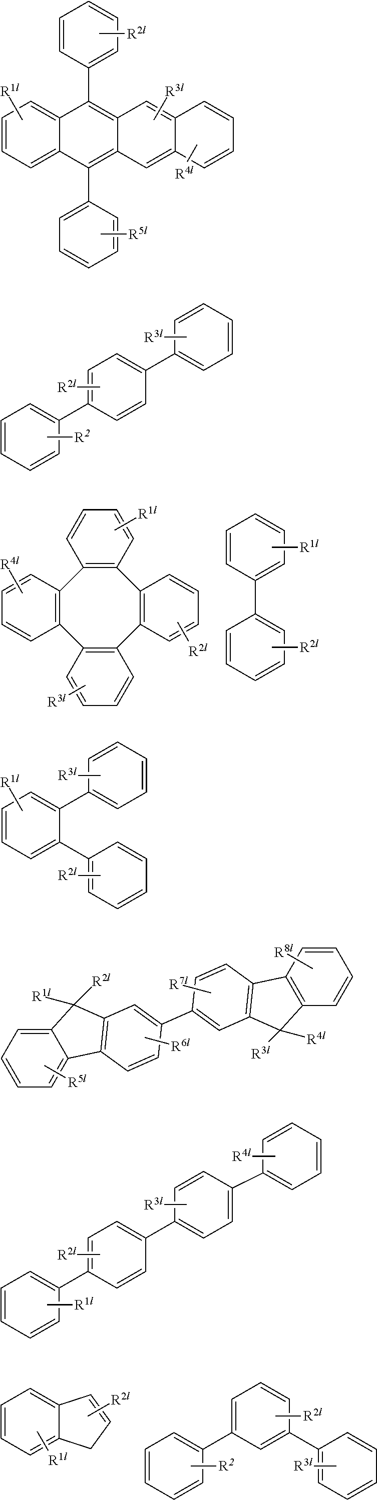

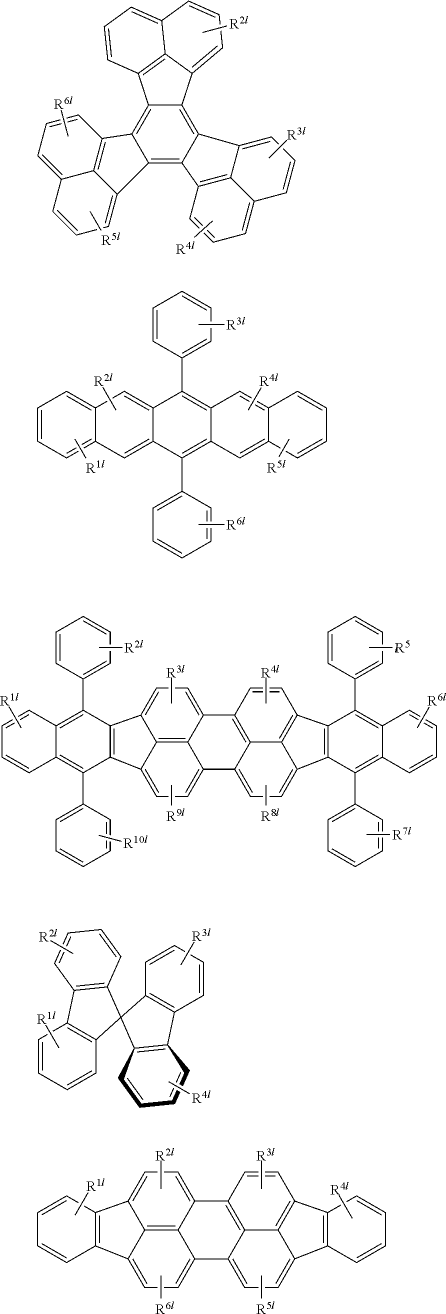

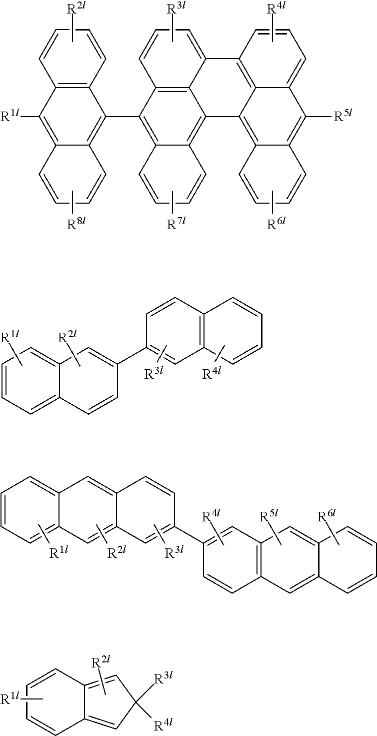

### 2. Arylethylene, Arylacetylene and Their Derivatives

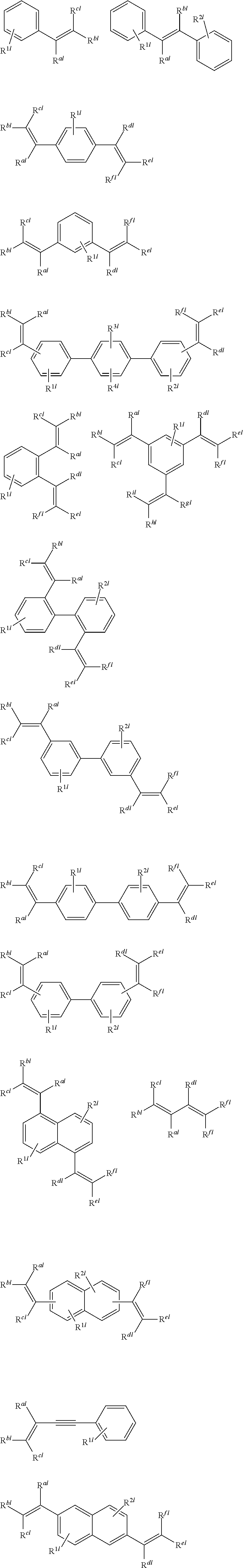

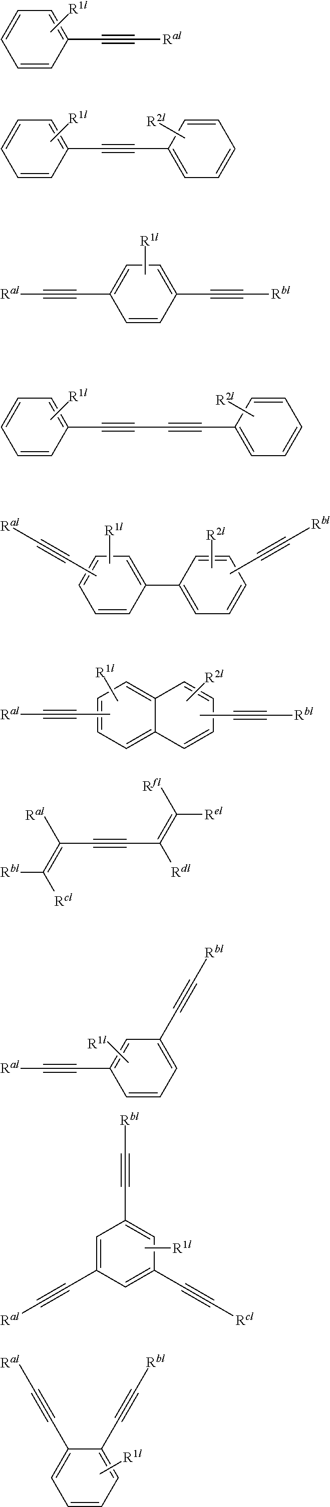

wherein R^{al}, R^{bl}, R^{cl}, R^{dl}, R^{el}, R^{fl}, R^{gl}, R^{hl} and R^{il}
can be one of the following structure:

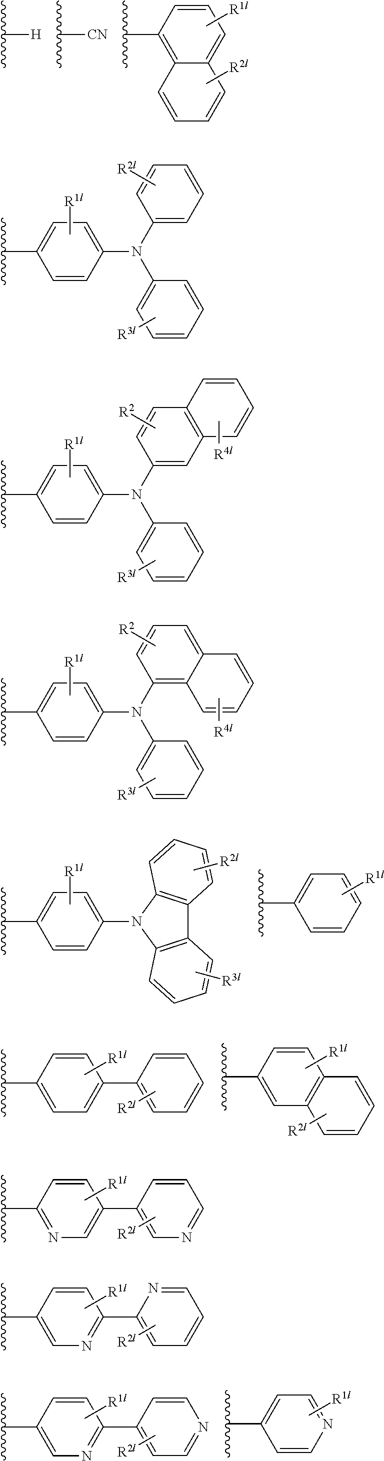

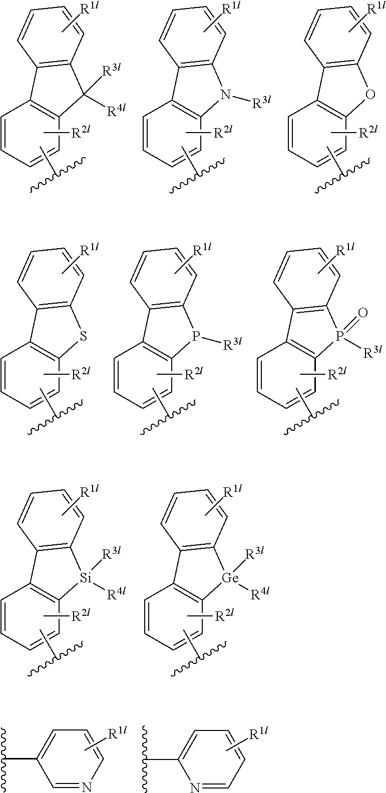

### 3. Heterocyclic Compounds and Their Derivatives

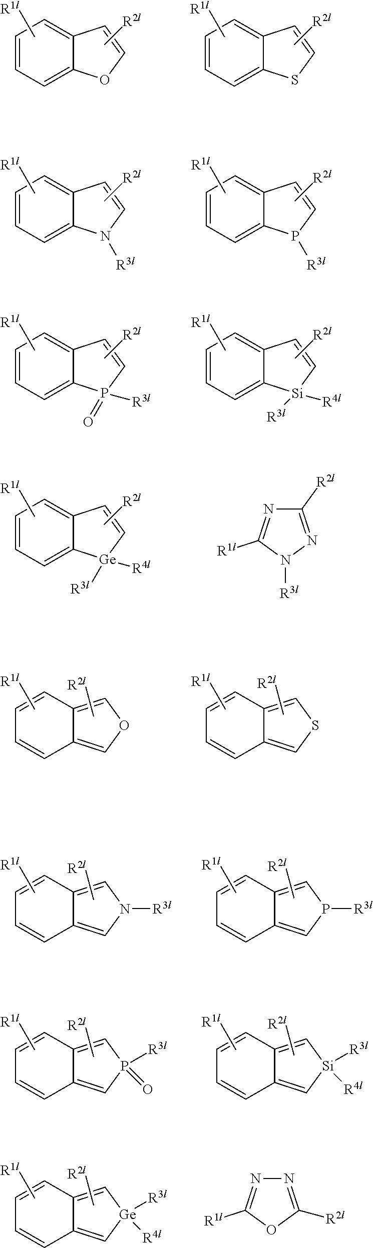

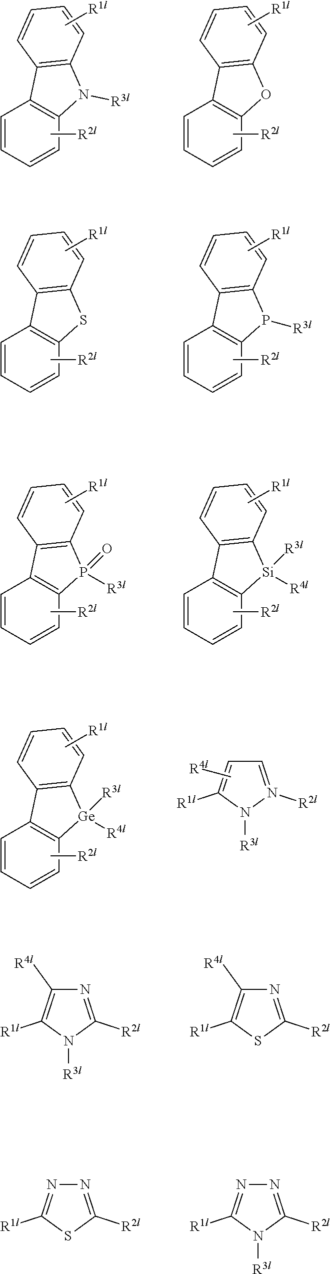

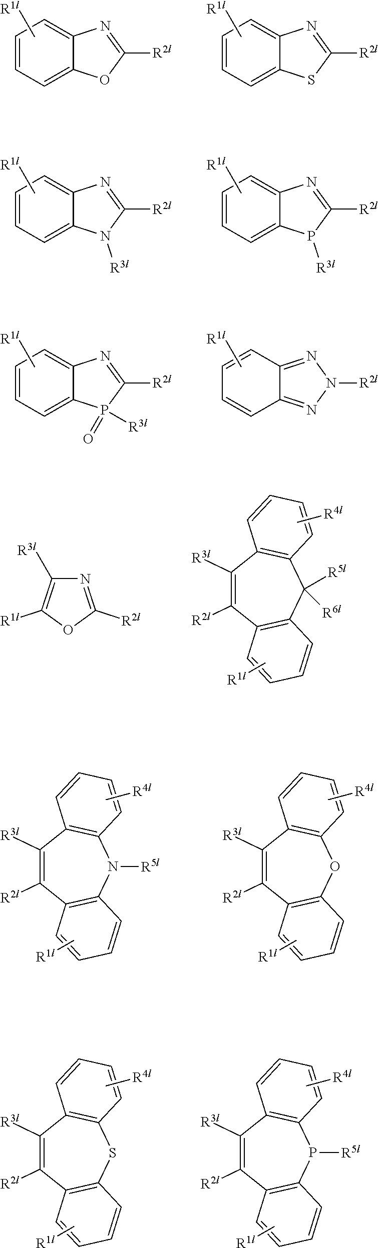

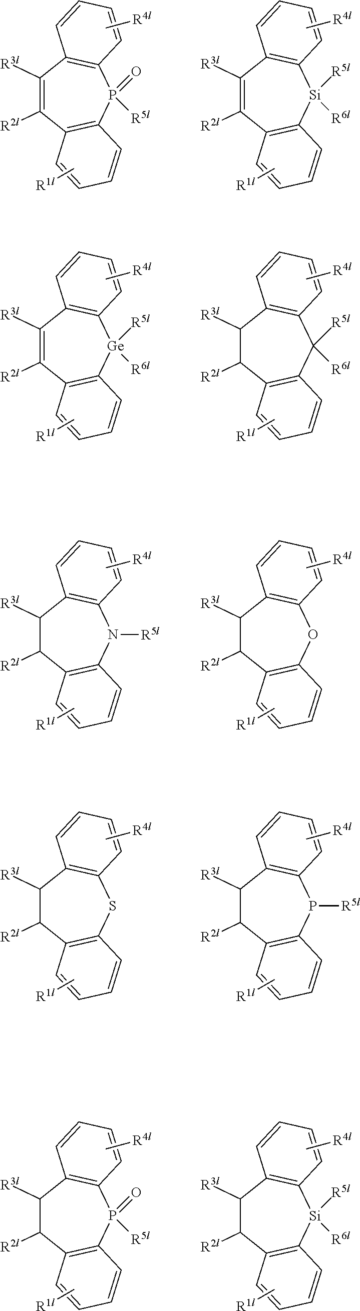

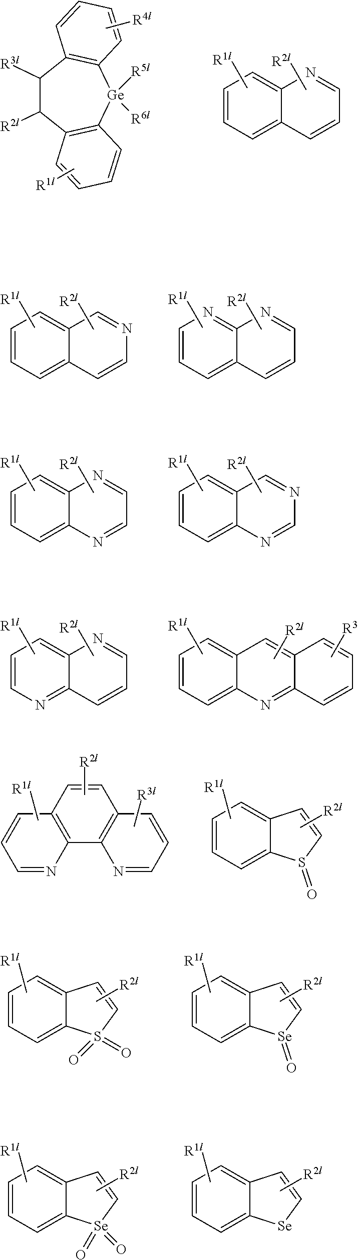

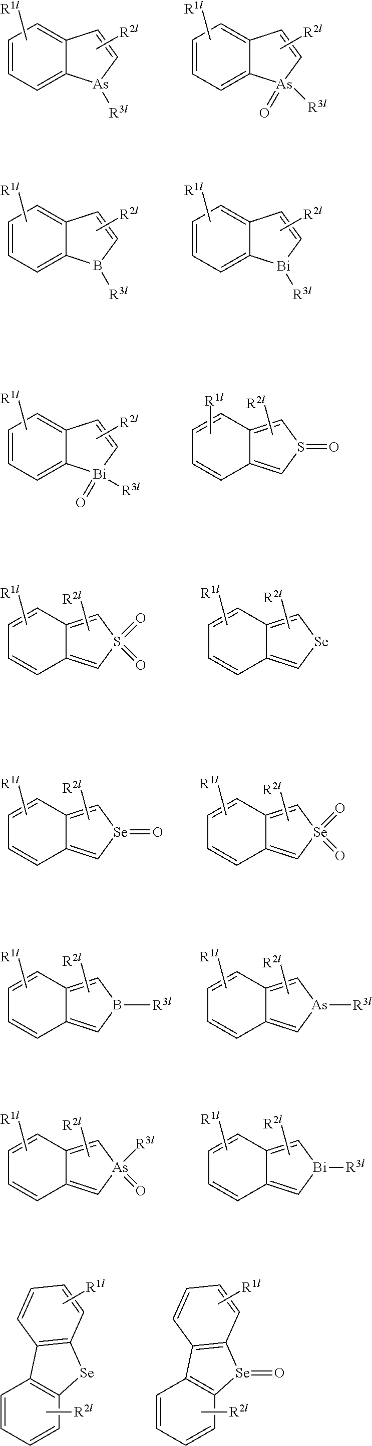

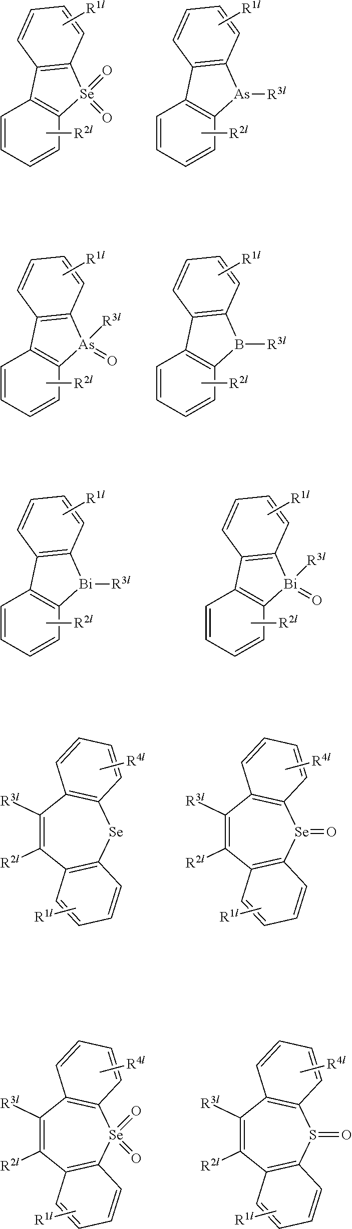

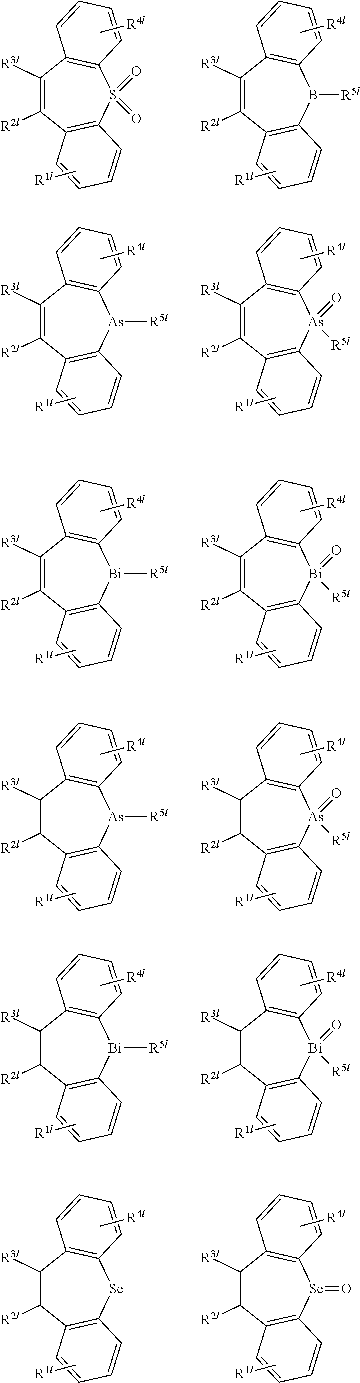

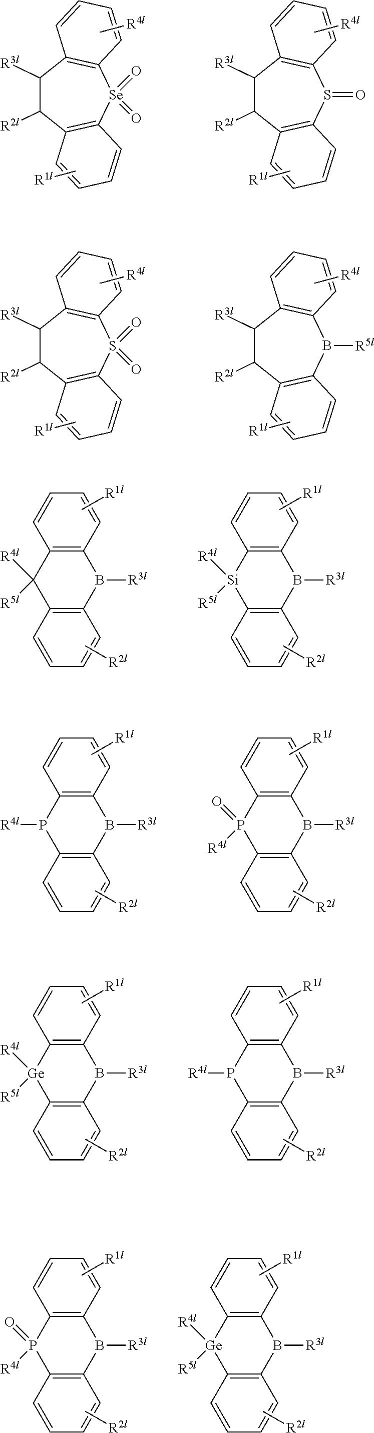

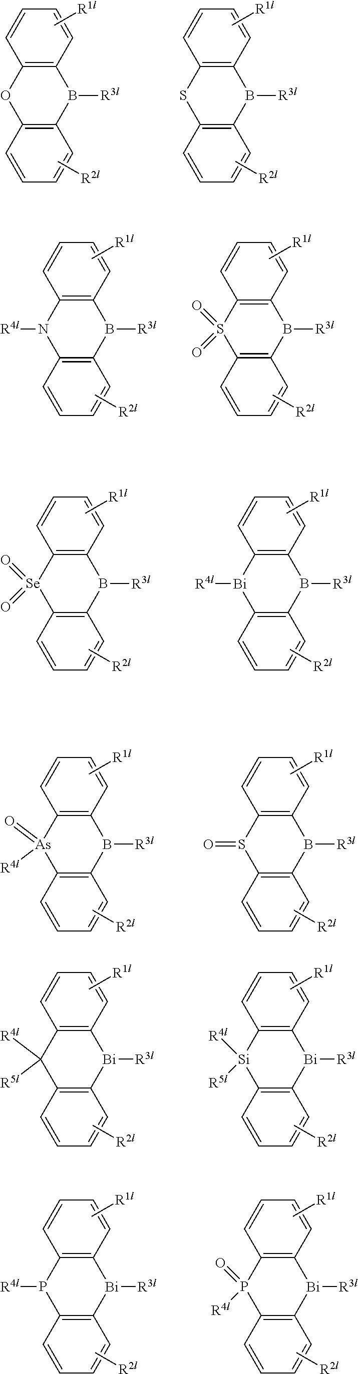

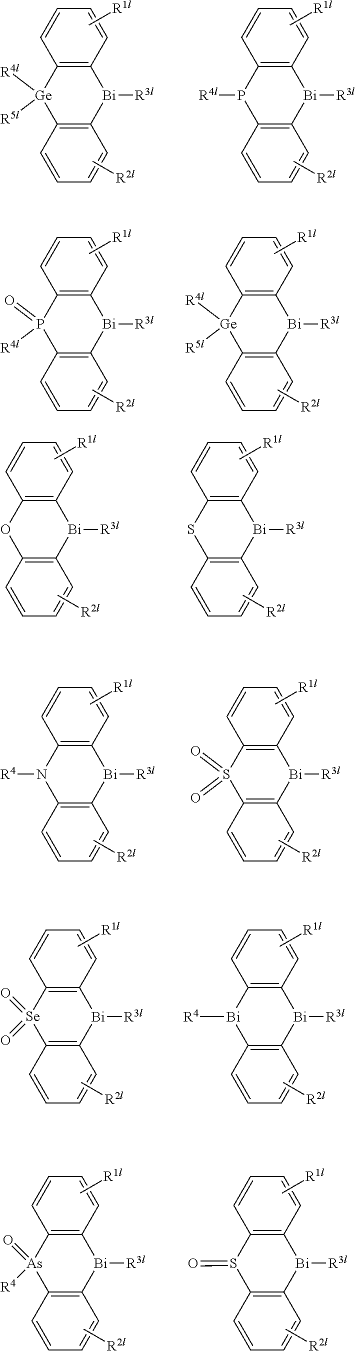

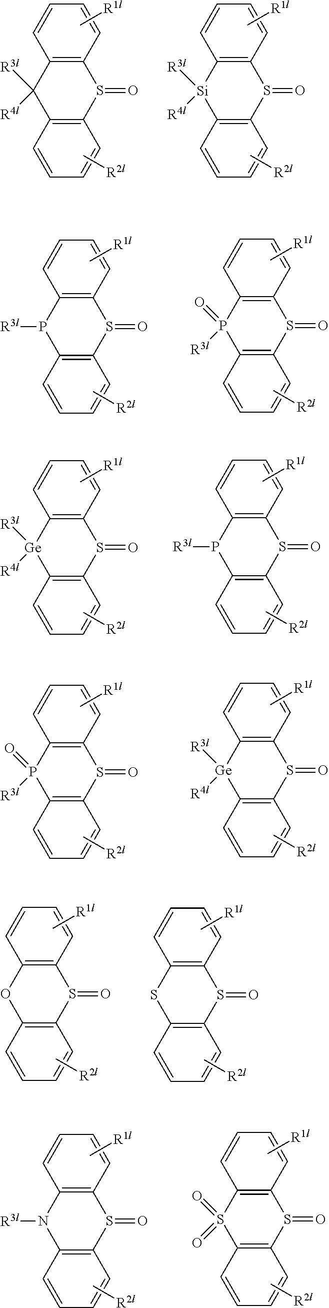

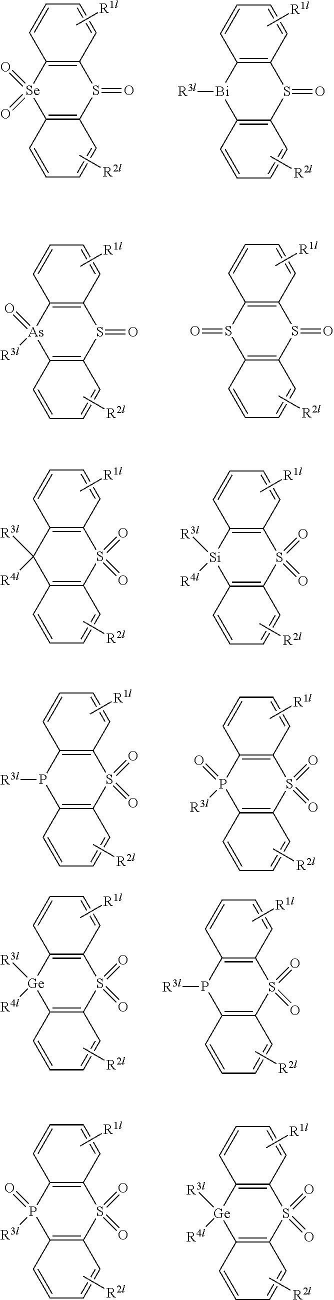

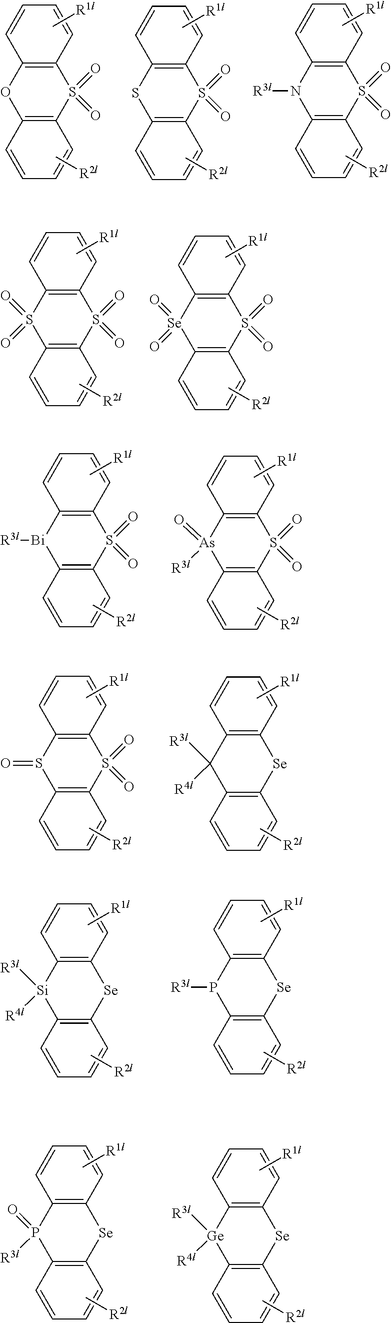

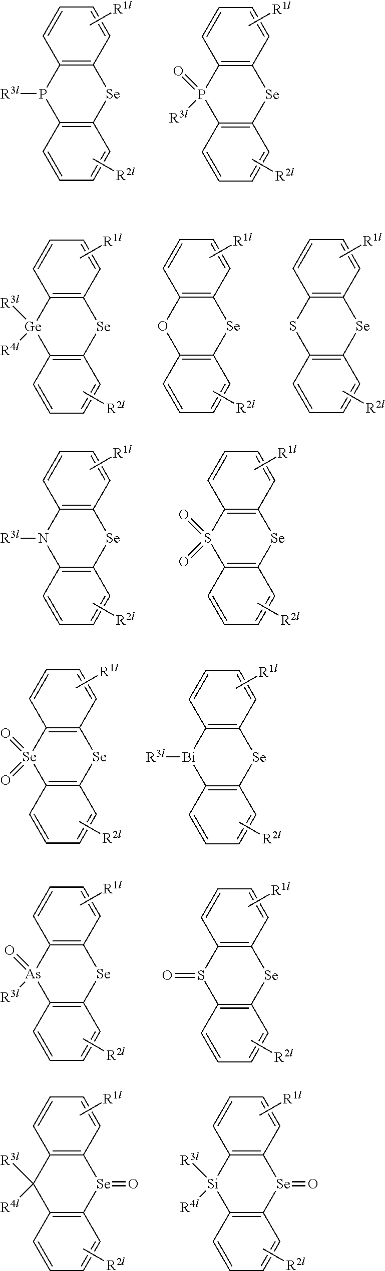

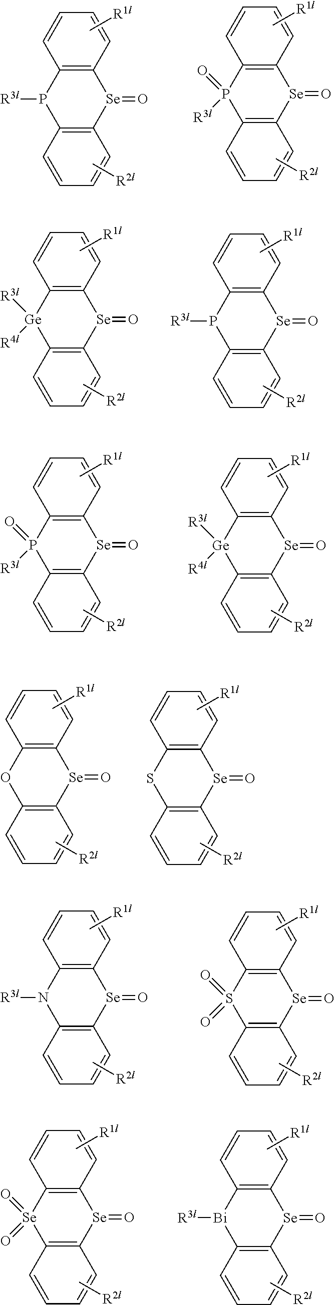

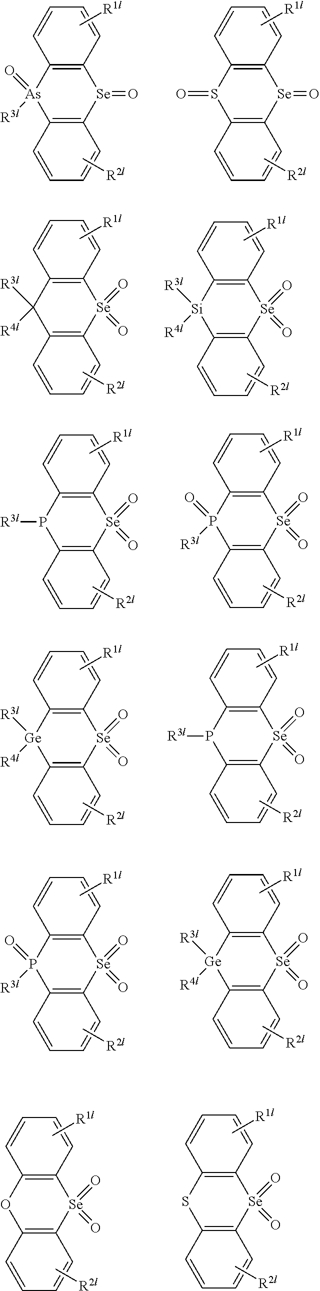

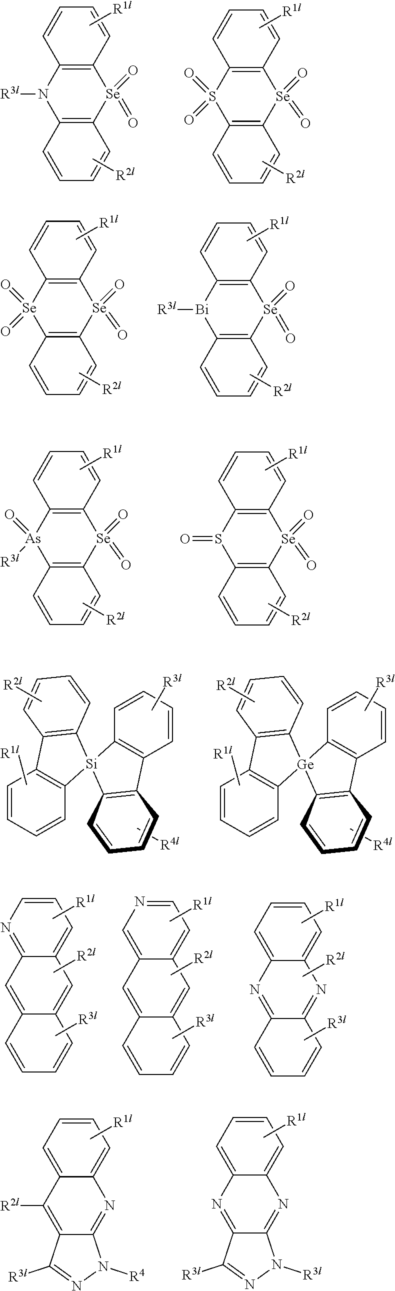

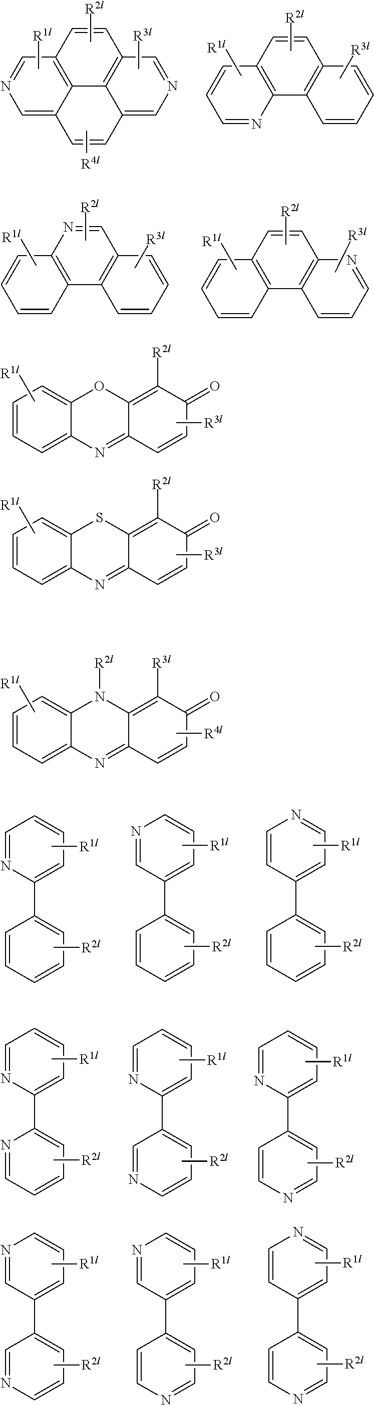

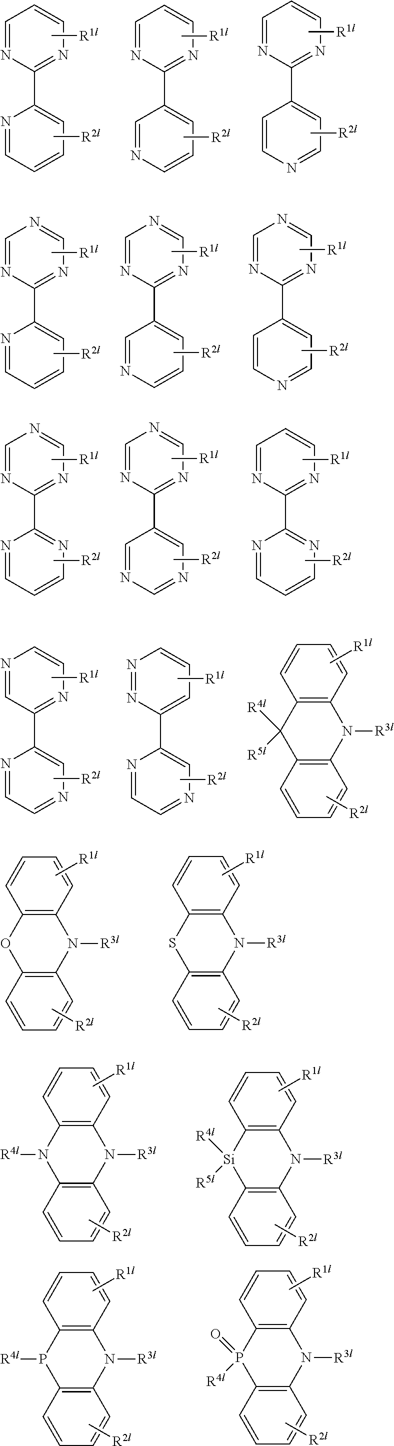

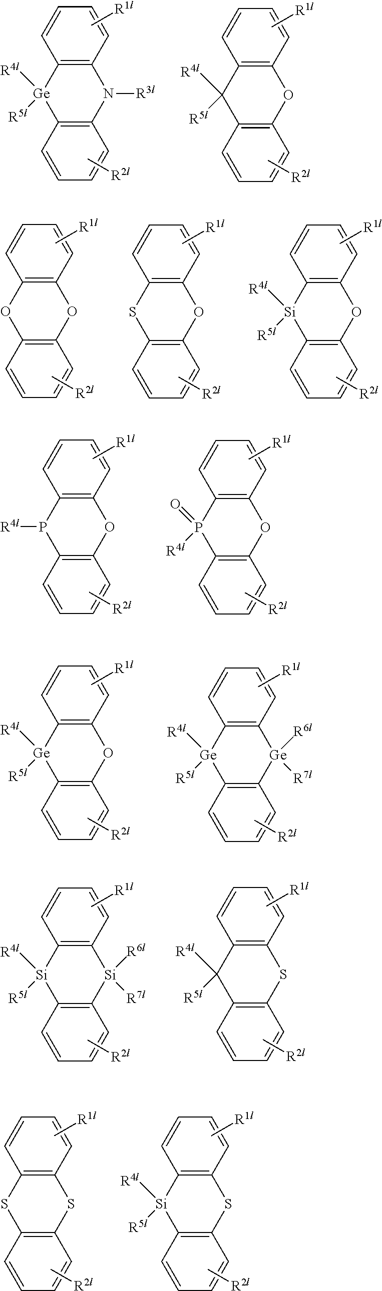

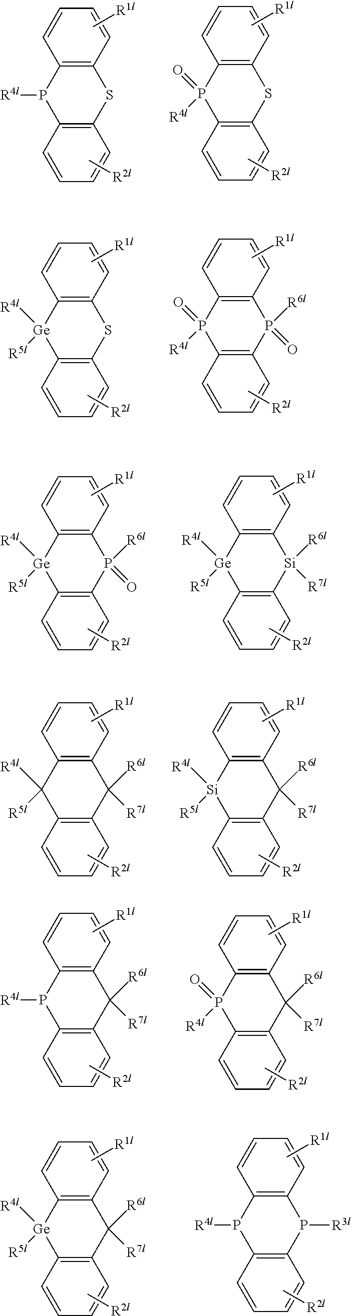

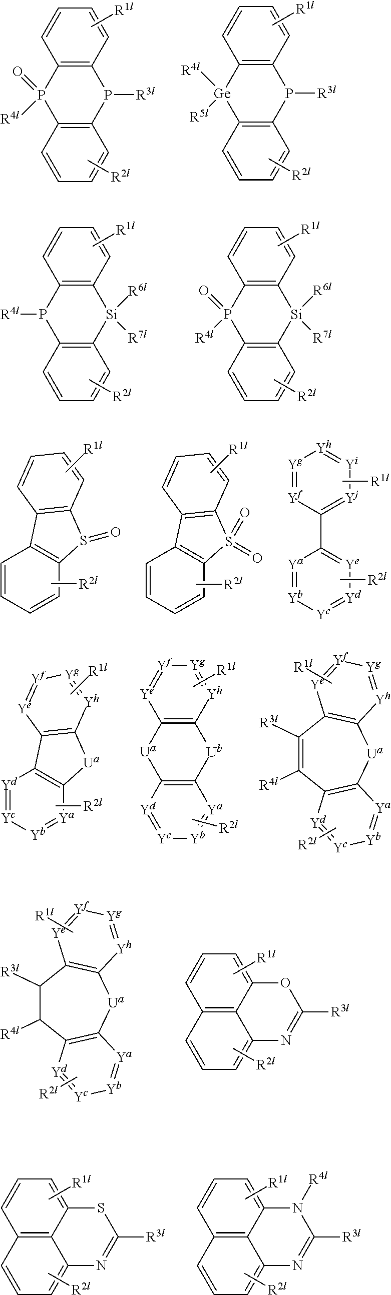

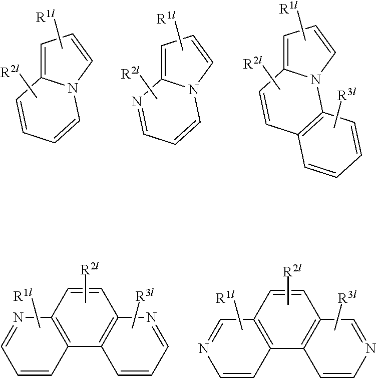

### 4. Other Fluorescent Luminophors

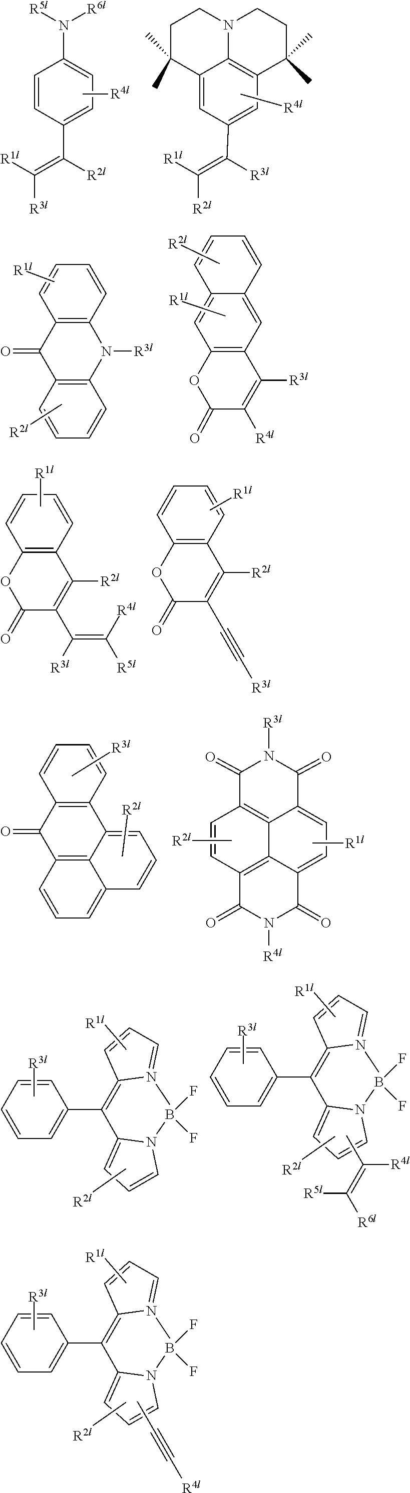

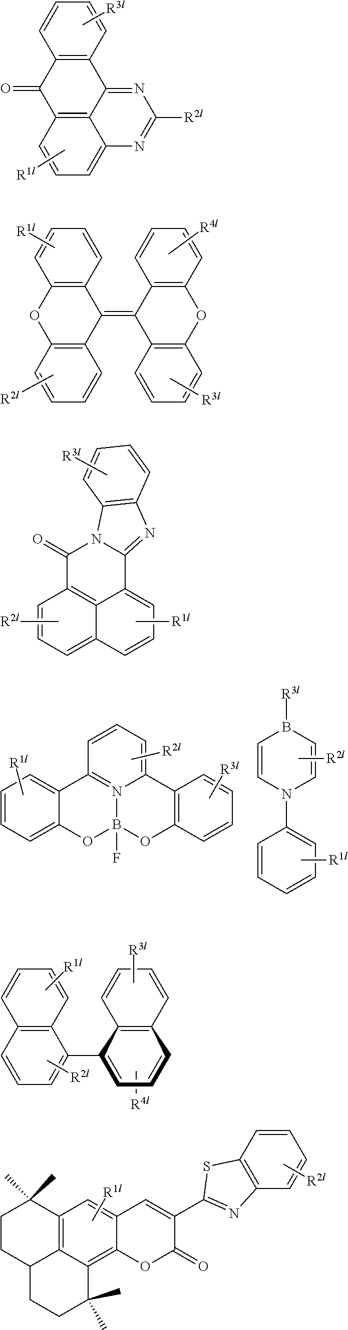

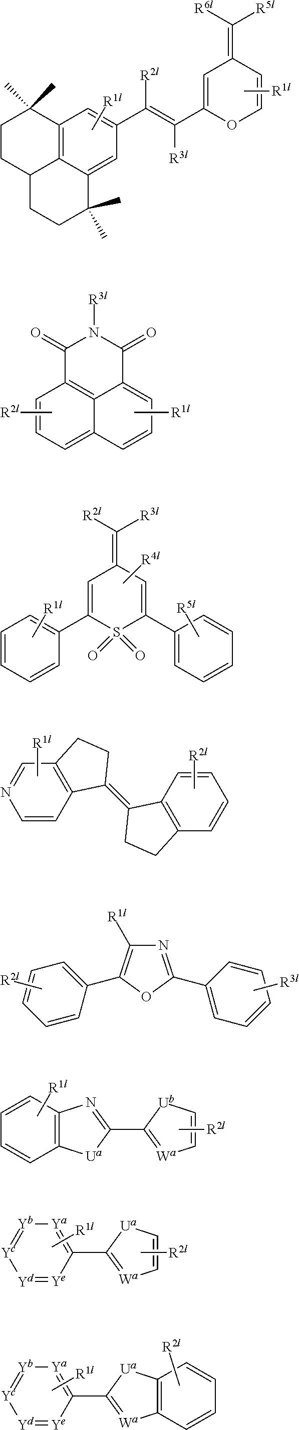

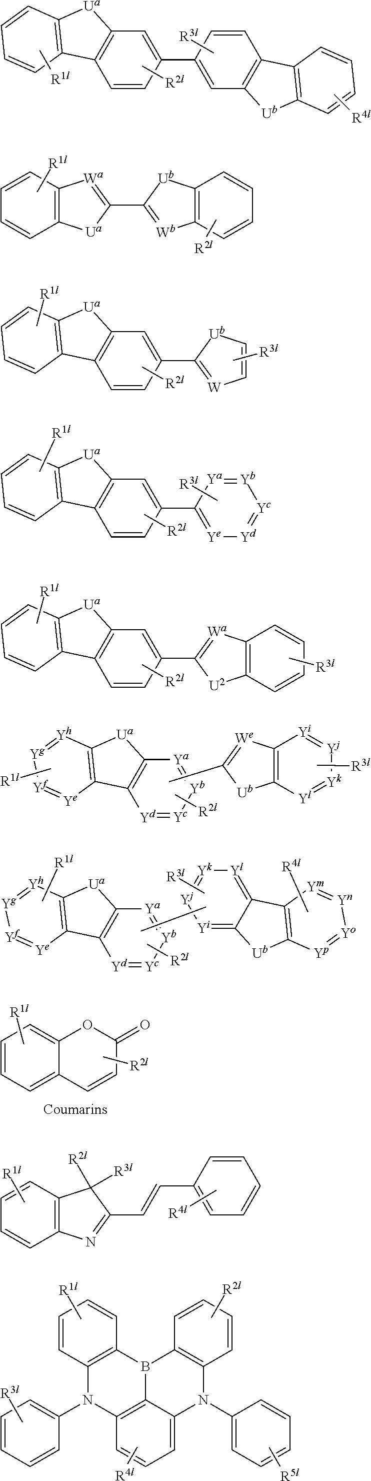

wherein each of R¹¹, R²¹, R³¹, R⁴¹, R⁵¹, R⁶¹, R⁷¹ and R⁸¹ independently are hydrogen, aryl, cycloalkyl, cycloalkenyl, heterocyclyl, heteroaryl, alkyl, alkenyl, alkynyl, deuterium, halogen, hydroxyl, thiol, nitro, cyano, amino, a mono- or di-alkylamino, a mono- or diarylamino, alkoxy, aryloxy, haloalkyl, aralkyl, ester, nitrile, isonitrile, heteroaryl, alkoxycarbonyl, acylamino, alkoxycarbonylamino, aryloxycarbonylamino, sulfonylamino, sulfamoyl, carbamoyl, alkylthio, sulfinyl, ureido, phosphoramide, mercapto, sulfo, carboxyl, hydrzino, substituted silyl, polymeric, or any conjugate or combination thereof;

wherein each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o} and Y^{p} independently are C, N or B;

wherein each of U^{a}, U^{b} and U^{c} independently represent CH₂, CR¹R². C═O, CH₂, SiR¹R², GeH₂, GeR³R², NH, NR³, PH, PR³, R³P═O, AsR³, R³As═O, O, S, S═O, SO₂, Se, Se═O, SeO₂, BH, BR³, R³Bi═O, BiH, or BiR³;

wherein each R¹, R², and R³ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoaryl amino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof.

In one embodiment, the fluorescent emitter is selected from the group consisting of TBPe, t-DABNA, FLB2, BH, and BH2.

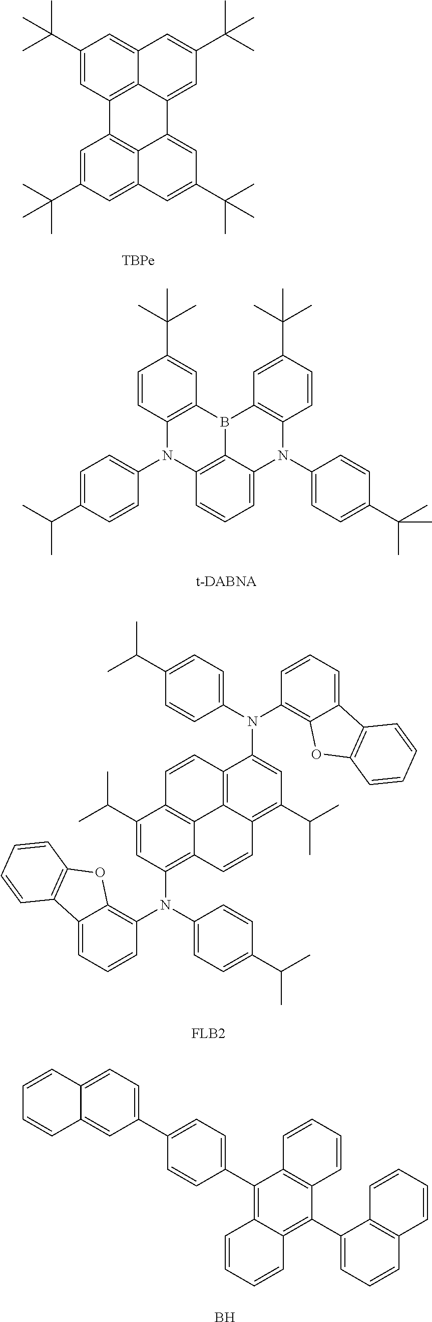

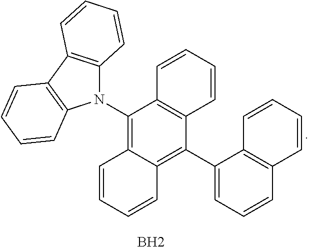

In one aspect, the device is an electro-optical device. Electro-optical devices include, but are not limited to, photo-absorbing devices such as solar- and photo-sensitive devices, organic light emitting devices, photo-emitting devices, or devices capable of both photo-absorption and emission and as markers for bio-applications. For example, the device can be an OLED.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art. Such devices are disclosed herein which comprise one or more of the compounds or compositions disclosed herein.

OLEDs can be produced by methods known to those skilled in the art. In general, the OLED is produced by successive vapor deposition of the individual layers onto a suitable substrate. Suitable substrates include, for example, glass, inorganic materials such as ITO or IZO or polymer films. For the vapor deposition, customary techniques may be used, such as thermal evaporation, chemical vapor deposition (CVD), physical vapor deposition (PVD) and others.

In an alternative process, the organic layers may be coated from solutions or dispersions in suitable solvents, in which case coating techniques known to those skilled in the art are employed. Suitable coating techniques are, for example, spin-coating, the casting method, the Langmuir-Blodgett (“LB”) method, the inkjet printing method, dip-coating, letterpress printing, screen printing, doctor blade printing, slit-coating, roller printing, reverse roller printing, offset lithography printing, flexographic printing, web printing, spray coating, coating by a brush or pad printing, and the like. Among the processes mentioned, in addition to the aforementioned vapor deposition, preference is given to spin-coating, the inkjet printing method and the casting method since they are particularly simple and inexpensive to perform. In the case that layers of the OLED are obtained by the spin-coating method, the casting method or the inkjet printing method, the coating can be obtained using a solution prepared by dissolving the composition in a concentration of 0.0001 to 90% by weight in a suitable organic solvent such as benzene, toluene, xylene, tetrahydrofuran, methyltetrahydrofuran, N,N-dimethylformamide, acetone, acetonitrile, anisole, dichloromethane, dimethyl sulfoxide, water and mixtures thereof.

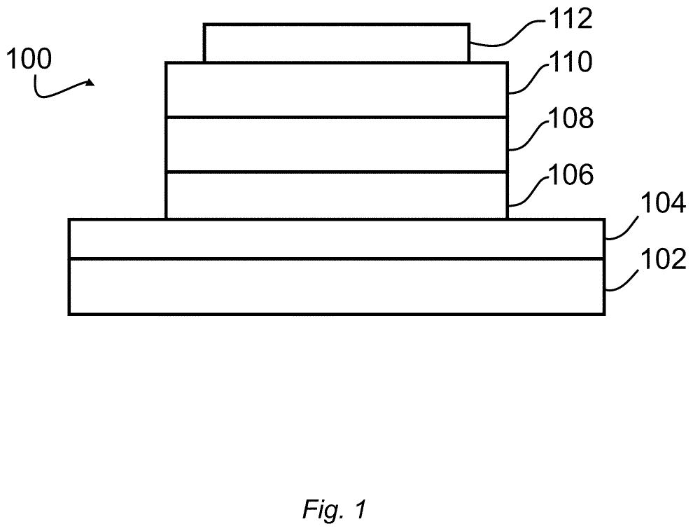

FIG. 1 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′ diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more compounds of the present disclosure optionally together with a host material. The host material can be any suitable host material known in the art. The emission color of an OLED is determined by the emission energy (optical energy gap) of the light processing material 108, which can be tuned by tuning the electronic structure of the emitting compounds, the host material, or both. Both the hole-transporting material in the HTL layer 106 and the electron-transporting material(s) in the ETL layer 110 may include any suitable hole-transporter known in the art.

Compounds described herein may exhibit phosphorescence. Phosphorescent OLEDs (i.e., OLEDs with phosphorescent emitters) typically have higher device efficiencies than other OLEDs, such as fluorescent OLEDs. Light emitting devices based on electrophosphorescent emitters are described in more detail in WO2000/070655 to Baldo et al., which is incorporated herein by this reference for its teaching of OLEDs, and in particular phosphorescent OLEDs.

As contemplated herein, an OLED of the present invention may include an anode, a cathode, and an organic layer disposed between the anode and the cathode. The organic layer may include a host and a phosphorescent dopant. The organic layer can include a compound of the invention and its variations as described herein.

In some embodiments, the OLED has one or more characteristics selected from the group consisting of being flexible, being reliable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In one embodiment, the invention relates to a consumer product comprising a device described herein. Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, reliable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays filed together, theater or stadium screen, a light therapy device, and a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C. “s

In some embodiments of the emissive region, the emissive region further comprises a host, wherein the host comprises at least one selected from the group consisting of metal complex, triphenylene, carbazole, dibenzothiophene, dibenzofuran, dibenzoselenophene, aza-triphenylene, aza-carbazole, aza-dibenzothiophene, aza-dibenzofuran, and aza-dibenzoselenophene.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be a triphenylene containing benzo-fused thiophene or benzo-fused furan. Any substituent in the host can be an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂ₙ₊₁, C≡C—CₙH₂ₙ₊₁, Ar₁, Ar₁-Ar₂, and CₙH₂ₙ-Ar₁, or the host has no substitutions. In the preceding substituents n can range from 1 to 10; and Ar1 and Ar2 can be independently selected from the group consisting of benzene, biphenyl, naphthalene, triphenylene, carbazole, and heteroaromatic analogs thereof. The host can be an inorganic compound. For example, a Zn containing inorganic material e.g. ZnS.

The host can be a compound comprising at least one chemical group selected from the group consisting of triphenylene, carbazole, dibenzothiophene, dibenzofuran, dibenzoselenophene, azatriphenylene, azacarbazole, aza-dibenzothiophene, aza-dibenzofuran, and aza-dibenzoselenophene. The host can include a metal complex. The host can be, but is not limited to, a specific compound selected from the group consisting of:

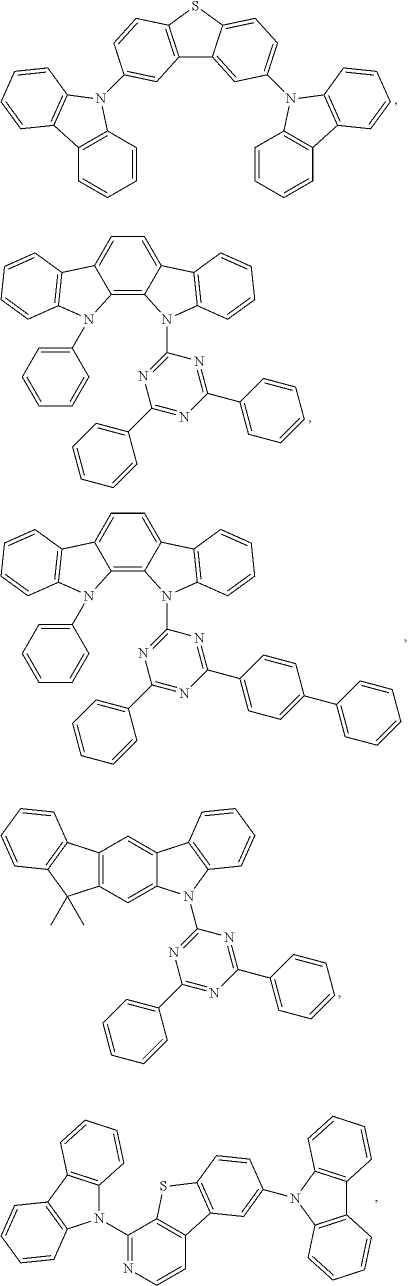

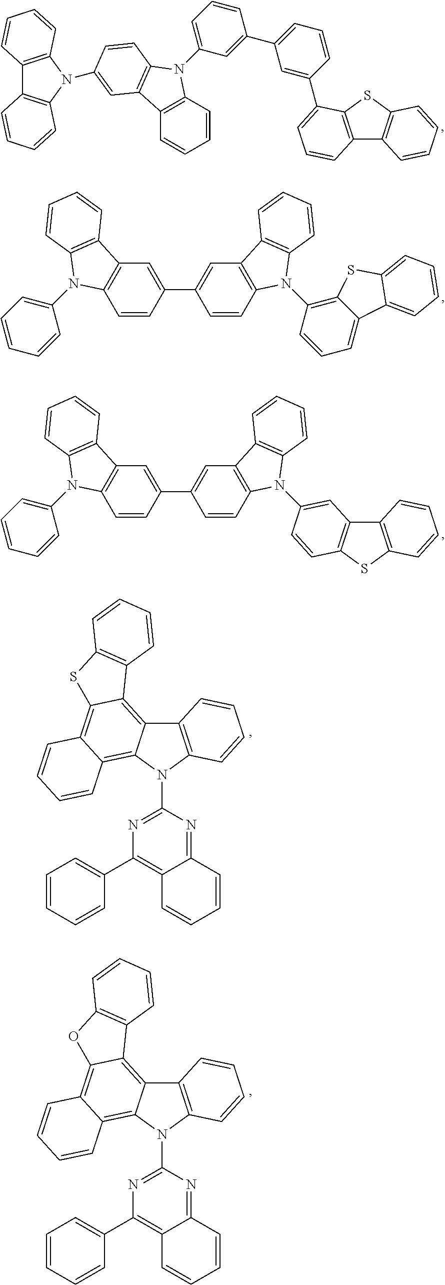 [SMILES: c1cc(-c2cccc(-n3c4ccccc4c4cc(-n5c6ccccc6c6ccccc65)ccc43)c2)cc(-c2cccc3c2sc2ccccc23)c1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-c2nc(-n3c4ccccc4c4c5c6ccccc6sc5c5ccccc5c43)nc3ccccc23)cc1 ; c1ccc(-c2nc(-n3c4ccccc4c4c5c6ccccc6oc5c5ccccc5c43)nc3ccccc23)cc1]

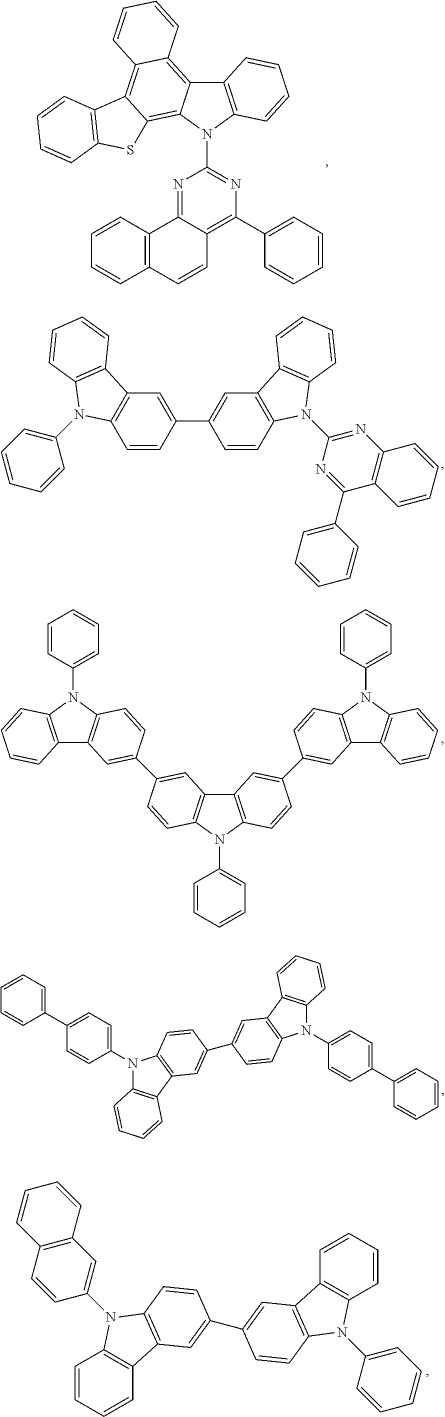

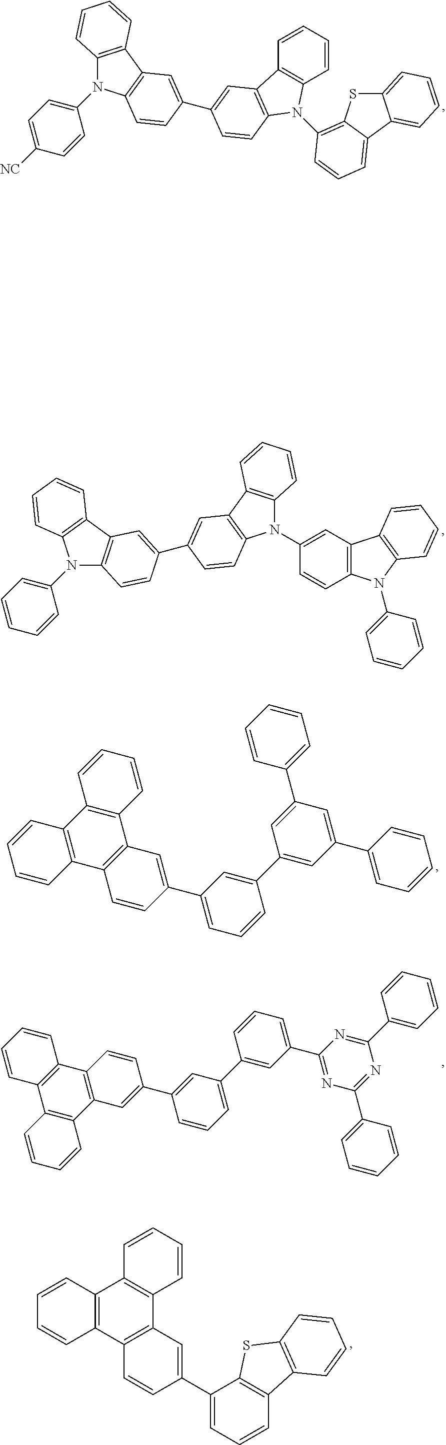

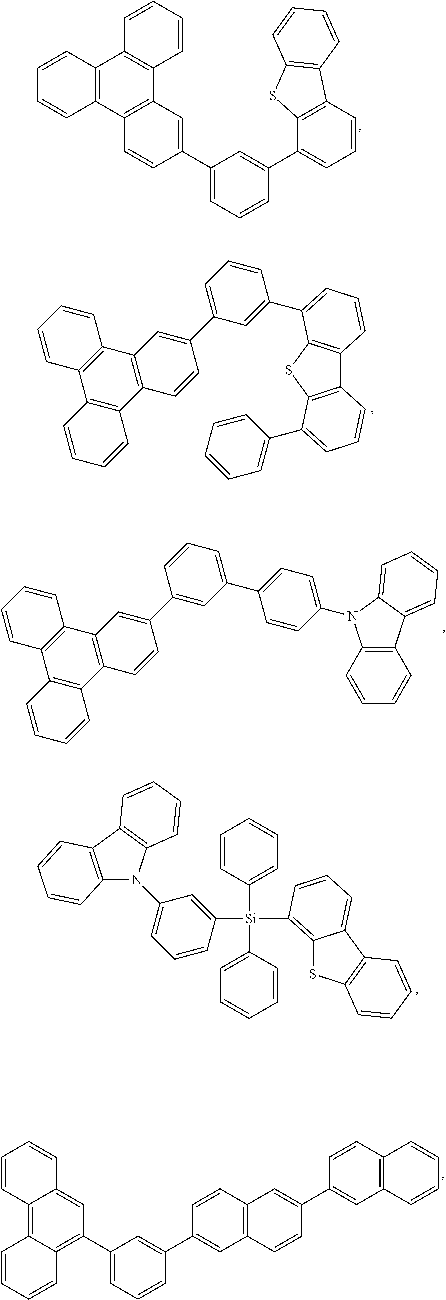

and combinations thereof.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

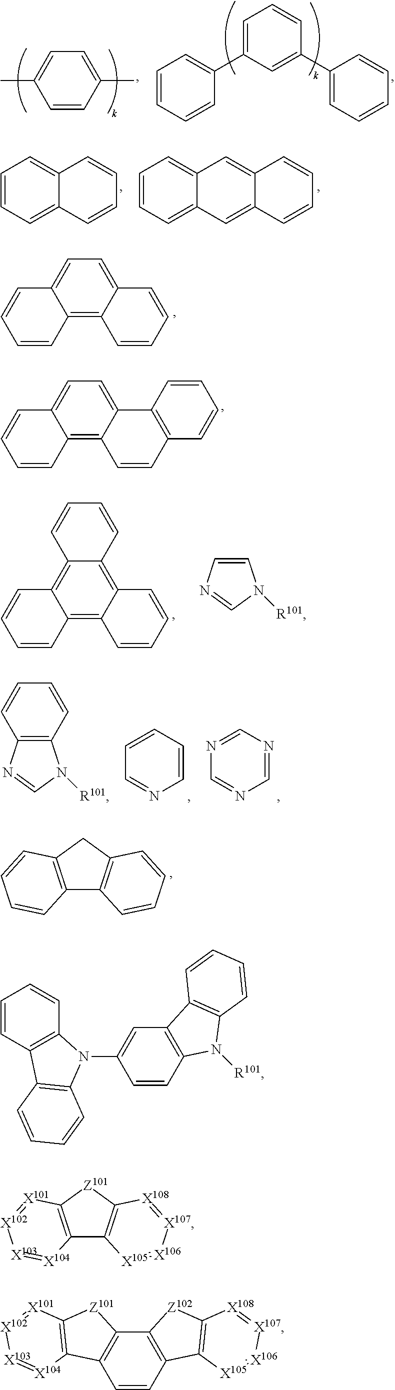

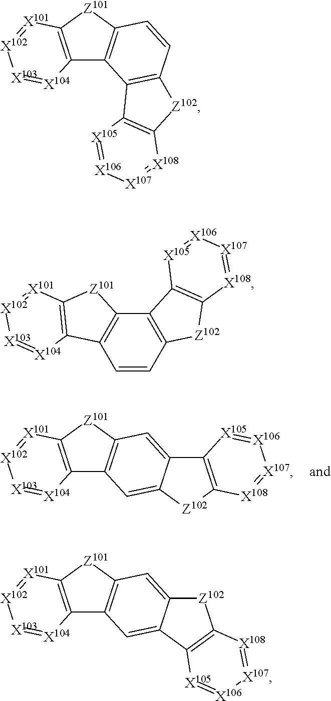

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above, k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

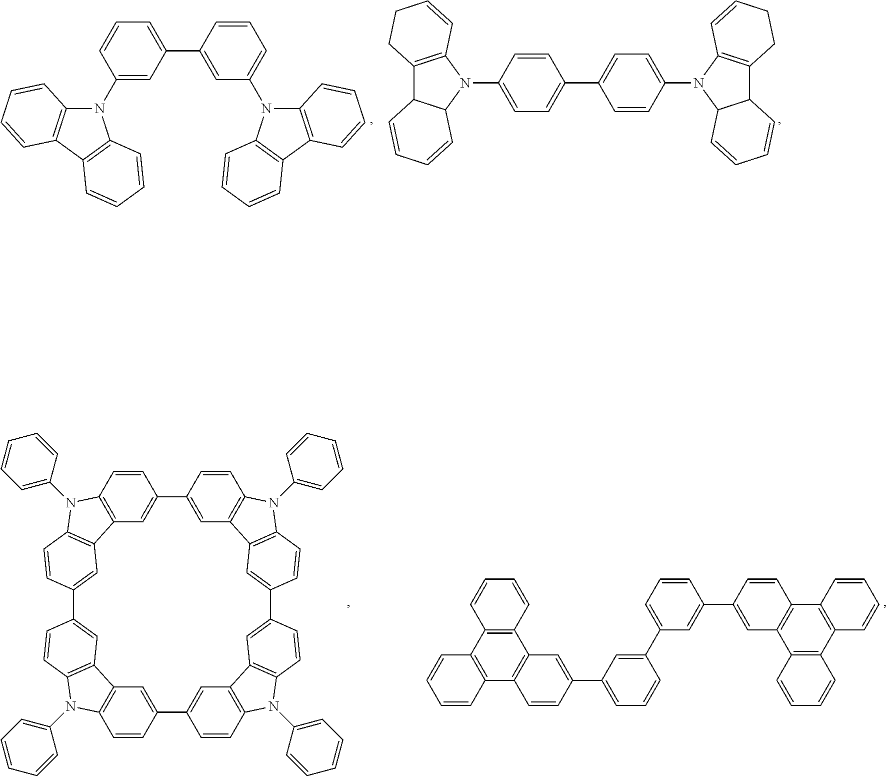

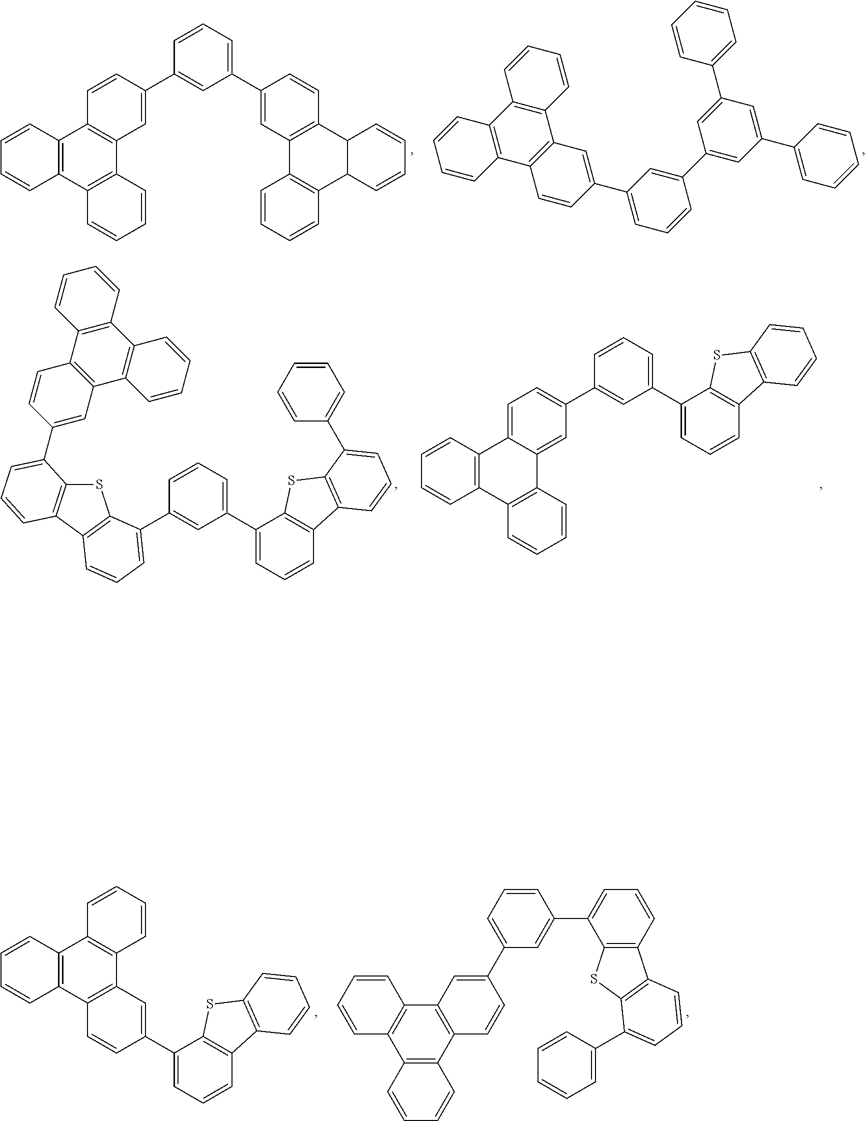

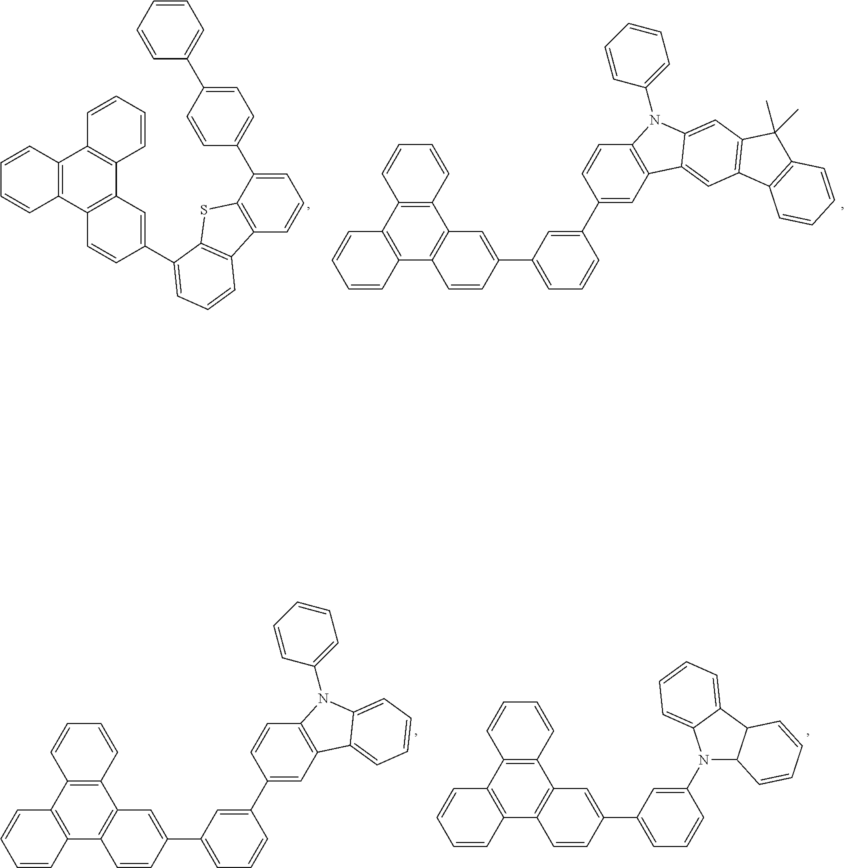 [SMILES: c1ccc(-c2ccc(-c3cccc4c3sc3c(-c5ccc6c7ccccc7c7ccccc7c6c5)cccc34)cc2)cc1 ; CC1(C)c2ccccc2-c2cc3c4cc(-c5cccc(-c6ccc7c8ccccc8c8ccccc8c7c6)c5)ccc4n(-c4ccccc4)c3cc21 ; c1ccc(-n2c3ccccc3c3cc(-c4cccc(-c5ccc6c7ccccc7c7ccccc7c6c5)c4)ccc32)cc1 ; C1=CC2c3ccccc3N(c3cccc(-c4ccc5c6ccccc6c6ccccc6c5c4)c3)C2C=C1]

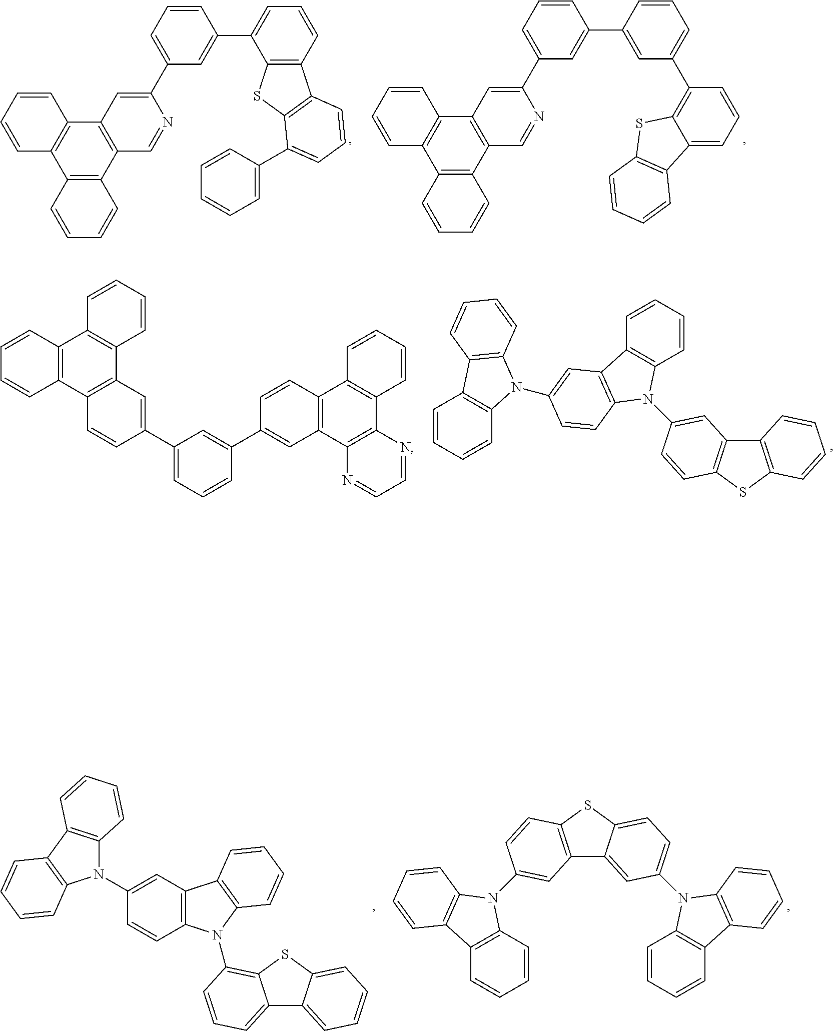

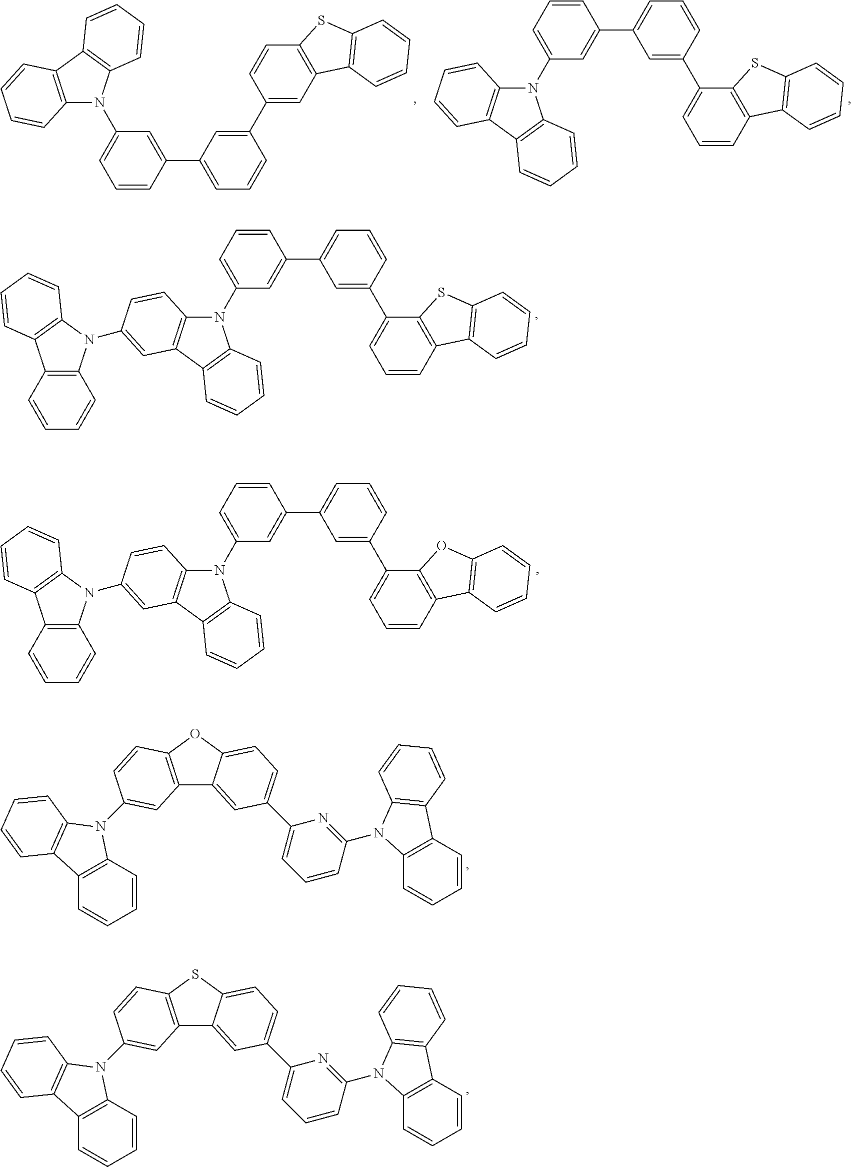

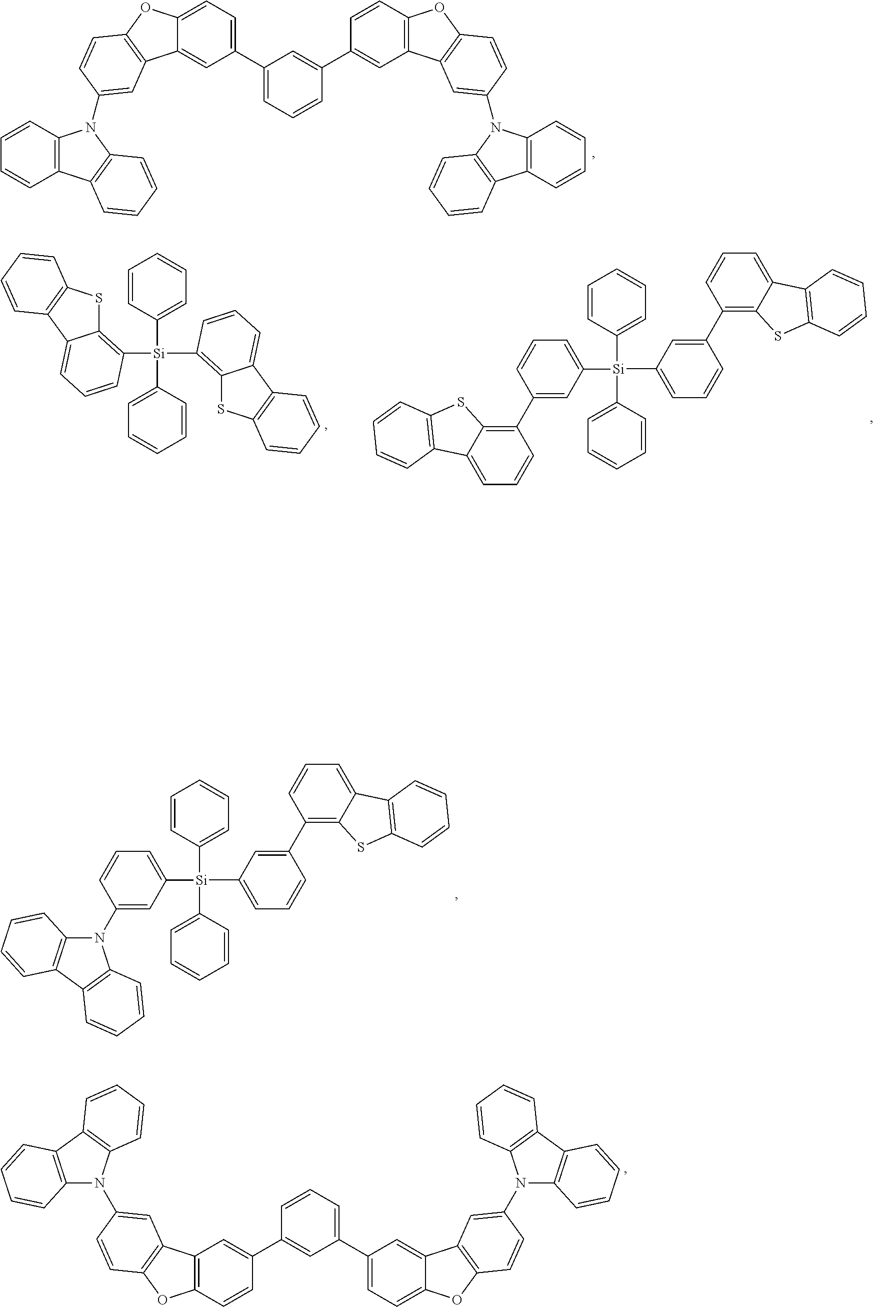

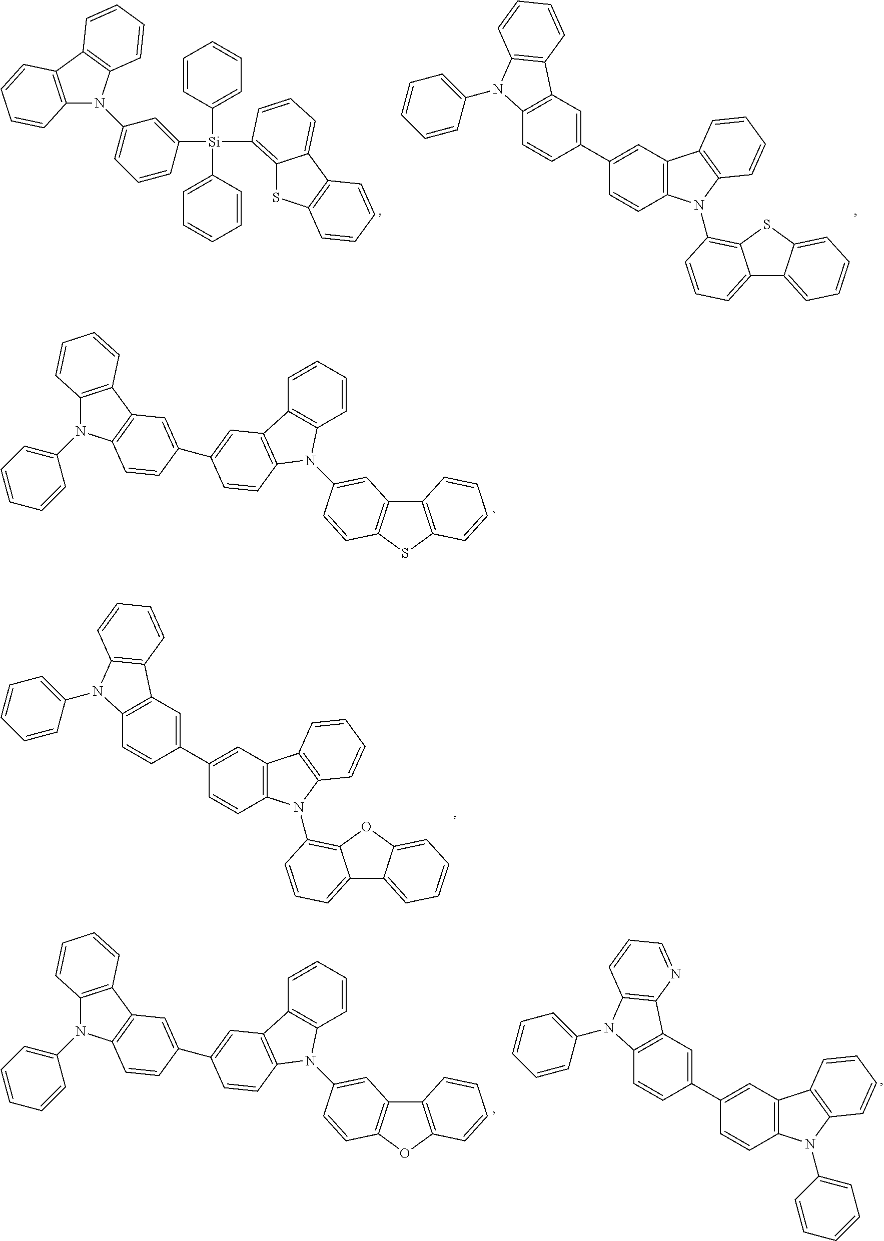 [SMILES: c1ccc([Si](c2ccccc2)(c2cccc(-n3c4ccccc4c4ccccc43)c2)c2cccc3c2sc2ccccc23)cc1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ncccc4n5-c4ccccc4)ccc32)cc1]

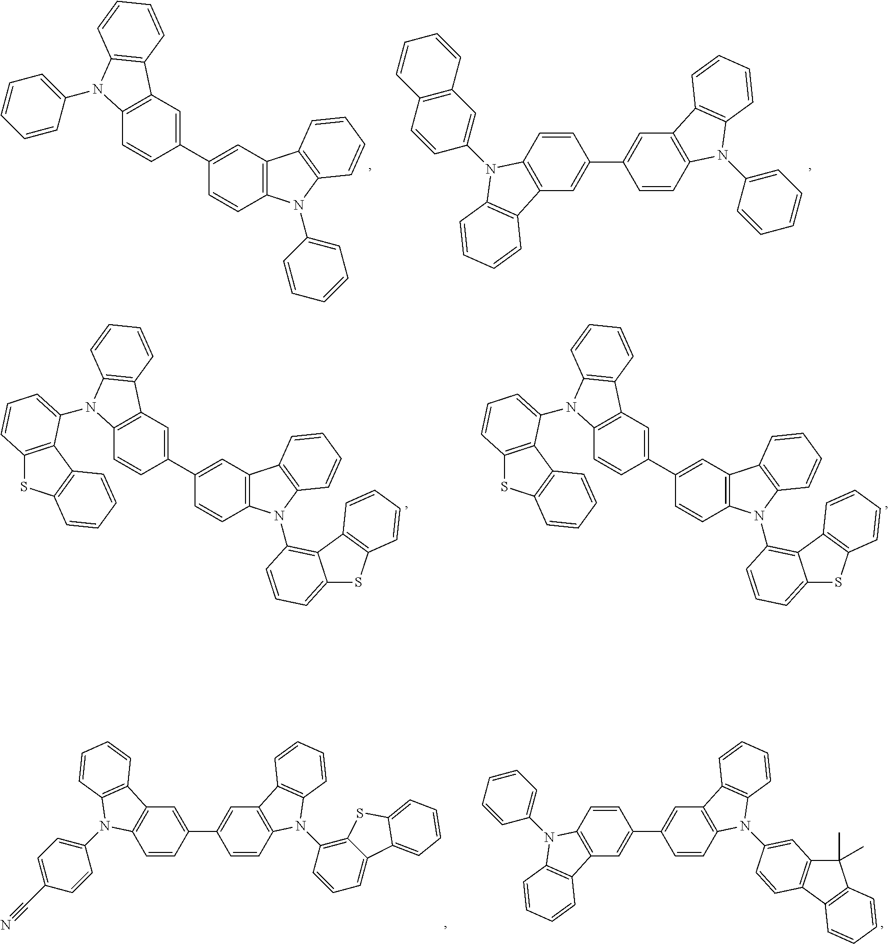 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5ccccc5c4)ccc32)cc1 ; c1ccc2c(c1)sc1cccc(-n3c4ccccc4c4cc(-c5ccc6c(c5)c5ccccc5n6-c5cccc6sc7ccccc7c56)ccc43)c12 ; c1ccc2c(c1)sc1cccc(-n3c4ccccc4c4cc(-c5ccc6c(c5)c5ccccc5n6-c5cccc6sc7ccccc7c56)ccc43)c12 ; N#Cc1ccc(-n2c3ccccc3c3cc(-c4ccc5c(c4)c4ccccc4n5-c4cccc5c4sc4ccccc45)ccc32)cc1 ; CC1(C)c2ccccc2-c2ccc(-n3c4ccccc4c4cc(-c5ccc6c(c5)c5ccccc5n6-c5ccccc5)ccc43)cc21]

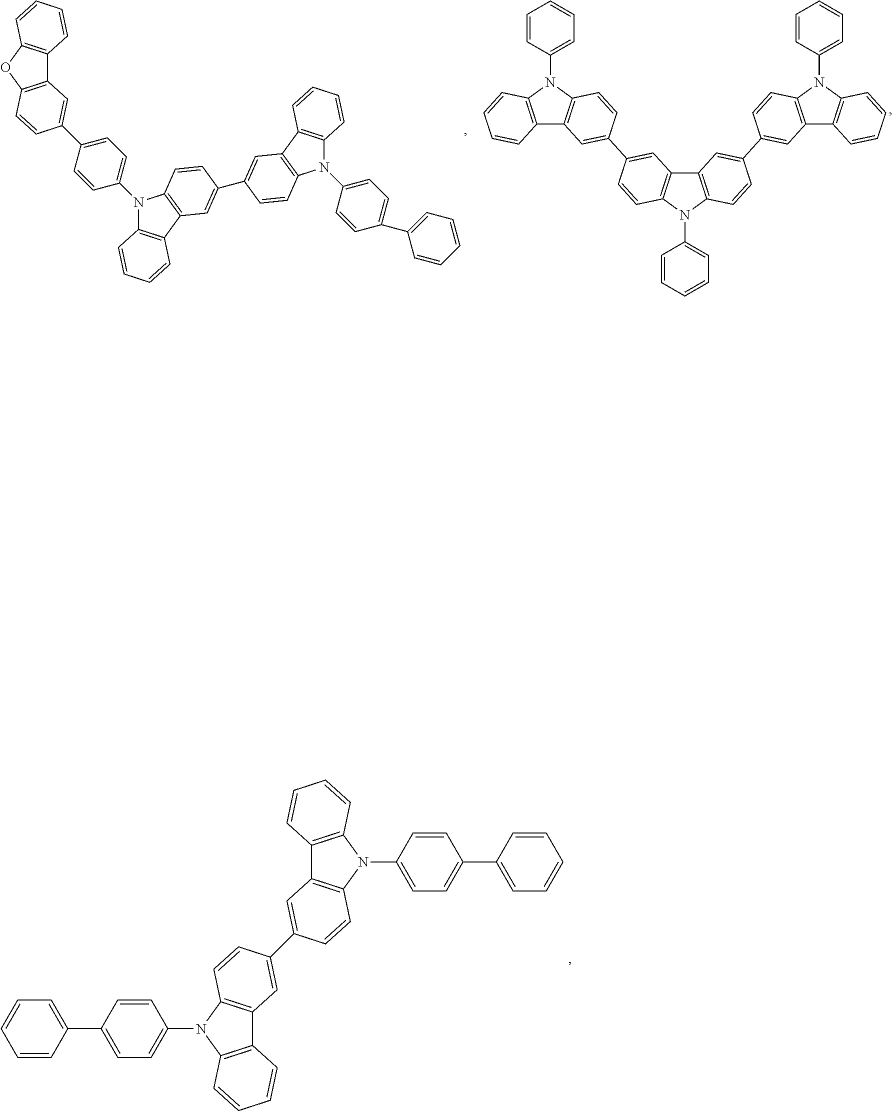 [SMILES: c1ccc(-c2ccc(-n3c4ccccc4c4cc(-c5ccc6c(c5)c5ccccc5n6-c5ccc(-c6ccc7oc8ccccc8c7c6)cc5)ccc43)cc2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

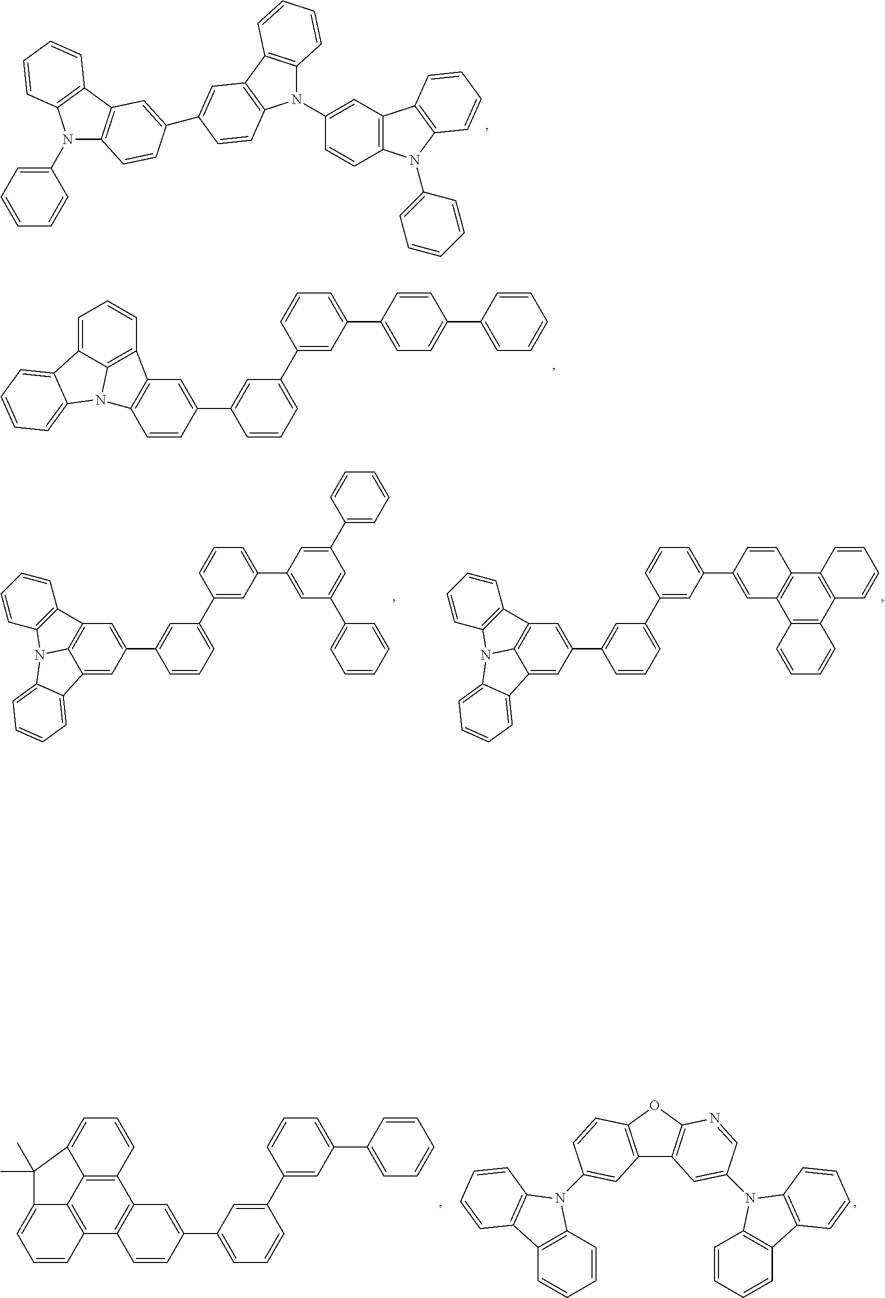

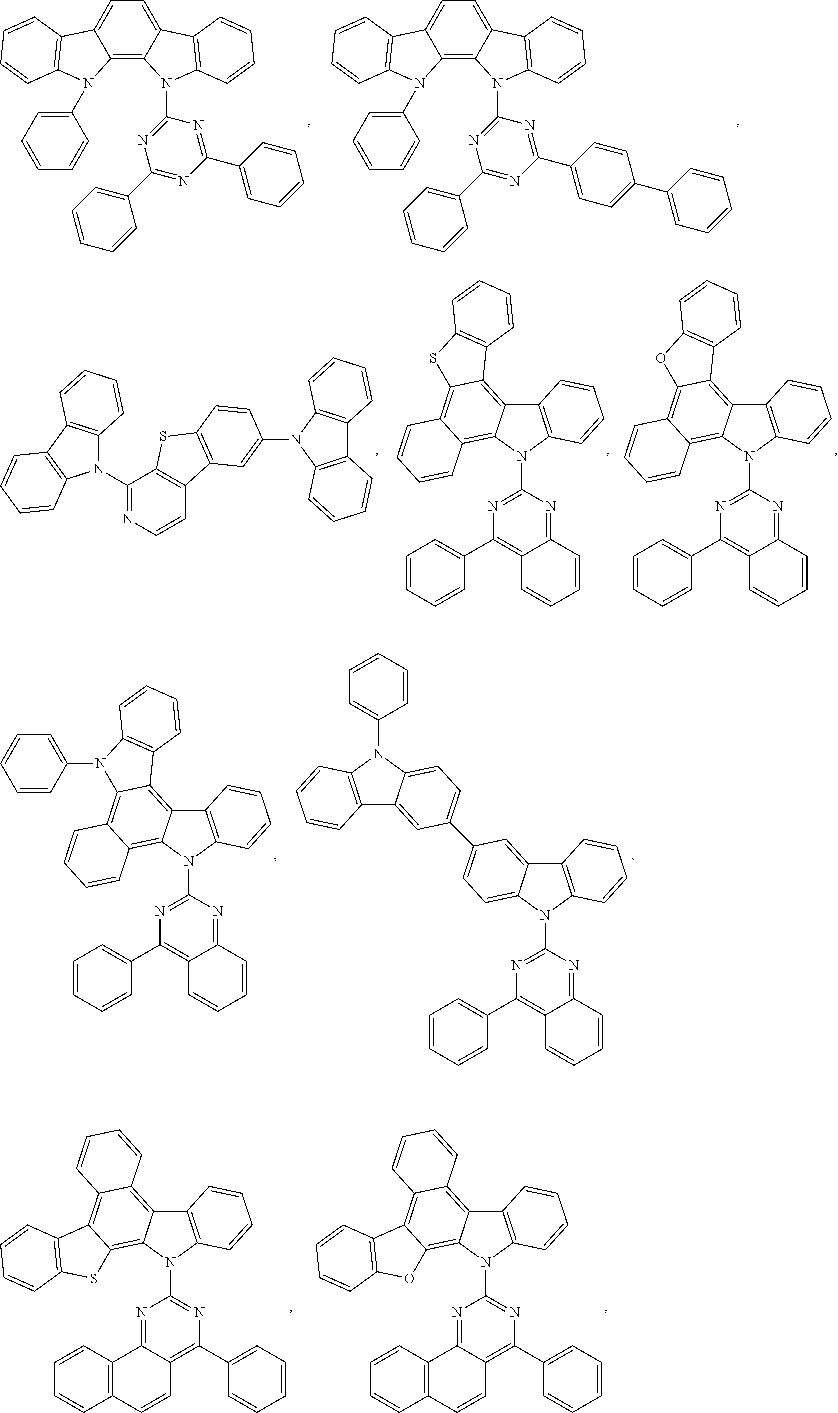

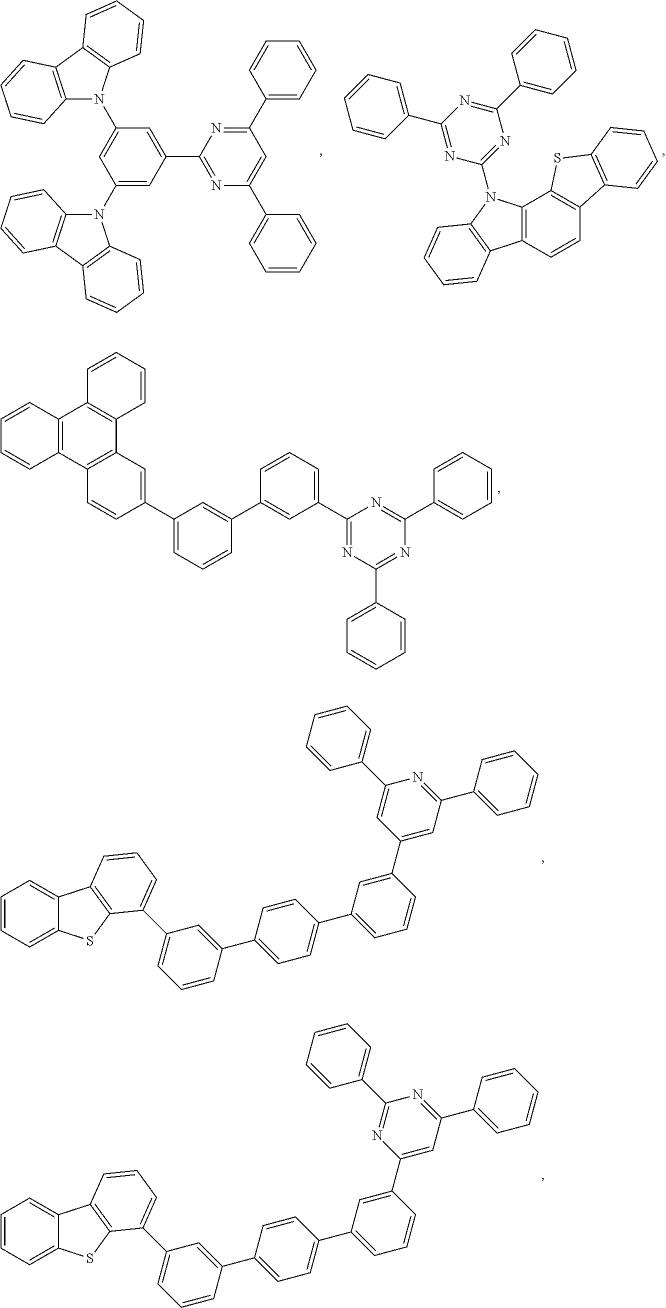

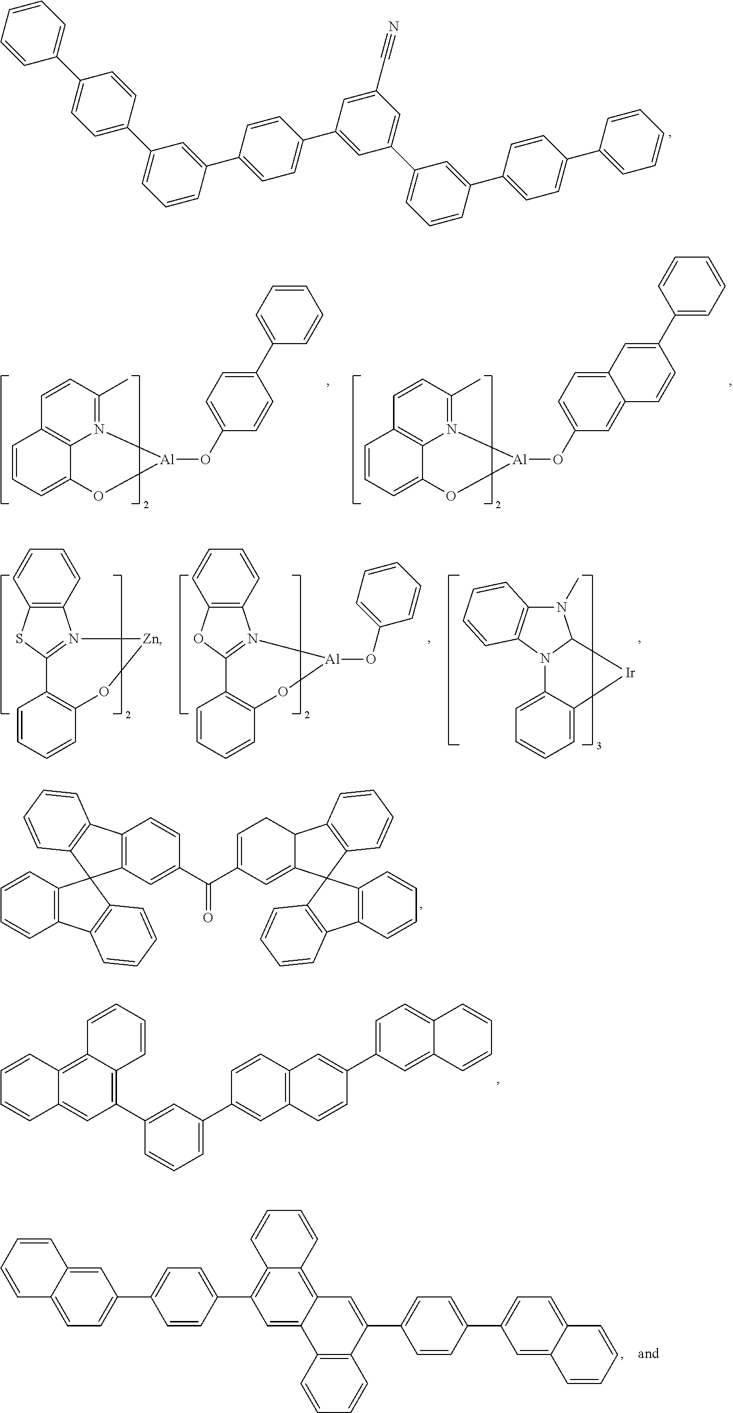

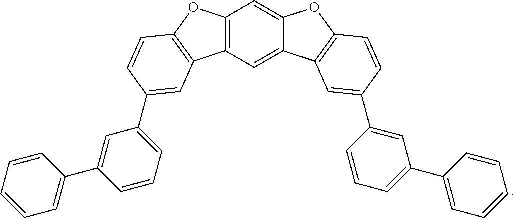 [SMILES: c1ccc(-c2cccc(-c3ccc4oc5cc6oc7ccc(-c8cccc(-c9ccccc9)c8)cc7c6cc5c4c3)c2)cc1]

Additional suitable hosts include, but are not limited to, mCP (1,3-bis(carbazol-9-yl)benzene), mCPy (2,6-bis(N-carbazolyl)pyridine), TCP (1,3,5-tris(carbazol-9-yl)benzene), TCTA (4,4′,4″-tris(carbazol-9-yl)triphenylamine), TPBi (1,3,5-tris(l-phenyl-1-H-benzimidazol-2-yl)benzene), mCBP (3,3-di(9H-carbazol-9-yl)biphenyl), pCBP (4,4′-bis(carbazol-9-yl)biphenyl), CDBP (4,4′-bis(9-carbazolyl)-2,2′-dimethylbiphenyl), DMFL-CBP (4,4′-bis(carbazol-9-yl)-9,9-dimethylfluorene), FL-4CBP (4,4′-bis(carbazol-9-yl)-9,9-bis(9-phenyl-9H-carbazole)fluorene), FL-2CBP (9,9-bis(4-carbazol-9-yl)phenyl)fluorene, also abbreviated as CPF), DPFL-CBP (4,4′-bis(carbazol-9-yl)-9,9-ditolylfluorene), FL-2CBP (9,9-bis(9-phenyl-9H-carbazole)fluorene), Spiro-CBP (2,2′,7,7′-tetrakis(carbazol-9-yl)-9,9′-spirobifluorene), ADN (9,10-di(naphth-2-yl)anthracene), TBADN (3-tert-butyl-9,10-di(naphth-2-yl)anthracene), DPVBi (4,4′-bis(2,2-diphenylethen-1-yl)-4,4′-dimethylphenyl), p-DMDPVBi (4,4′-bis(2,2-diphenylethen-1-yl)-4,4′-dimethylphenyl), TDAF (tert(9,9-diarylfluorene)), BSBF (2-(9,9′-spirobifluoren-2-yl)-9,9′-spirobifluorene), TSBF (2,7-bis(9,9′-spirobifluoren-2-yl)-9,9′-spirobifluorene), BDAF (bis(9,9-diarylfluorene)), p-TDPVBi (4,4′-bis(2,2-diphenylethen-1-yl)-4,4′-di-(tert-butyl)phenyl), TPB3 (1,3,5-tri(pyren-1-yl)benzene, PBD (2-(4-biphenylyl)-5-(4-tert-butylphenyl)-1,3,4-oxadiazole), BCP (2,9-dimethyl-4,7-diphenyl-1,10-phenanthroline), BP-OXD-Bpy (6,6′-bis[5-(biphenyl-4-yl)-1,3,4-oxadiazo-2-yl]-2,2′-bipyridyl), NTAZ (4-(naphth-1-yl)-3,5-diphenyl-4H-1,2,4-triazole), Bpy-OXD (1,3-bis[2-(2,2′-bipyrid-6-yl)-1,3,4oxadiazo-5-yl]benzene), BPhen (4,7-diphenyl-1,10-phenanthroline), TAZ (3-(4-biphenylyl)-4-phenyl-5-tert-butylphenyl-1,2,4-triazole), PADN (2-phenyl-9,10-di(naphth-2-yl)anthracene), Bpy-FOXD (2,7-bis[2-(2,2′-bipyrid-6-yl)-1,3,4-oxadiazol-5-yl]-9,9-dimethylfluorene), OXD-7 (1,3-bis[2-(4-tert-butylphenyl)-1,3,4-oxadiazol-5-yl]benzene), HNBphen (2-(naphth-2-yl)-4,7-diphenyl-1,10-phenanthroline), NBphen (2,9-bis(naphth-2-yl)-4,7-diphenyl-1,10-phenanthroline), 3TPYMB (tris(2,4,6-trimethyl-3-(pyrid-3-yl)phenyl)borane), 2-NPIP (1-methyl-2-(4-(naphth-2-yl)phenyl)-1H-imidazo[4,5-f]-[1,10]phenanthroline), Liq (8-hydroxyquinolinolatolithium), and Alq (bis(2-methyl-8-quinolinolate)-4-(phenylphenolato)aluminum), and also of mixtures of the aforesaid substances.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

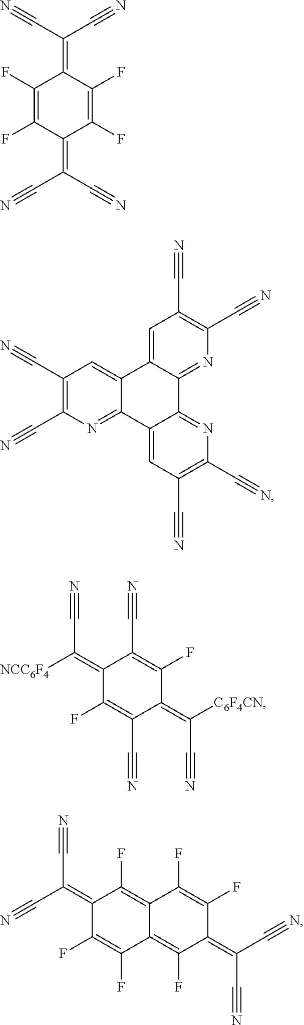

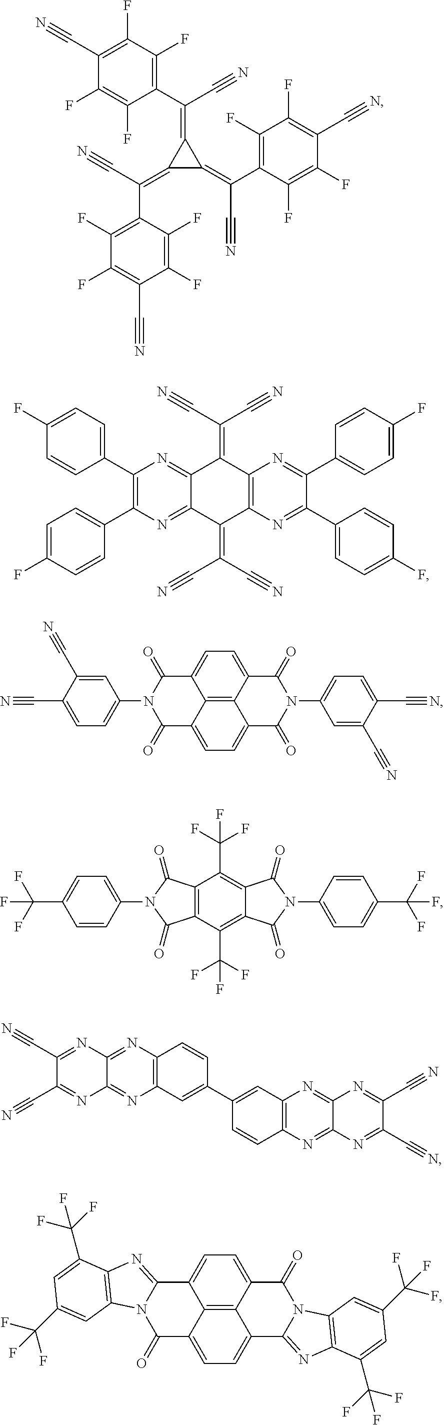

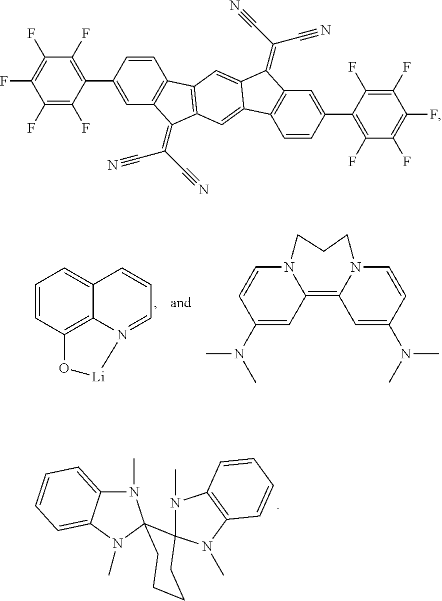

HIL/HTL:

A hole injecting/transporting material to be used in the present invention is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

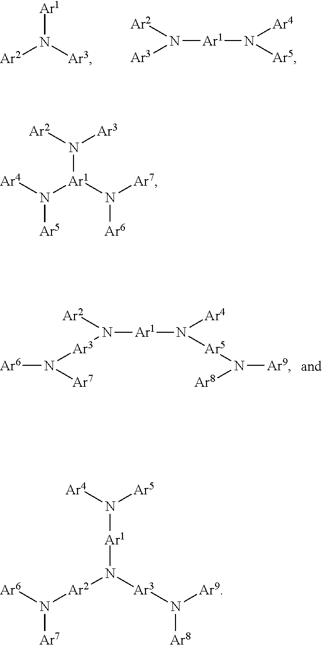

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

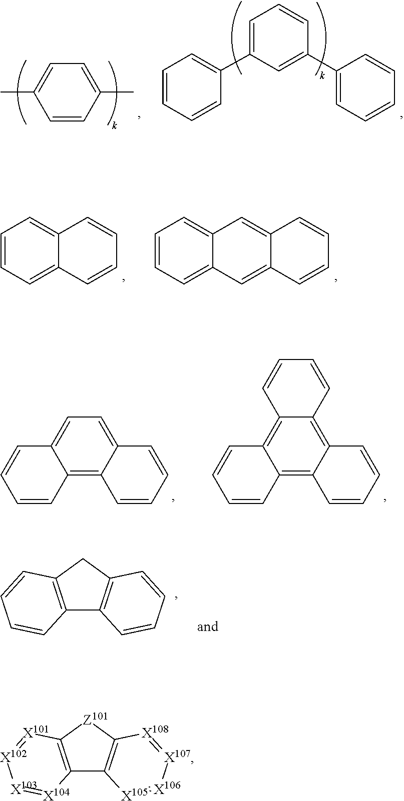

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but are not limited to the following general formula:

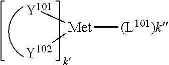

wherein Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, U.S. Ser. No. 06/517,957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

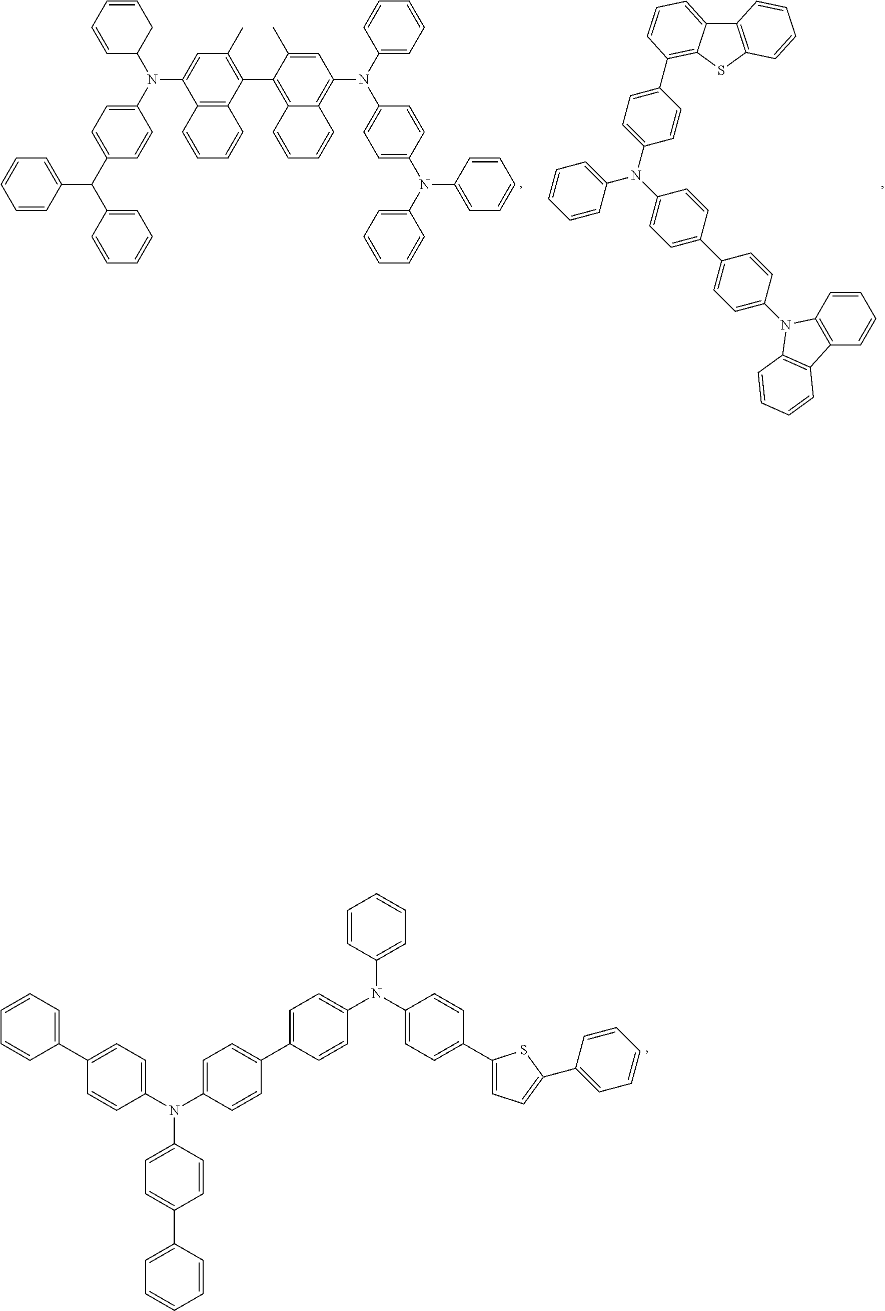

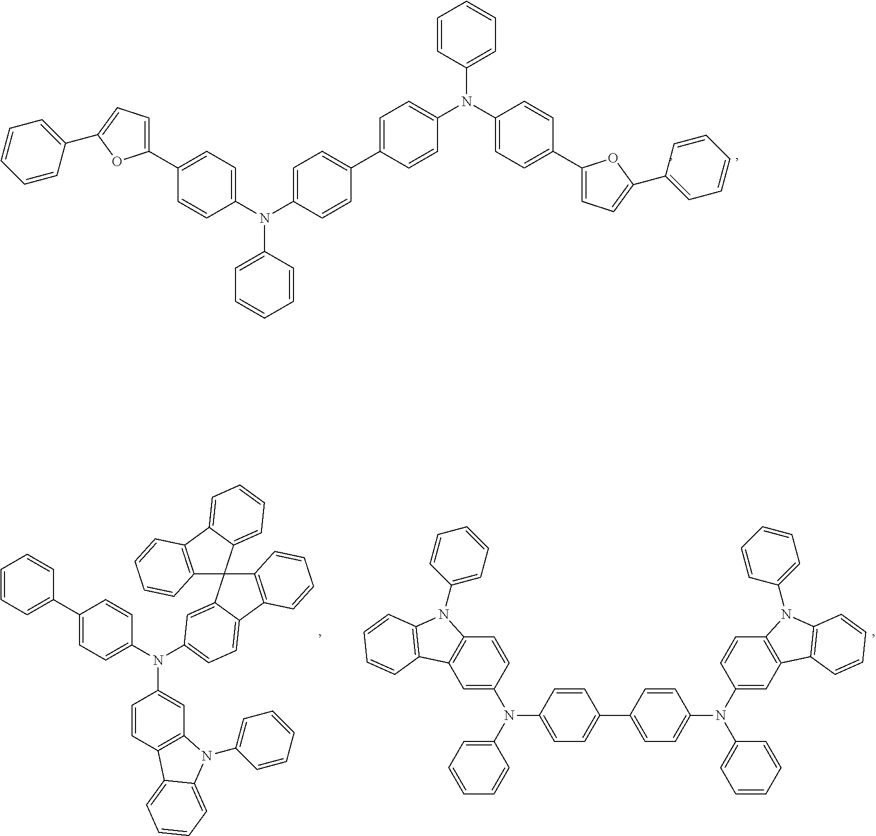 [SMILES: c1ccc(-c2ccc(-c3ccc(N(c4ccccc4)c4ccc(-c5ccc(N(c6ccccc6)c6ccc(-c7ccc(-c8ccccc8)o7)cc6)cc5)cc4)cc3)o2)cc1 ; c1ccc(-c2ccc(N(c3ccc4c(c3)C3(c5ccccc5-c5ccccc53)c3ccccc3-4)c3ccc4c5ccccc5n(-c5ccccc5)c4c3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

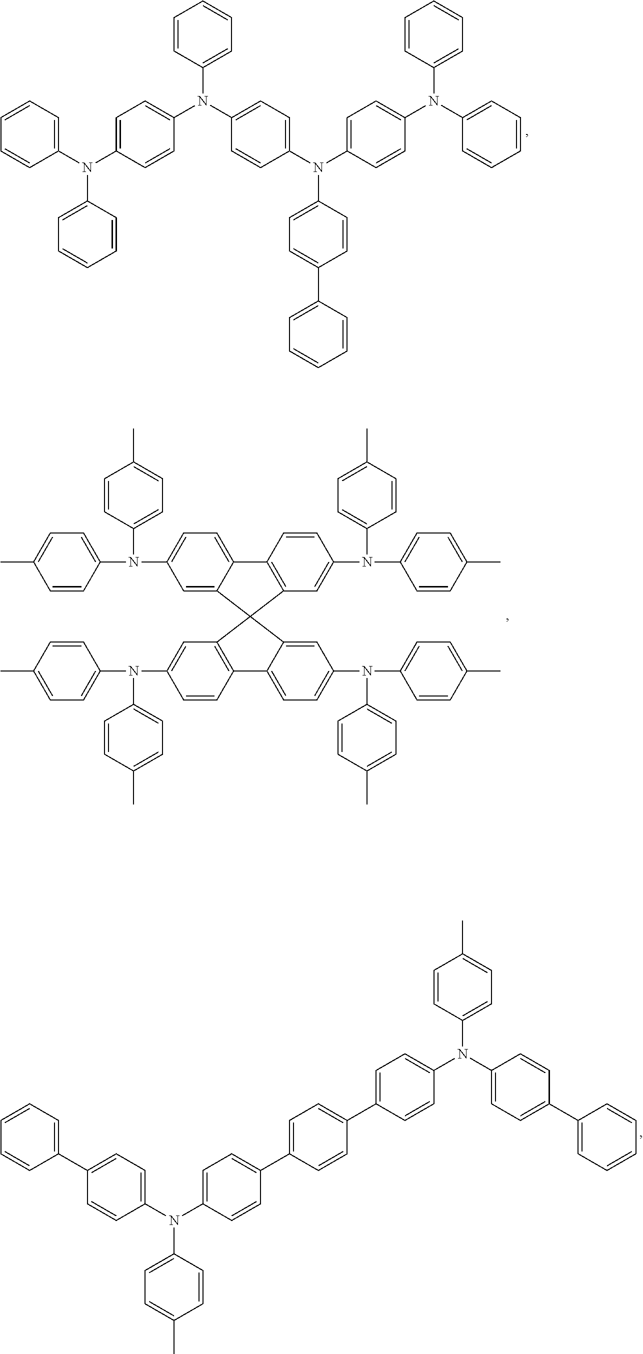

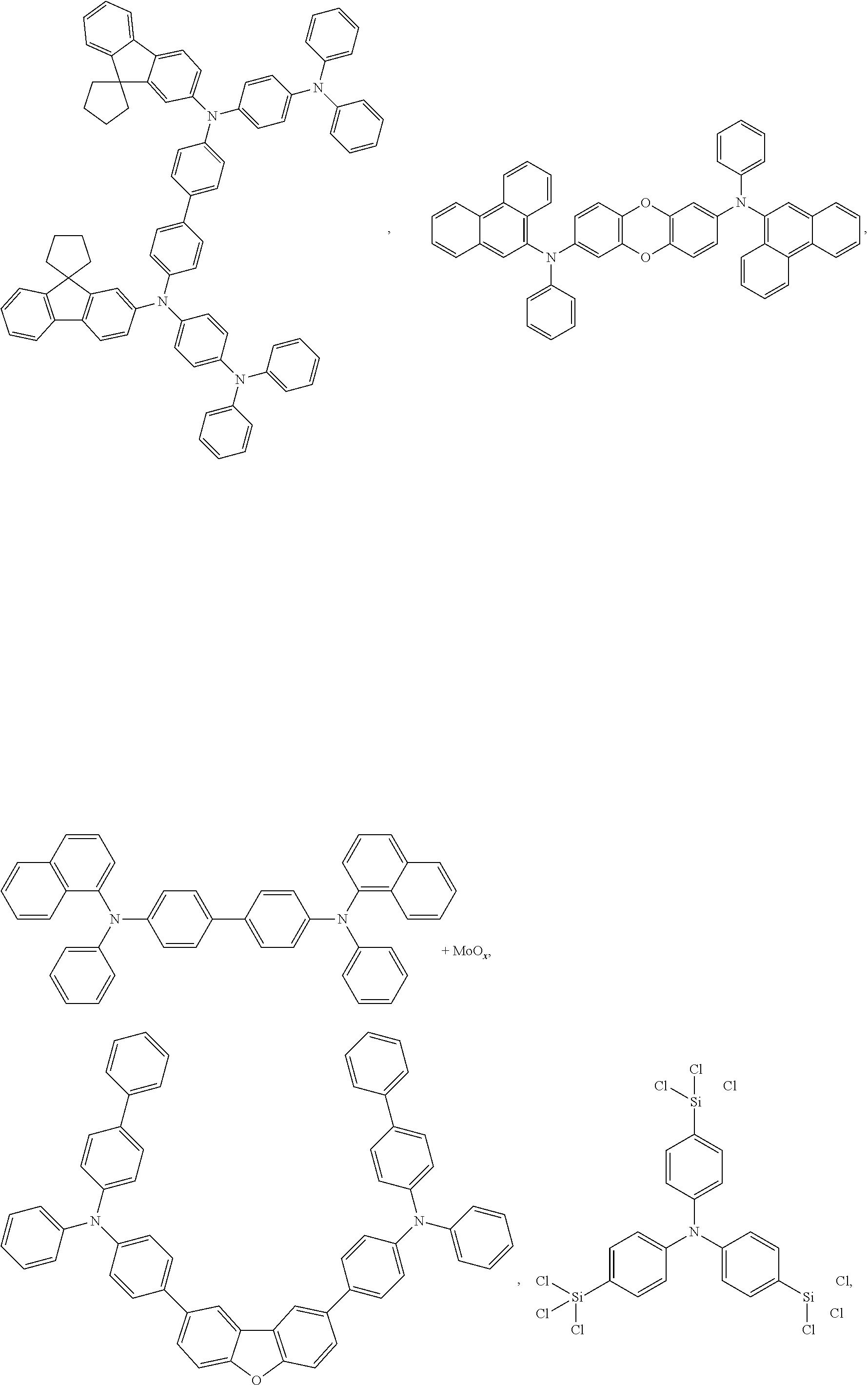

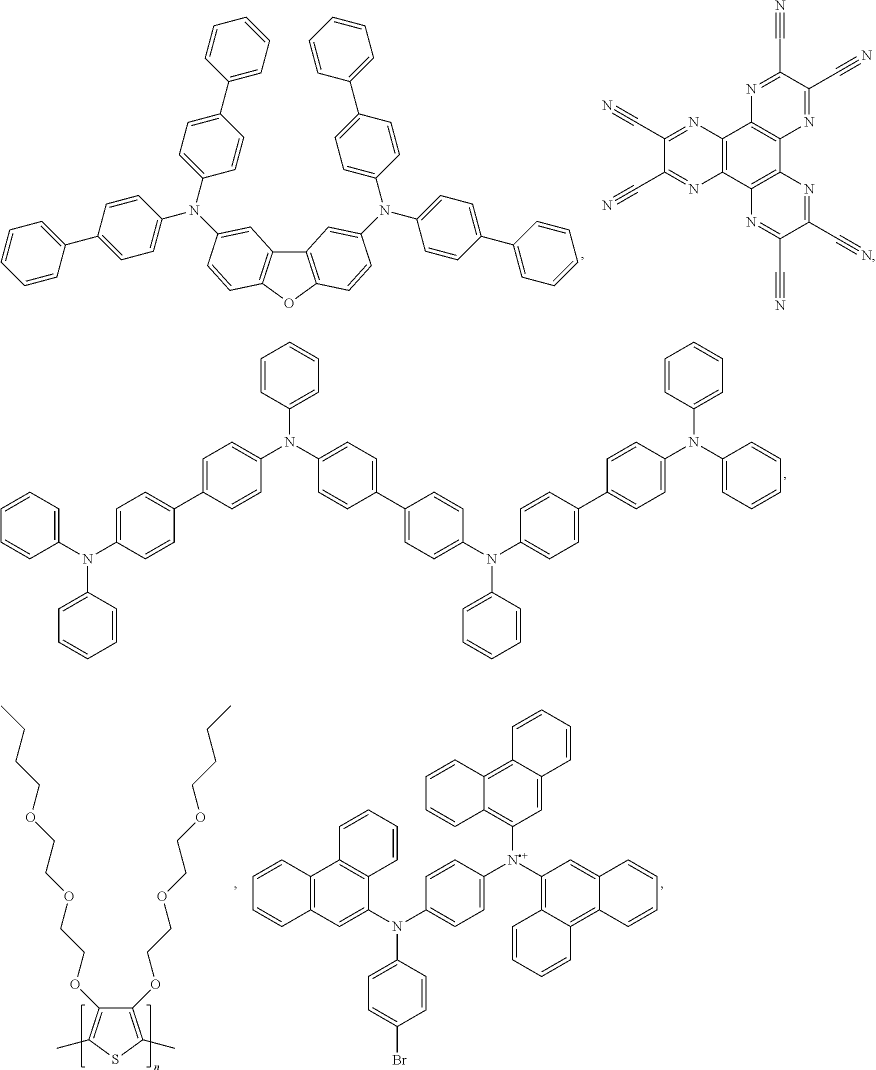

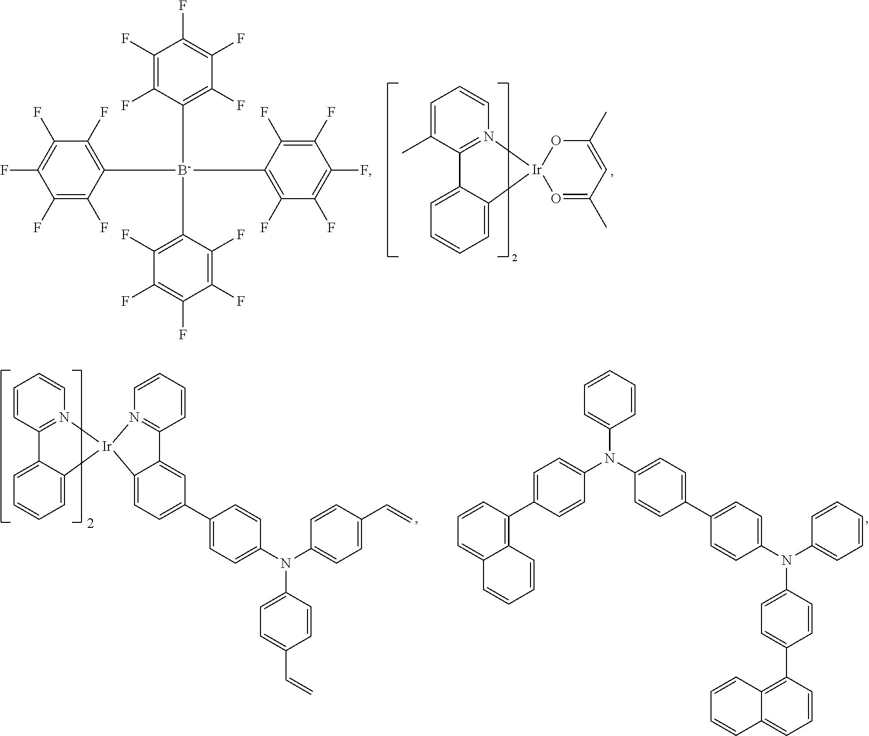

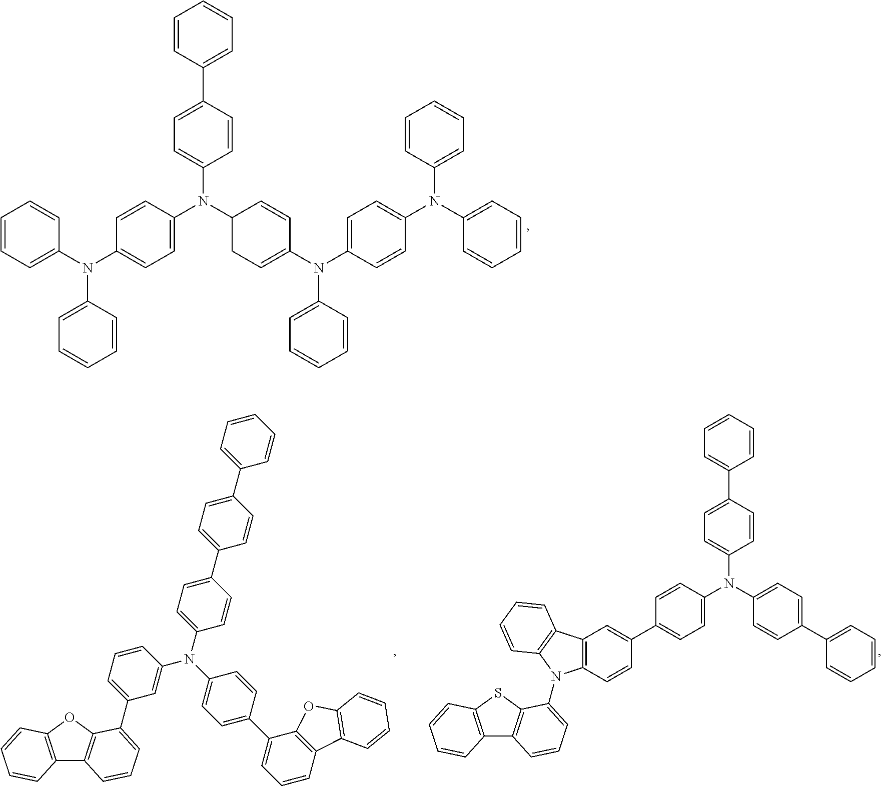 [SMILES: C1=CC(N(c2ccc(-c3ccccc3)cc2)c2ccc(N(c3ccccc3)c3ccccc3)cc2)CC=C1N(c1ccccc1)c1ccc(N(c2ccccc2)c2ccccc2)cc1 ; c1ccc(-c2ccc(-c3ccc(N(c4ccc(-c5cccc6c5oc5ccccc56)cc4)c4cccc(-c5cccc6c5oc5ccccc56)c4)cc3)cc2)cc1 ; c1ccc(-c2ccc(N(c3ccc(-c4ccccc4)cc3)c3ccc(-c4ccc5c(c4)c4ccccc4n5-c4cccc5c4sc4ccccc45)cc3)cc2)cc1]

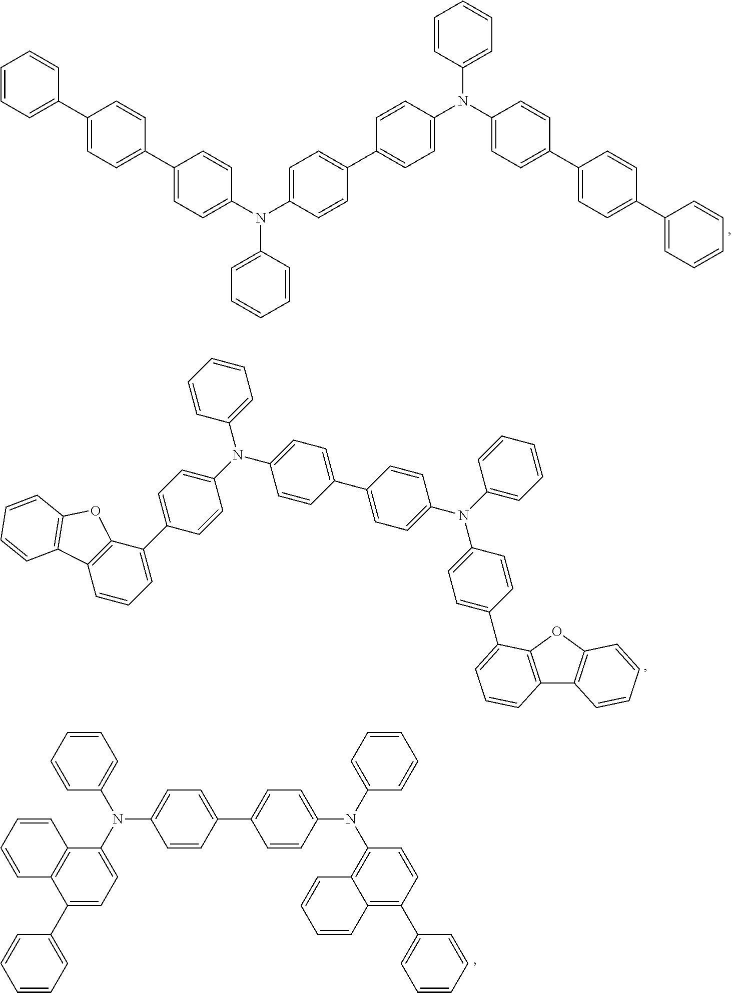 [SMILES: c1ccc(-c2ccc(-c3ccc(N(c4ccccc4)c4ccc(-c5ccc(N(c6ccccc6)c6ccc(-c7ccc(-c8ccccc8)cc7)cc6)cc5)cc4)cc3)cc2)cc1 ; c1ccc(N(c2ccc(-c3ccc(N(c4ccccc4)c4ccc(-c5cccc6c5oc5ccccc56)cc4)cc3)cc2)c2ccc(-c3cccc4c3oc3ccccc34)cc2)cc1 ; c1ccc(-c2ccc(N(c3ccccc3)c3ccc(-c4ccc(N(c5ccccc5)c5ccc(-c6ccccc6)c6ccccc56)cc4)cc3)c3ccccc23)cc1]

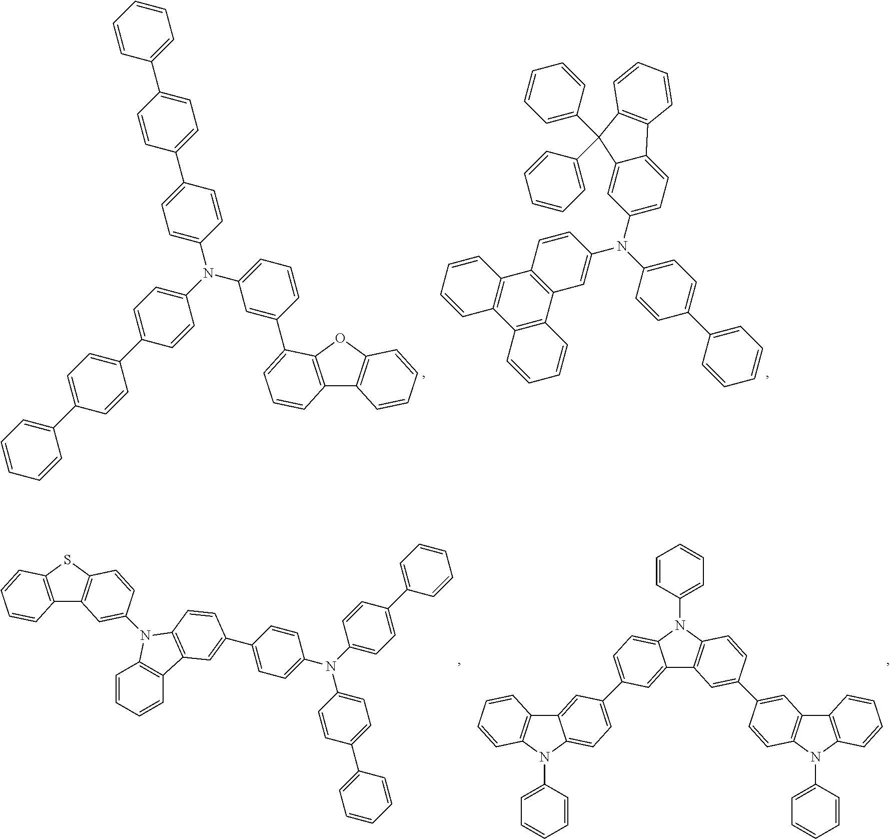 [SMILES: c1ccc(-c2ccc(-c3ccc(N(c4ccc(-c5ccc(-c6ccccc6)cc5)cc4)c4cccc(-c5cccc6c5oc5ccccc56)c4)cc3)cc2)cc1 ; c1ccc(-c2ccc(N(c3ccc4c(c3)C(c3ccccc3)(c3ccccc3)c3ccccc3-4)c3ccc4c5ccccc5c5ccccc5c4c3)cc2)cc1 ; c1ccc(-c2ccc(N(c3ccc(-c4ccccc4)cc3)c3ccc(-c4ccc5c(c4)c4ccccc4n5-c4ccc5sc6ccccc6c5c4)cc3)cc2)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

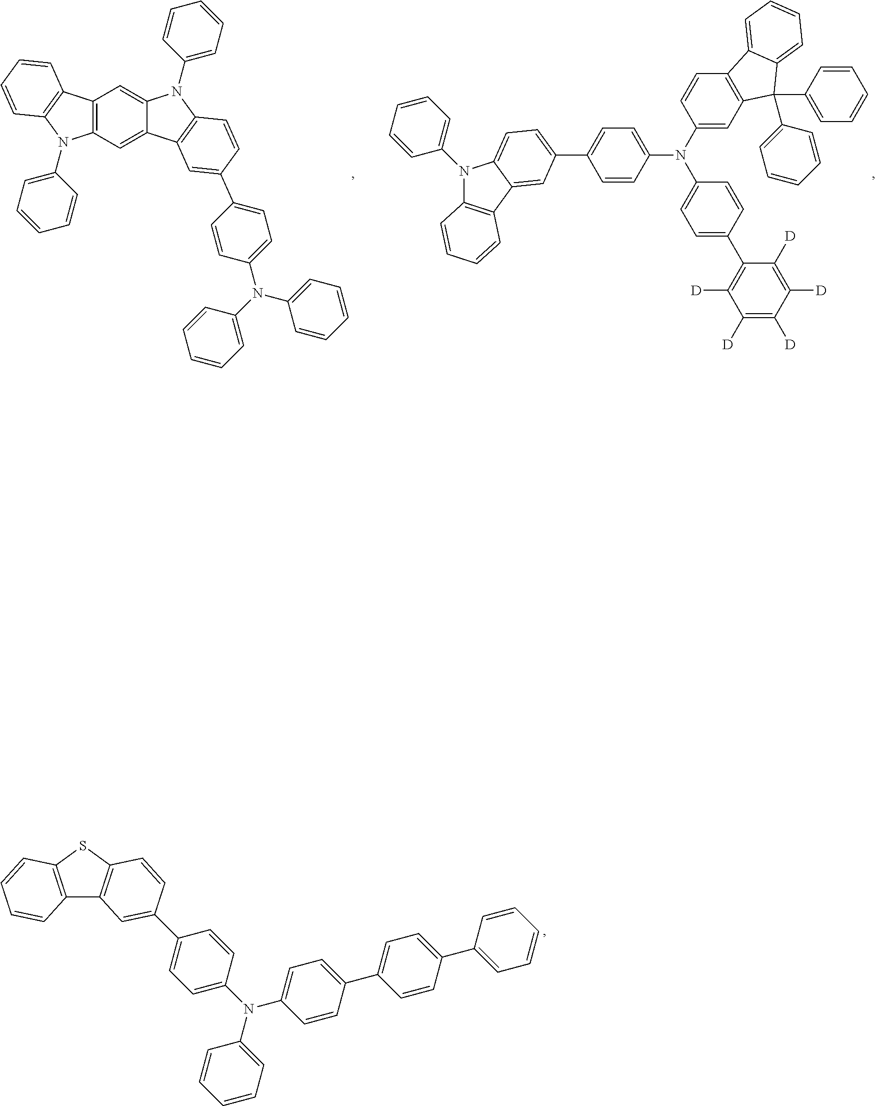 [SMILES: c1ccc(N(c2ccccc2)c2ccc(-c3ccc4c(c3)c3cc5c(cc3n4-c3ccccc3)c3ccccc3n5-c3ccccc3)cc2)cc1 ; [2H]c1c([2H])c([2H])c(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)c([2H])c1[2H] ; c1ccc(-c2ccc(-c3ccc(N(c4ccccc4)c4ccc(-c5ccc6sc7ccccc7c6c5)cc4)cc3)cc2)cc1]

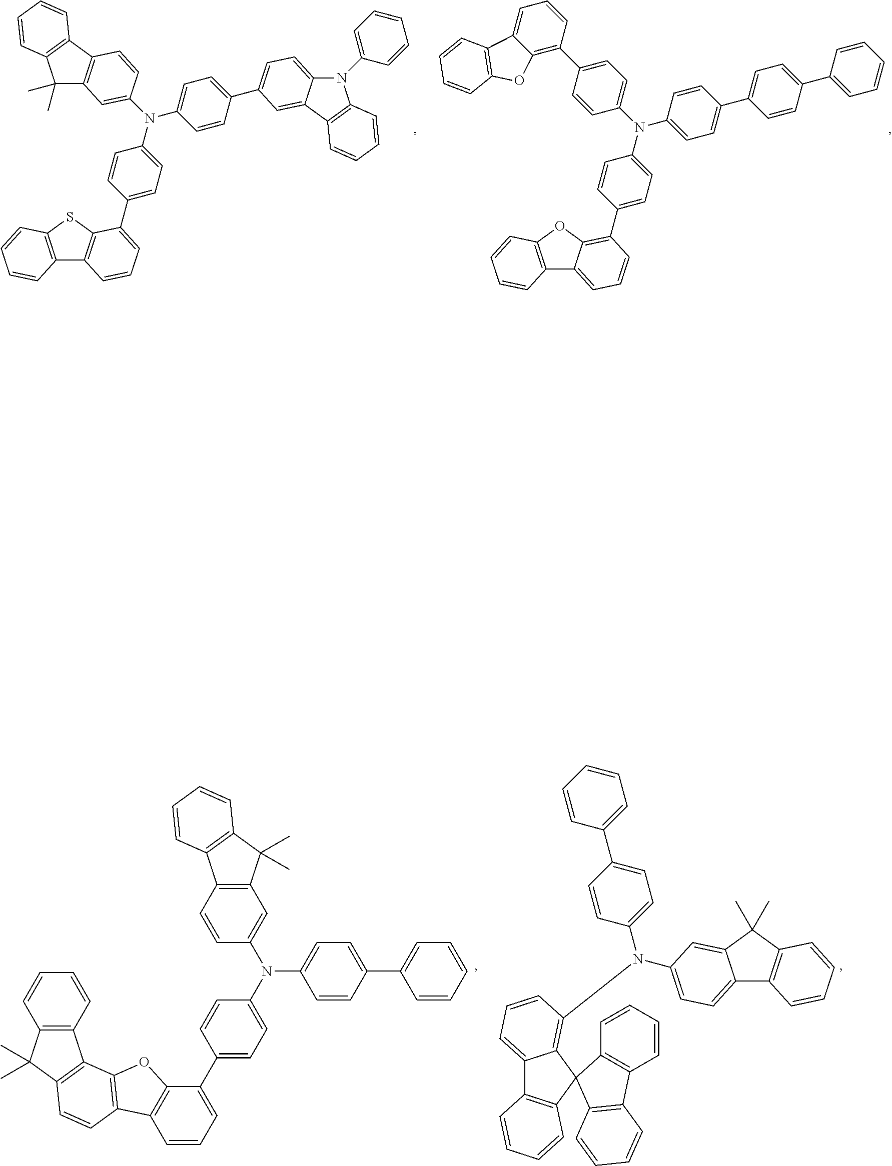

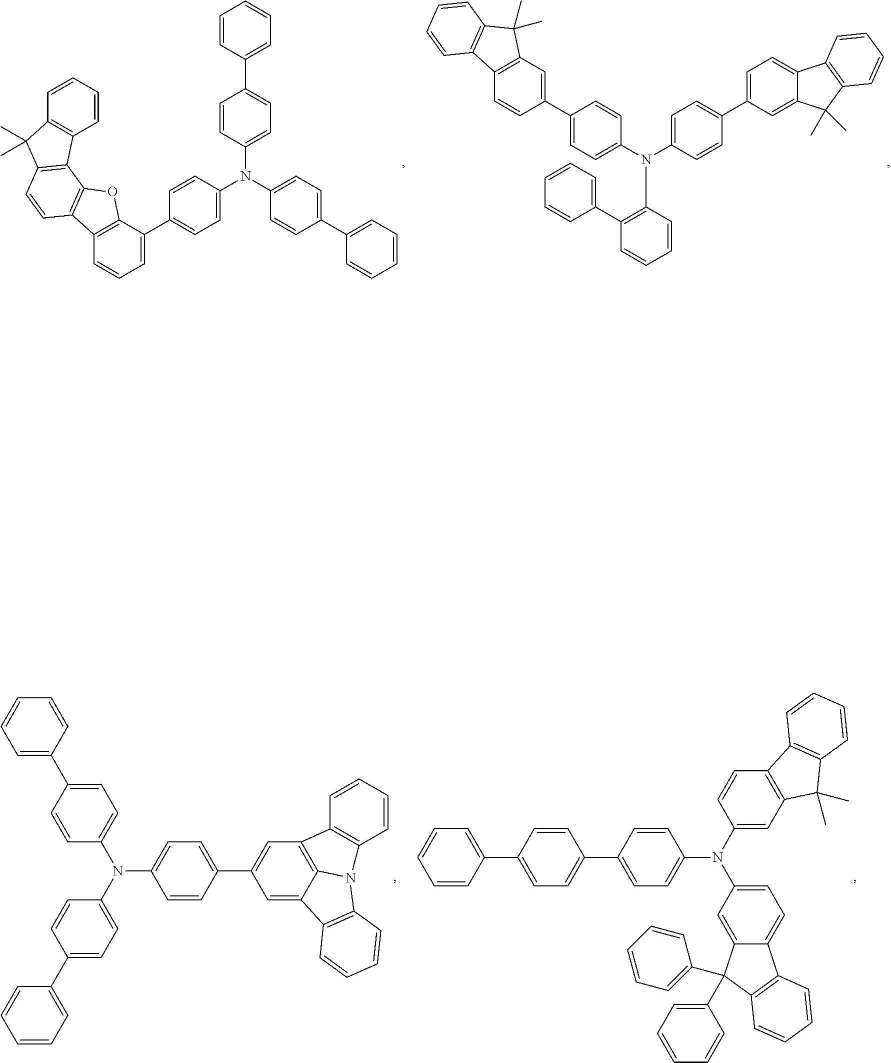

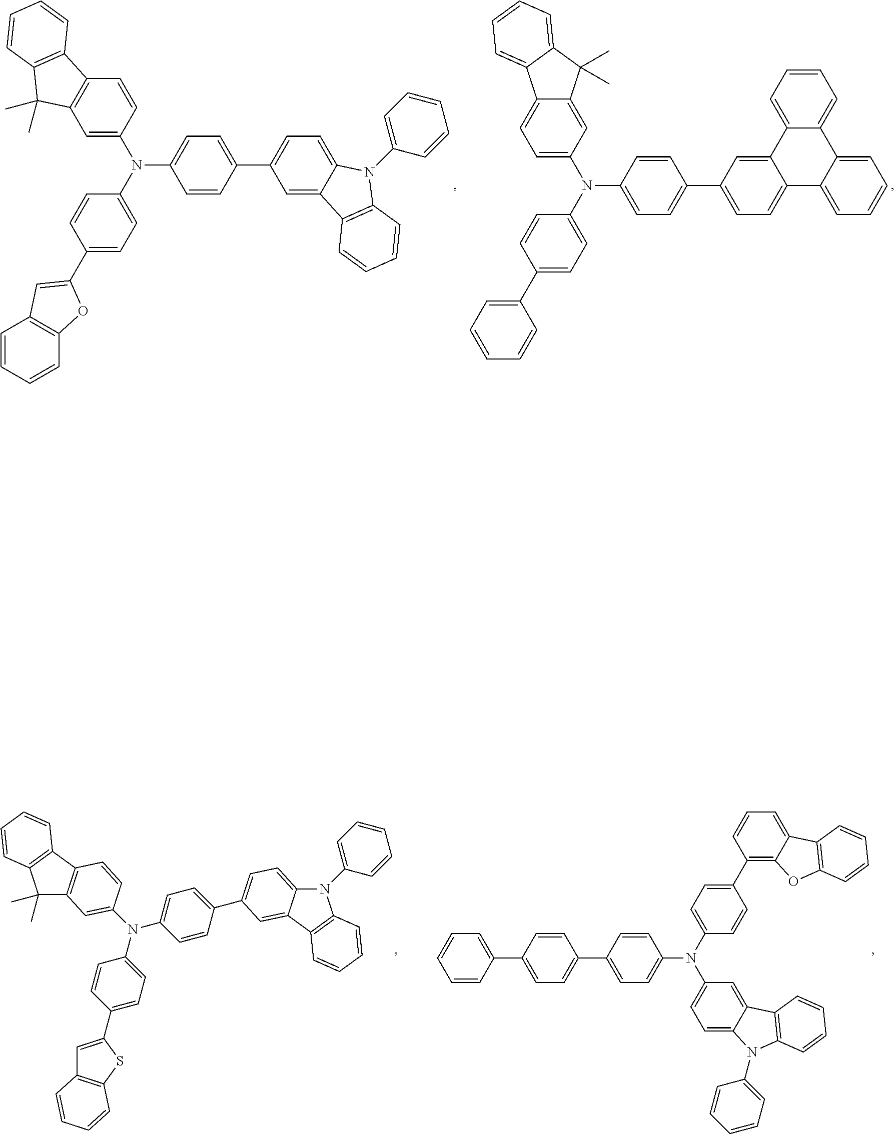 [SMILES: CC1(C)c2ccccc2-c2ccc(N(c3ccc(-c4ccc5c(c4)c4ccccc4n5-c4ccccc4)cc3)c3ccc(-c4cc5ccccc5o4)cc3)cc21 ; CC1(C)c2ccccc2-c2ccc(N(c3ccc(-c4ccccc4)cc3)c3ccc(-c4ccc5c6ccccc6c6ccccc6c5c4)cc3)cc21 ; CC1(C)c2ccccc2-c2ccc(N(c3ccc(-c4ccc5c(c4)c4ccccc4n5-c4ccccc4)cc3)c3ccc(-c4cc5ccccc5s4)cc3)cc21 ; c1ccc(-c2ccc(-c3ccc(N(c4ccc(-c5cccc6c5oc5ccccc56)cc4)c4ccc5c(c4)c4ccccc4n5-c4ccccc4)cc3)cc2)cc1]

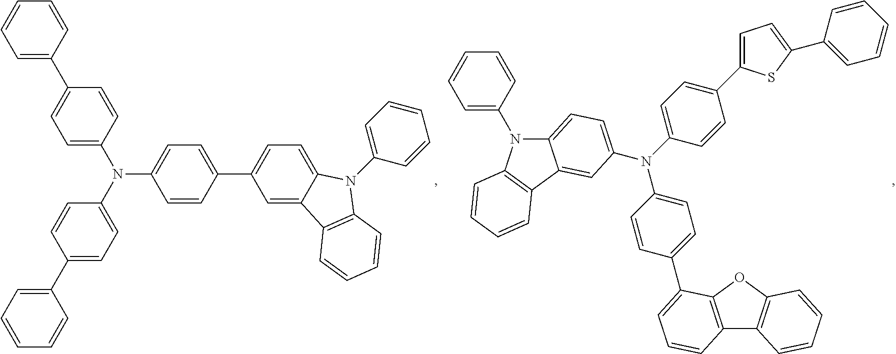

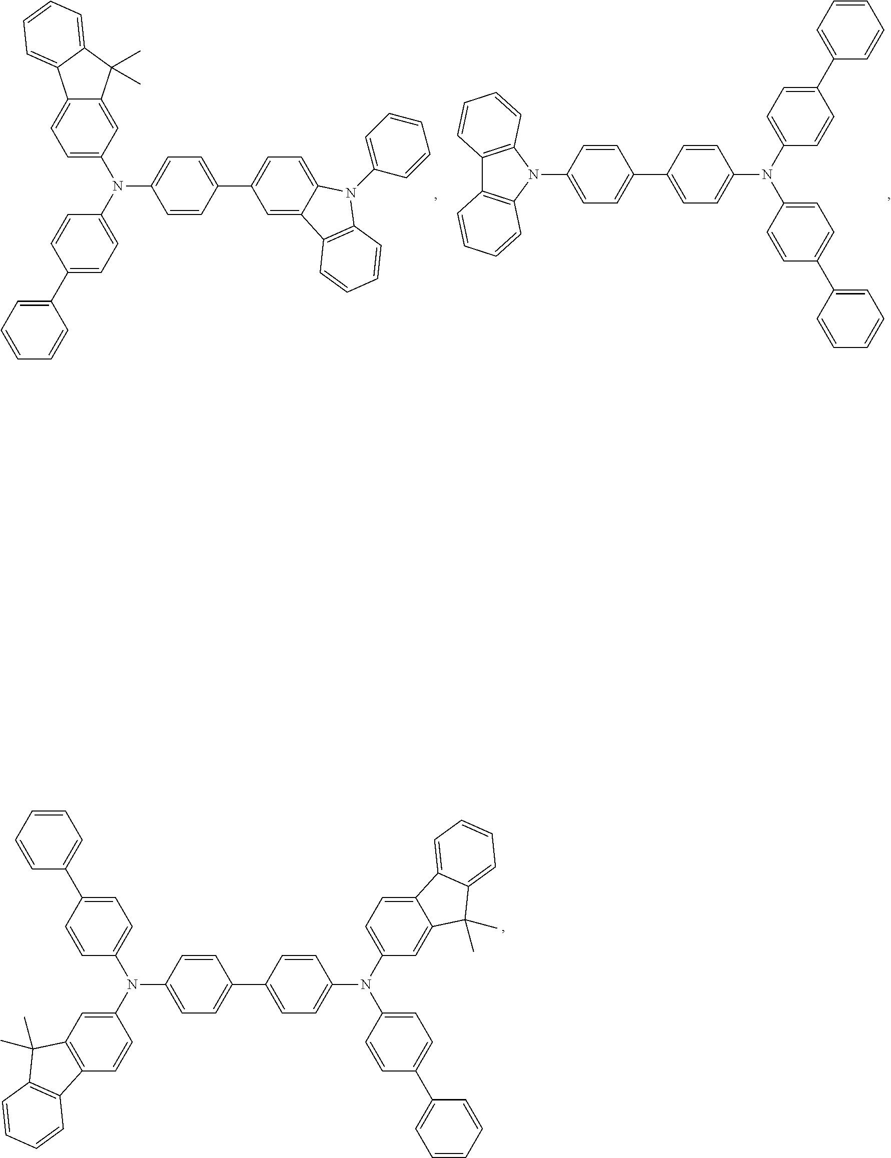

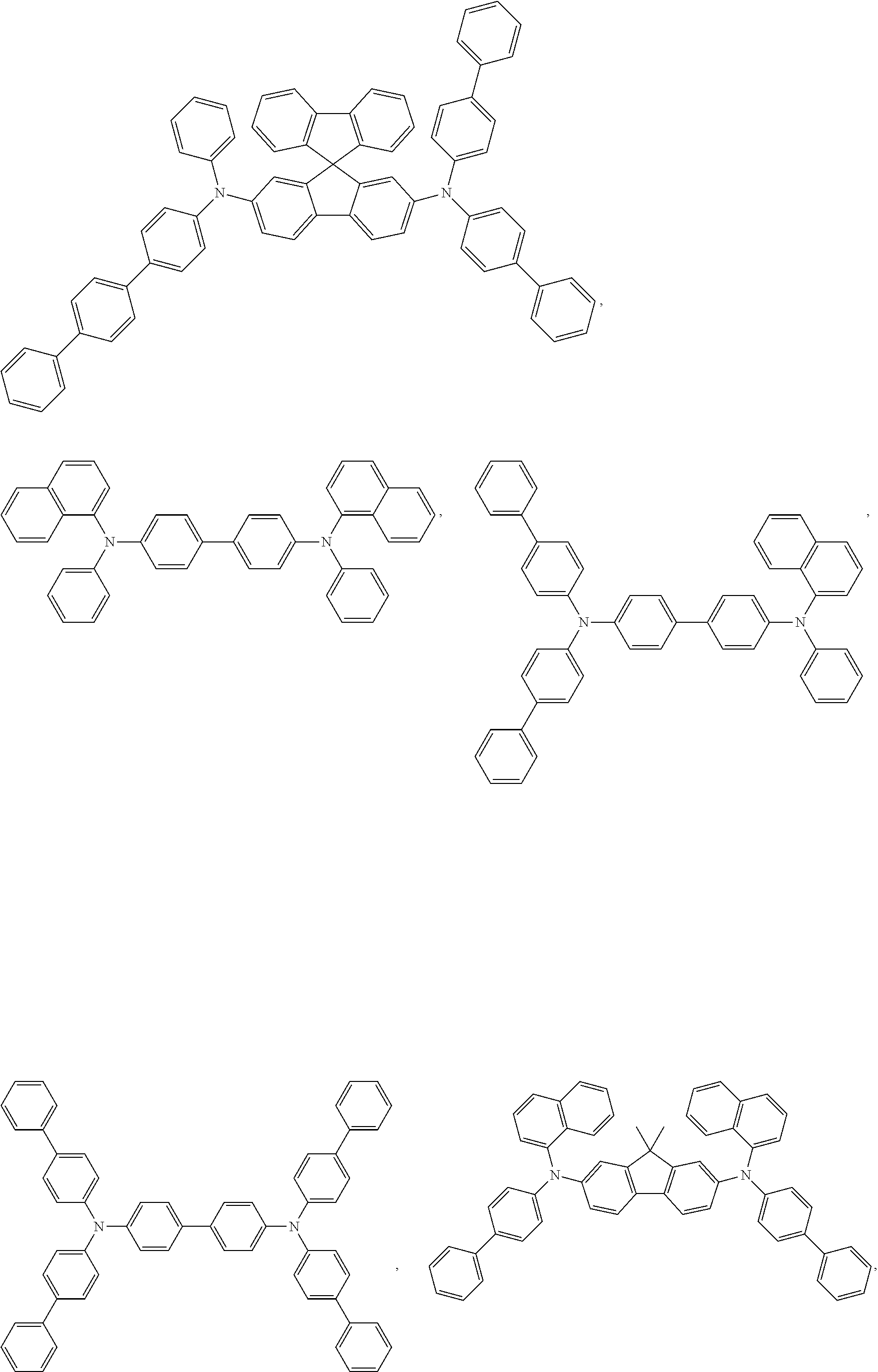

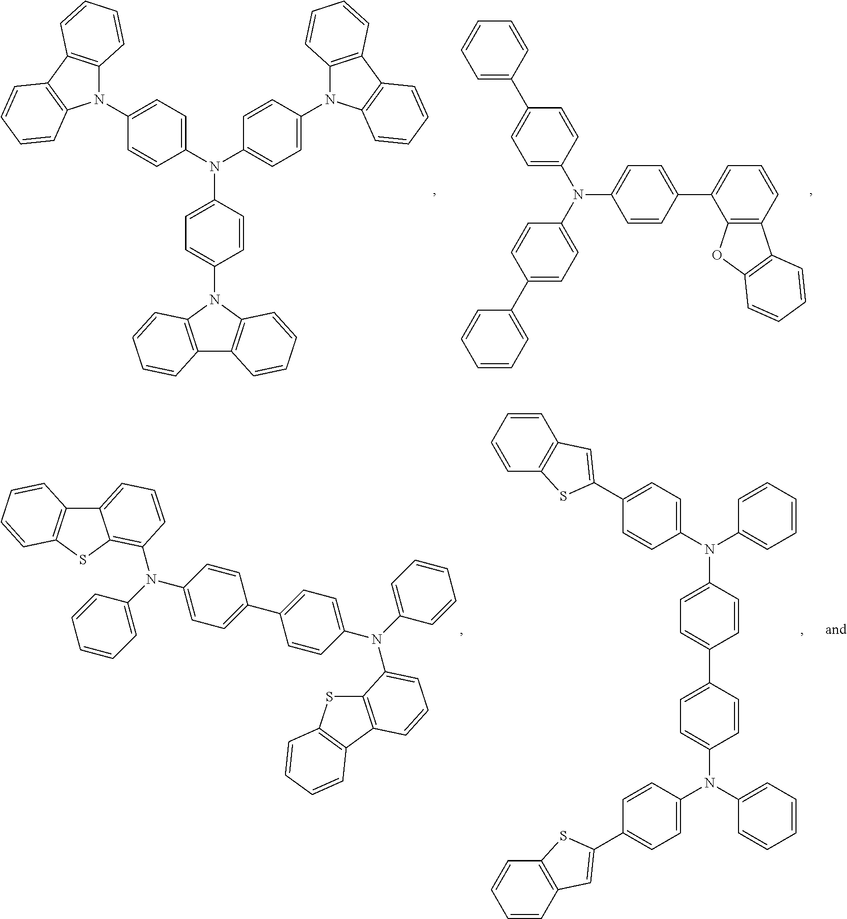

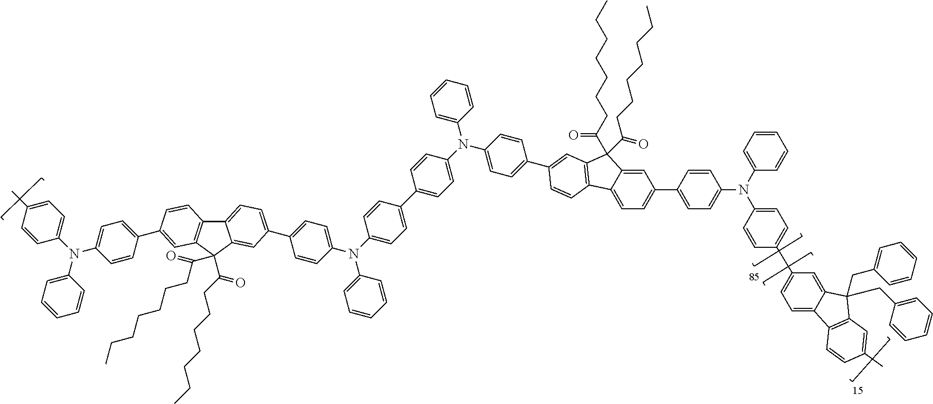

EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

xxxxxxxxxxxxxxxxxxxxxxxxxxxxxxxxxxxx

Additional Emitters:

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Ser. No. 06/699,599, U.S. Ser. No. 06/916,554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

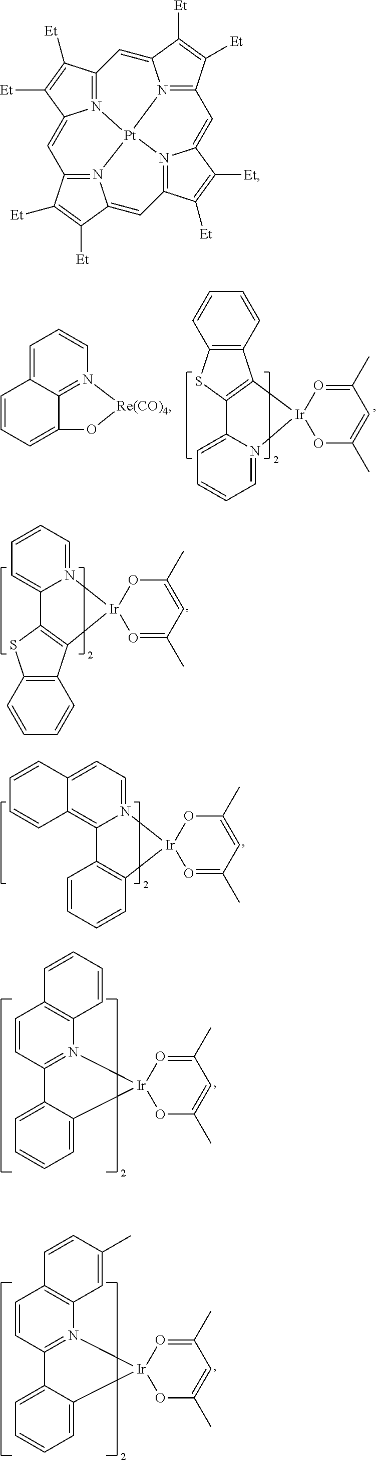

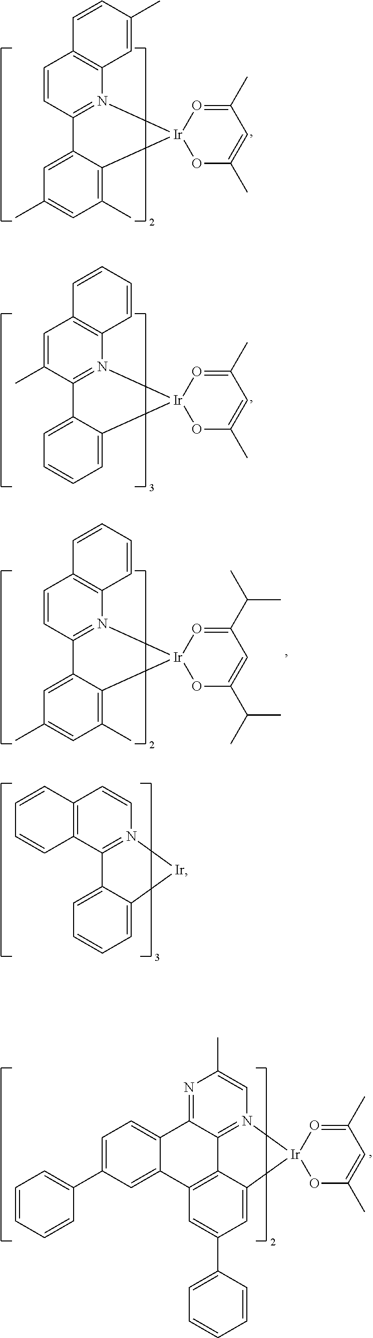

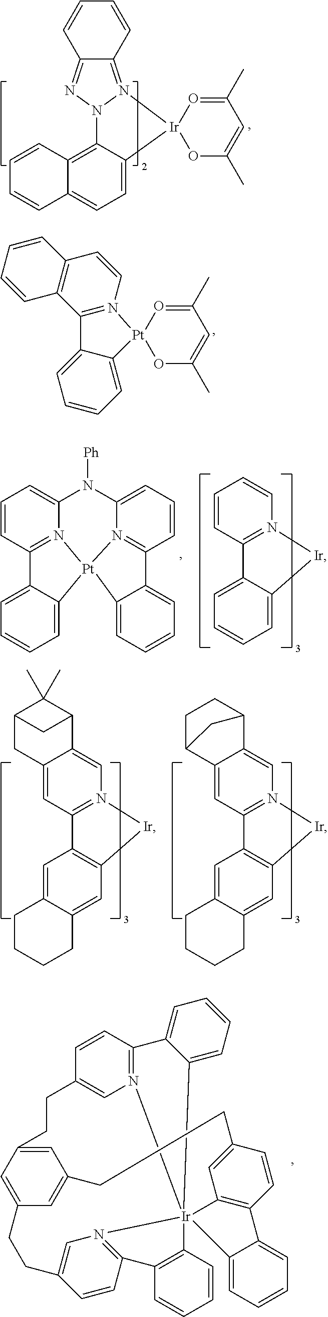

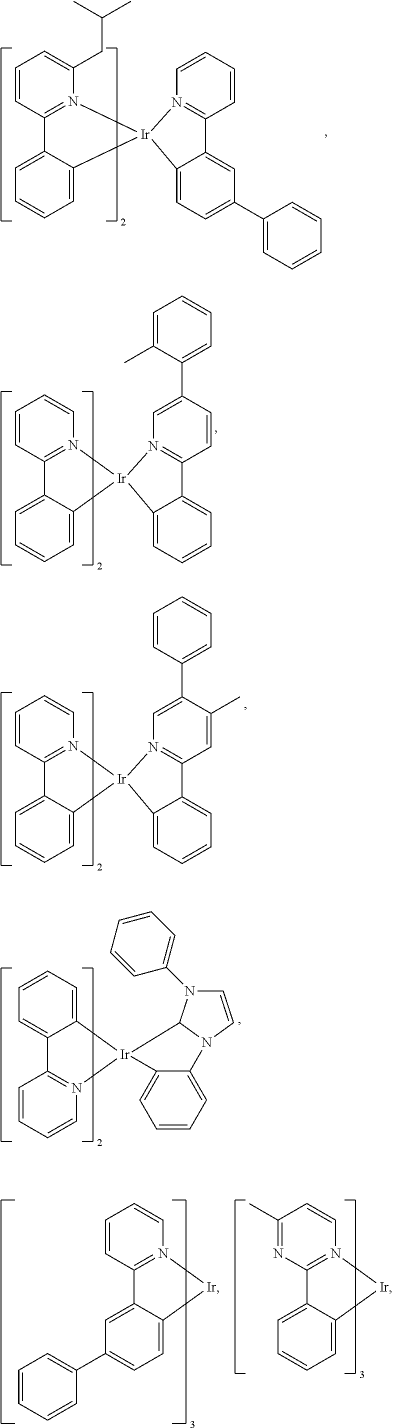

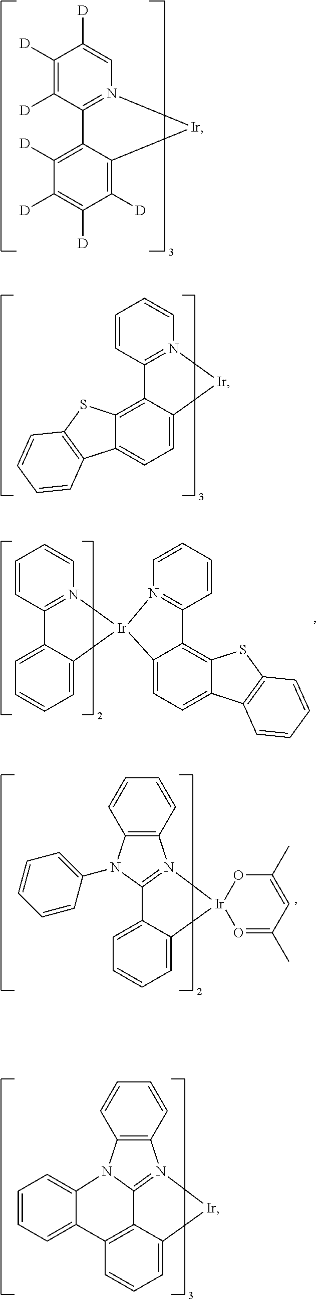

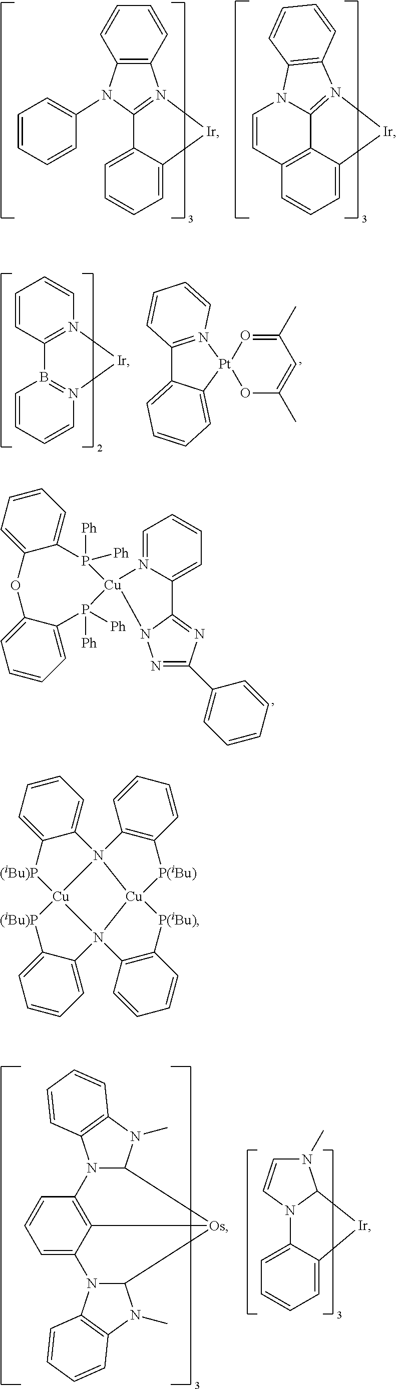

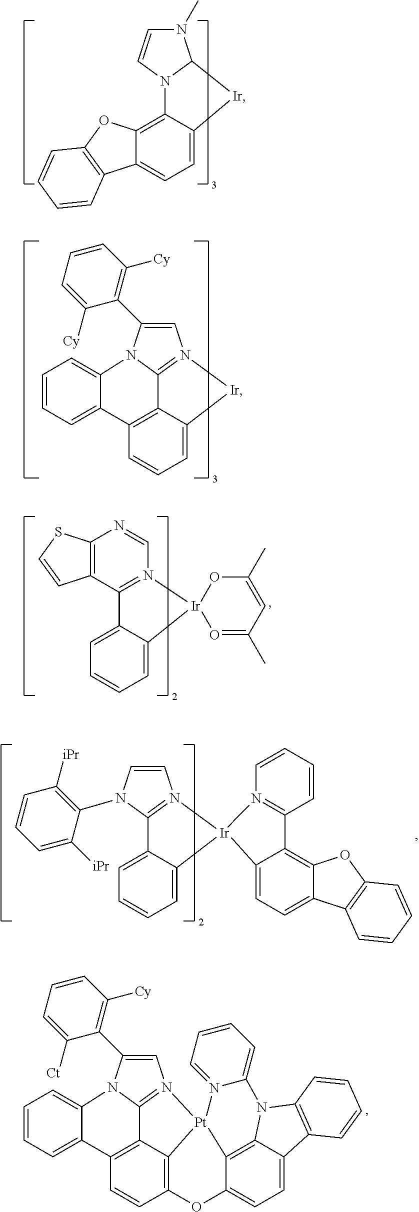

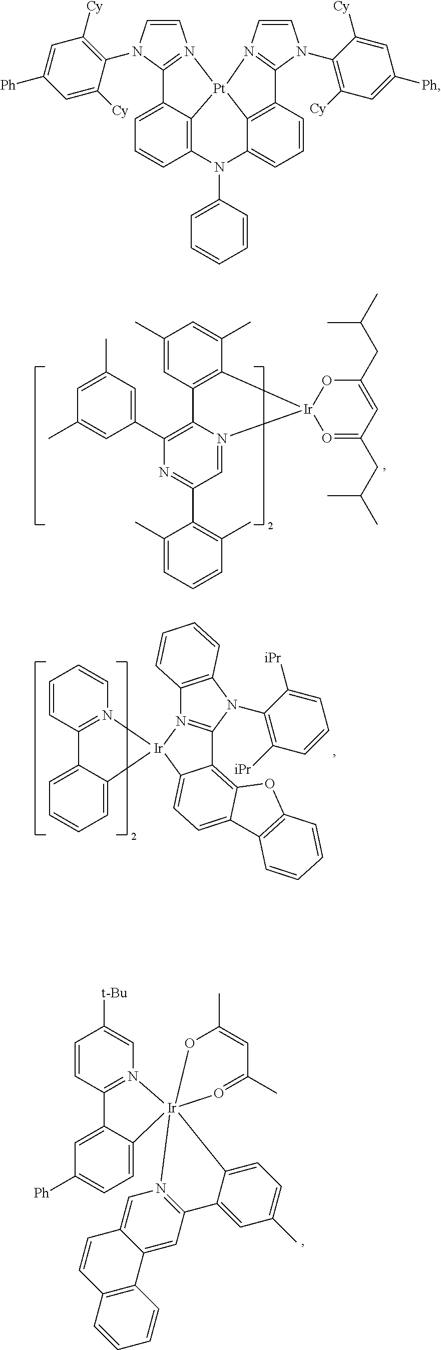

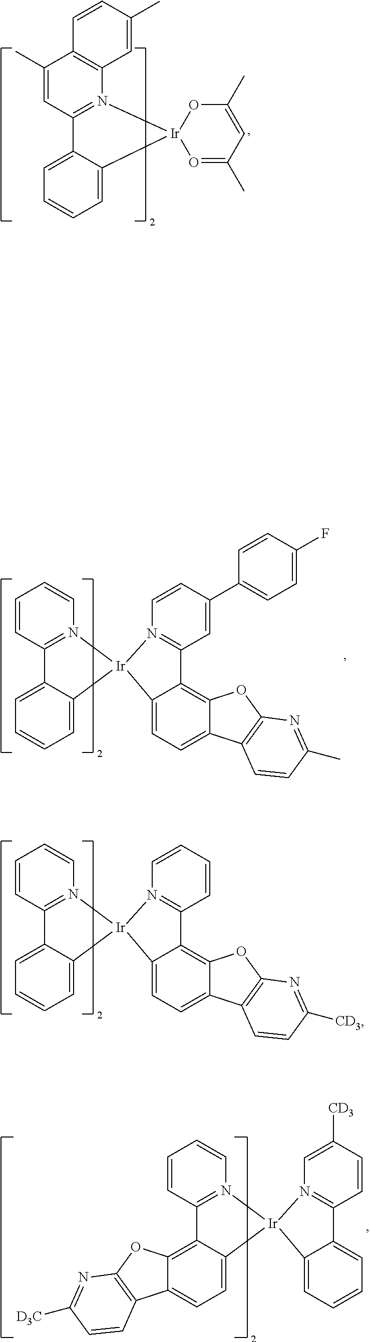

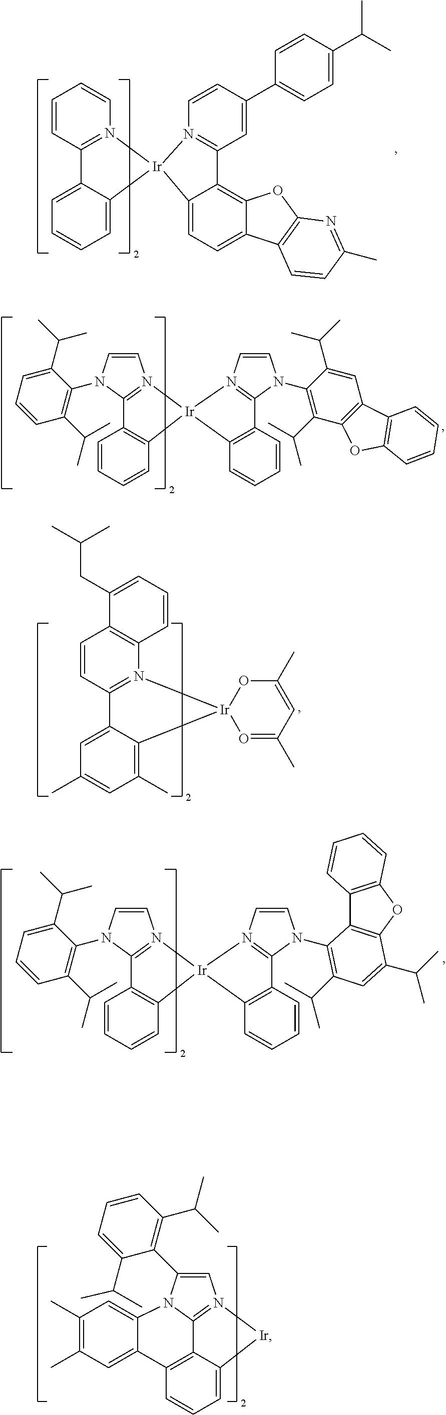

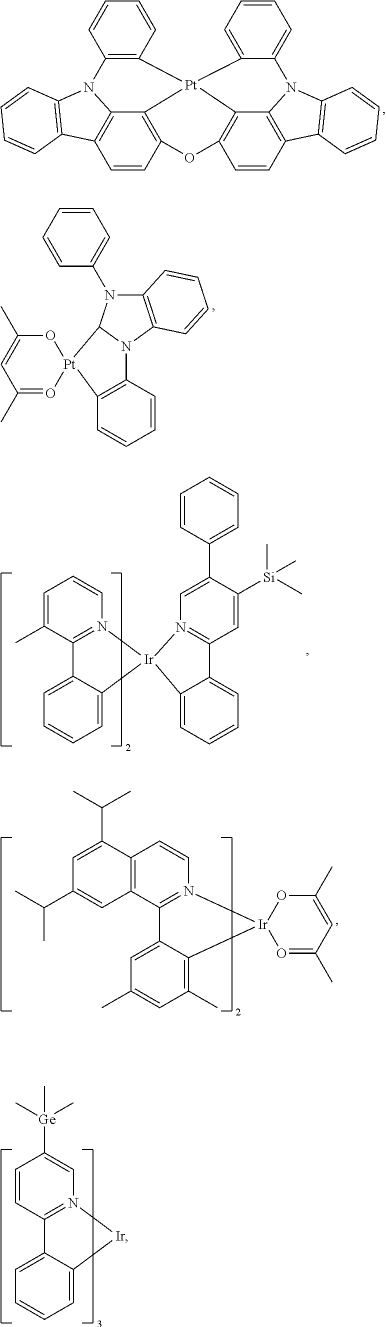

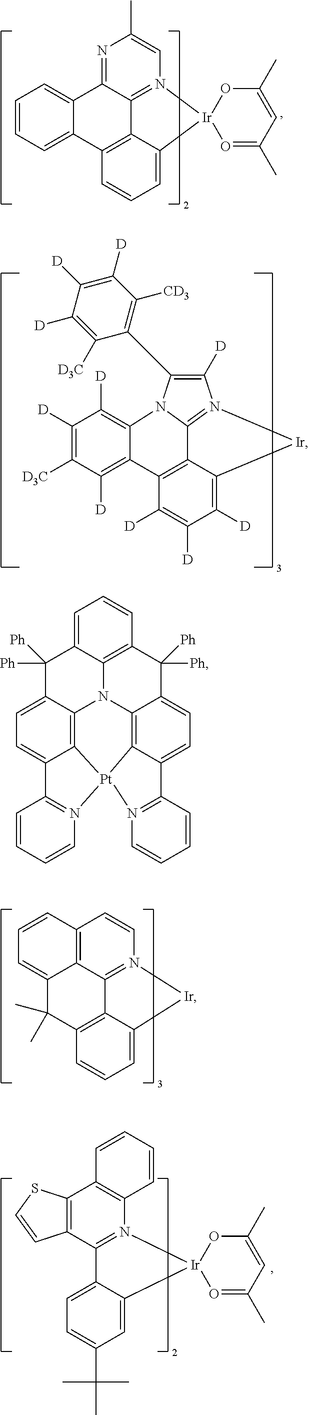

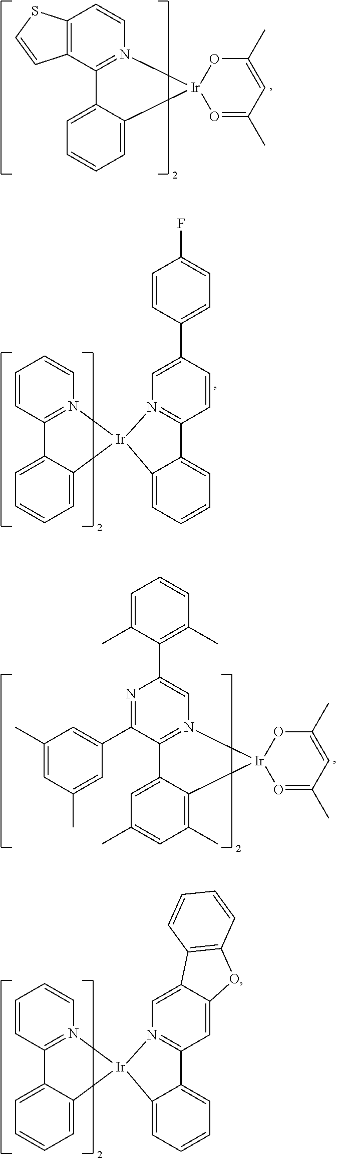

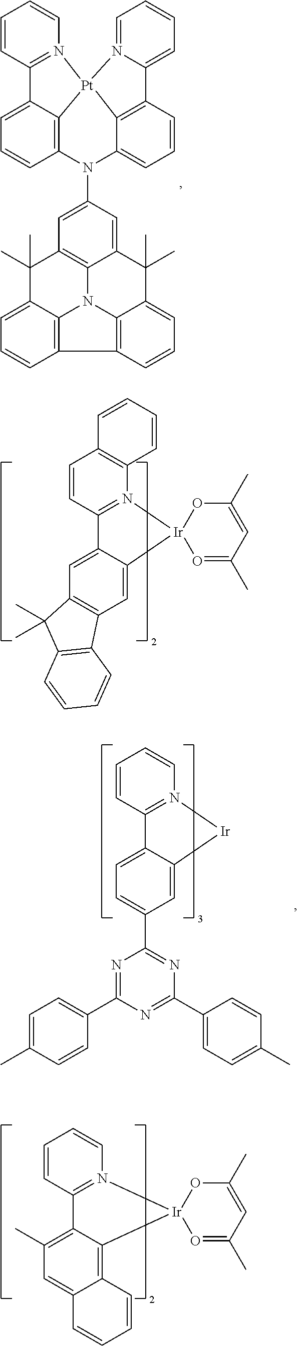

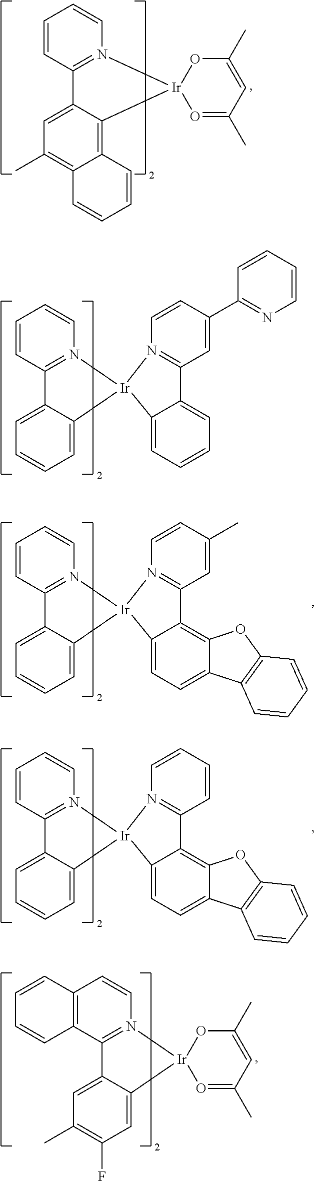

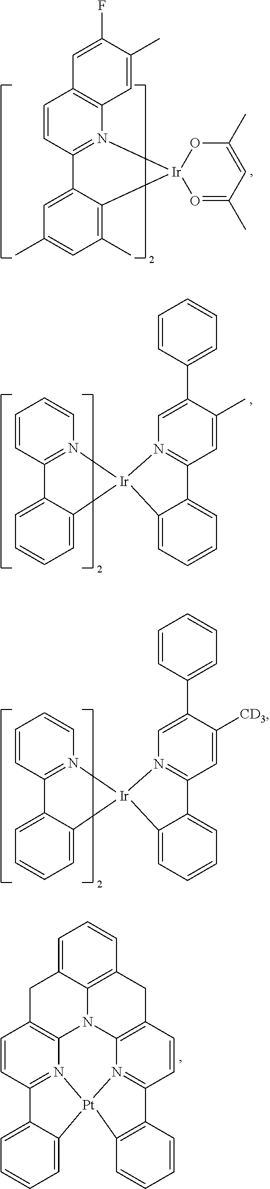

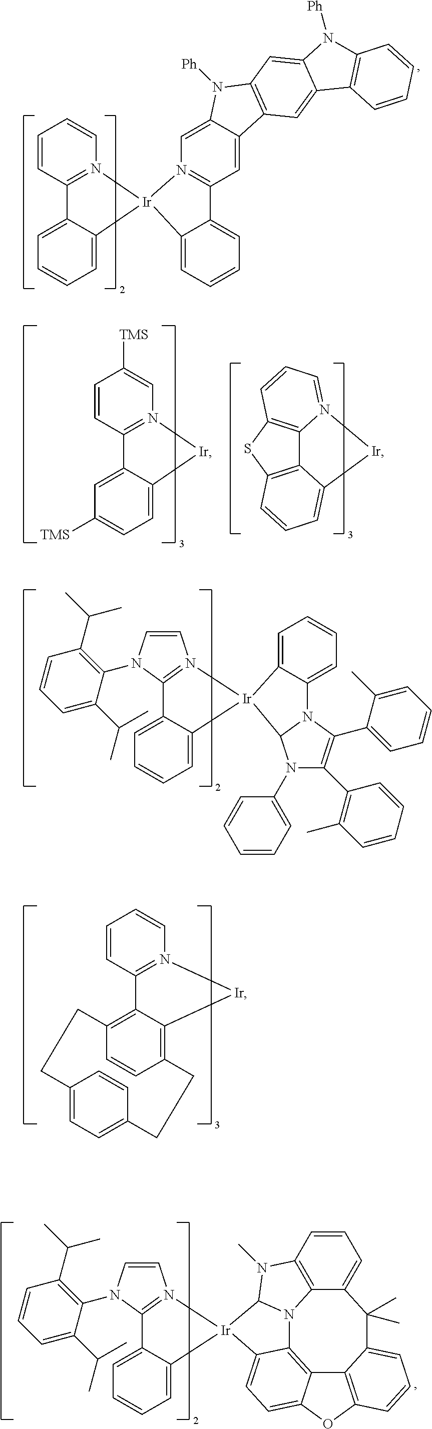

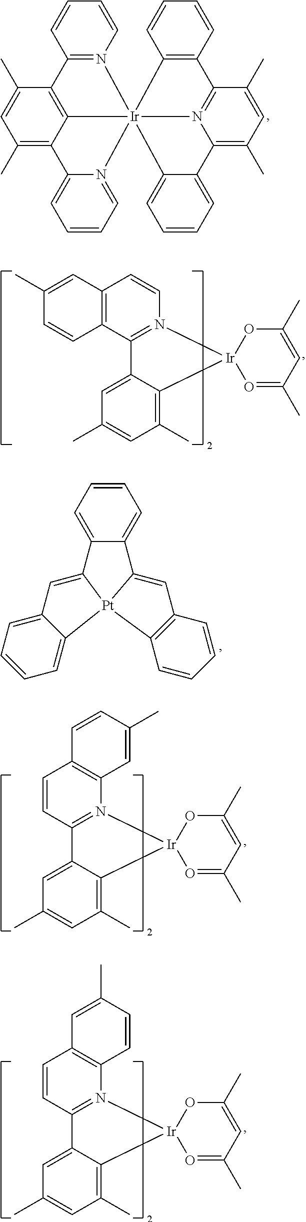

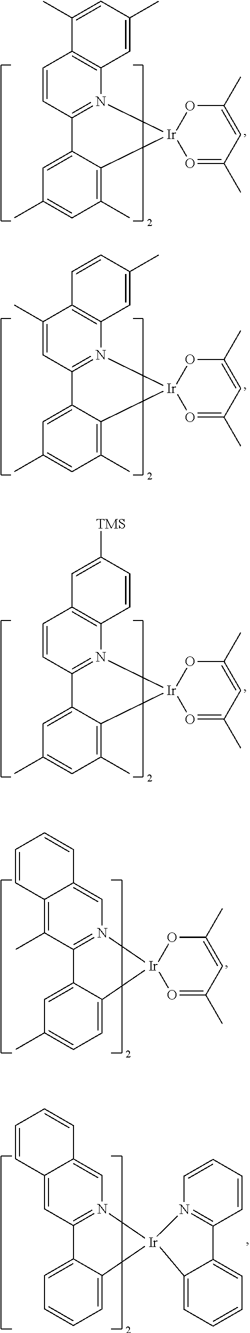

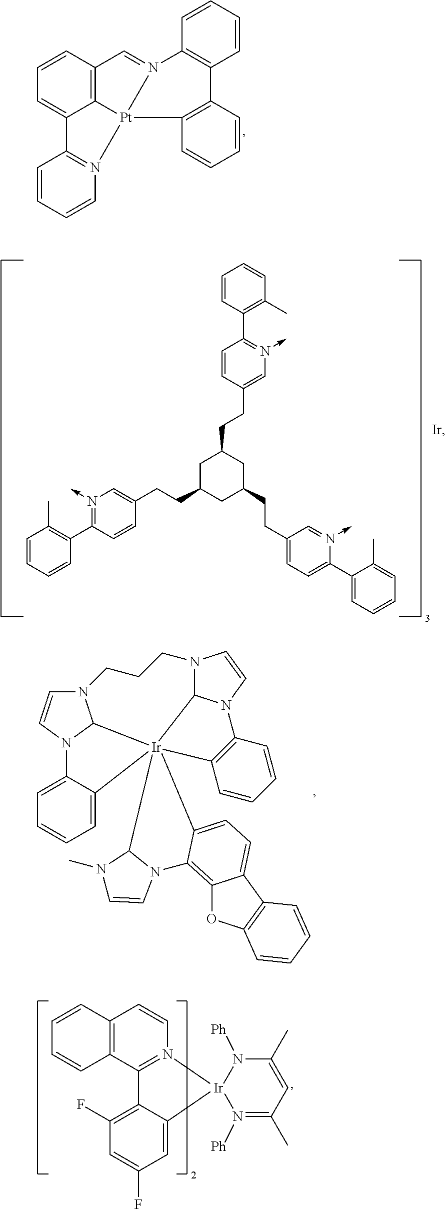

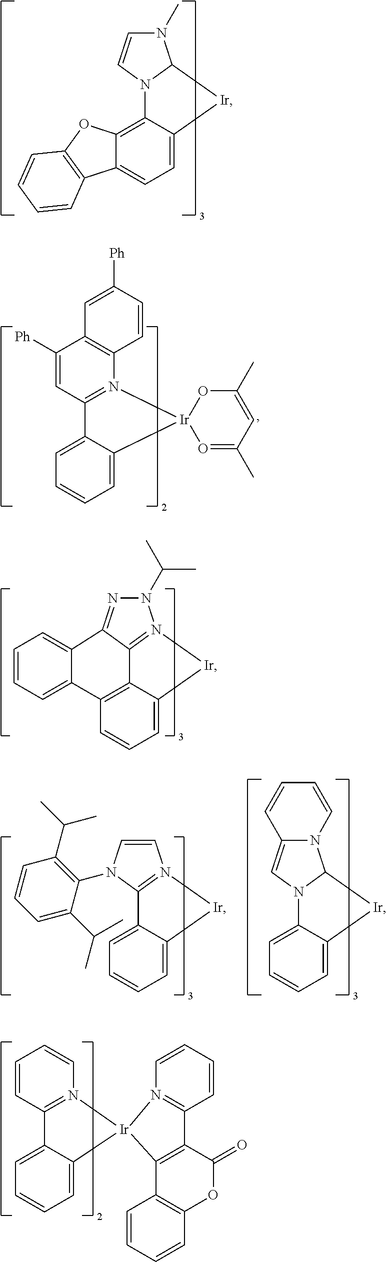

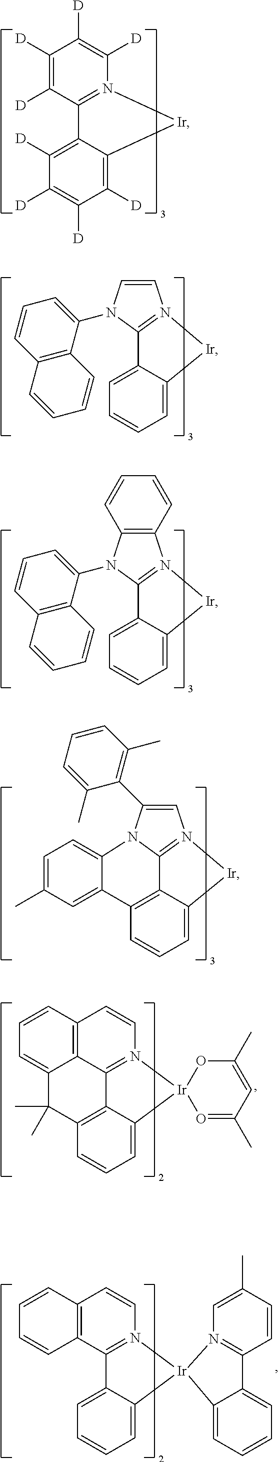

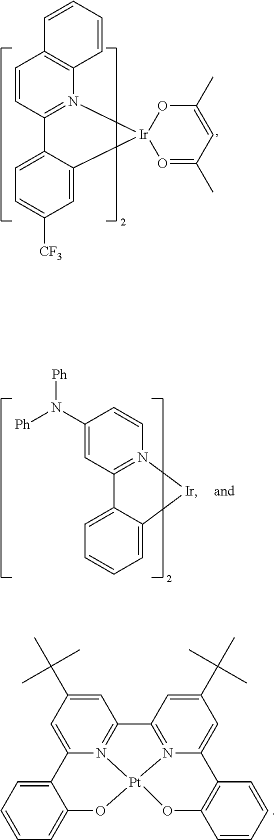

HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

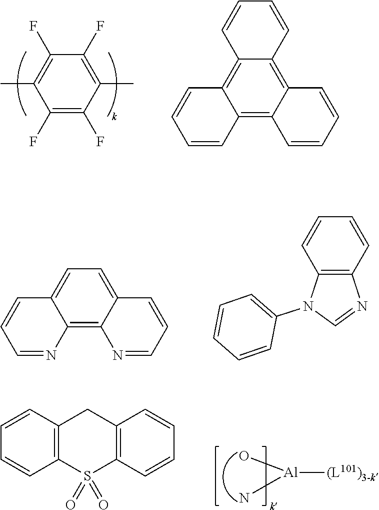

wherein k is an integer from 1 to 20; L¹⁰¹ is an another ligand, k′ is an integer from 1 to 3.

ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

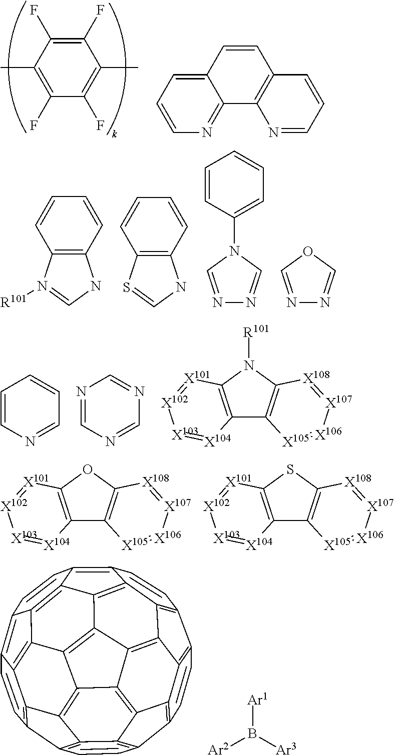

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above, k is an integer from 1 to 20. X¹⁰¹ to X¹⁰⁸ is selected from C (including CH) or N.

In another aspect, the metal complexes used in ETL contains, but not limit to the following general formula:

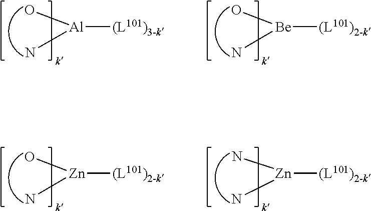

wherein (O-N) or (N-N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

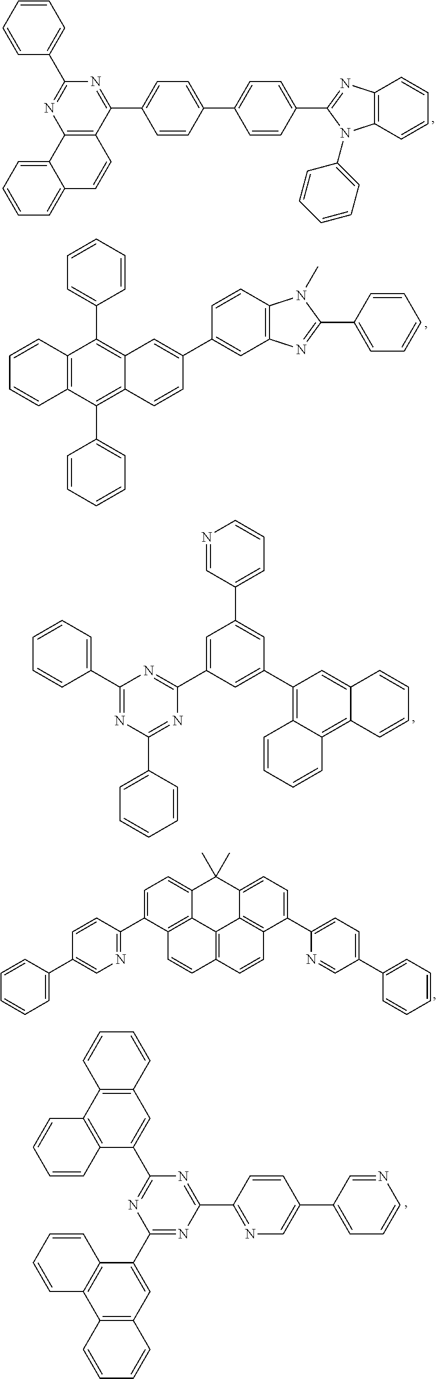

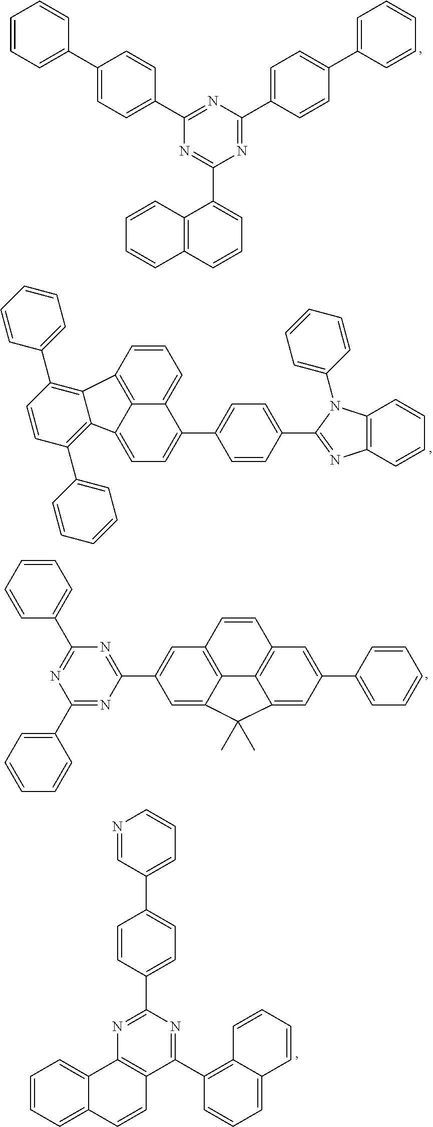

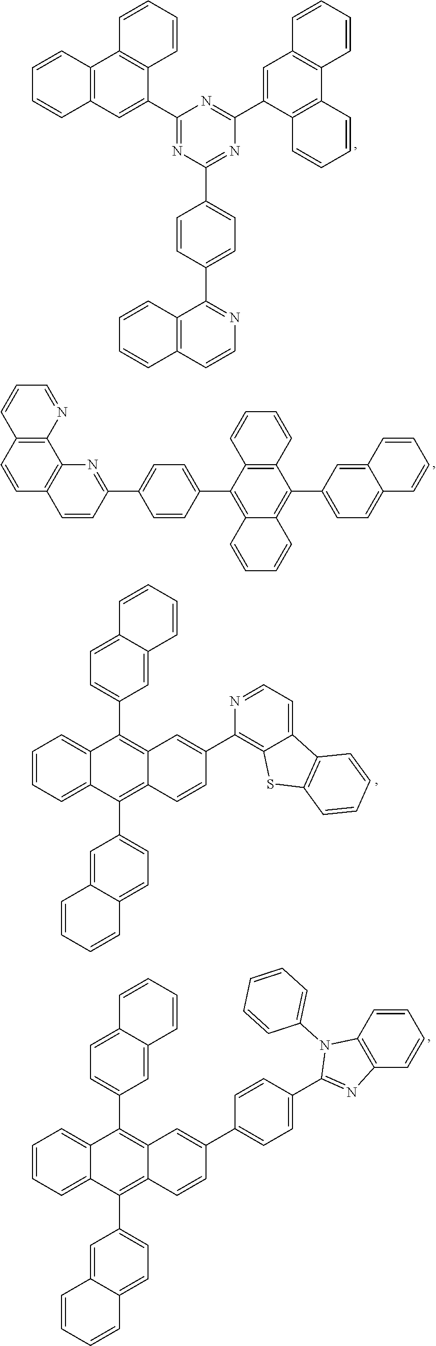 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc2cc(-c3c4ccccc4c(-c4ccc(-c5ccc6ccc7cccnc7c6n5)cc4)c4ccccc34)ccc2c1 ; c1ccc2cc(-c3c4ccccc4c(-c4ccc5ccccc5c4)c4cc(-c5nccc6c5sc5ccccc56)ccc34)ccc2c1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

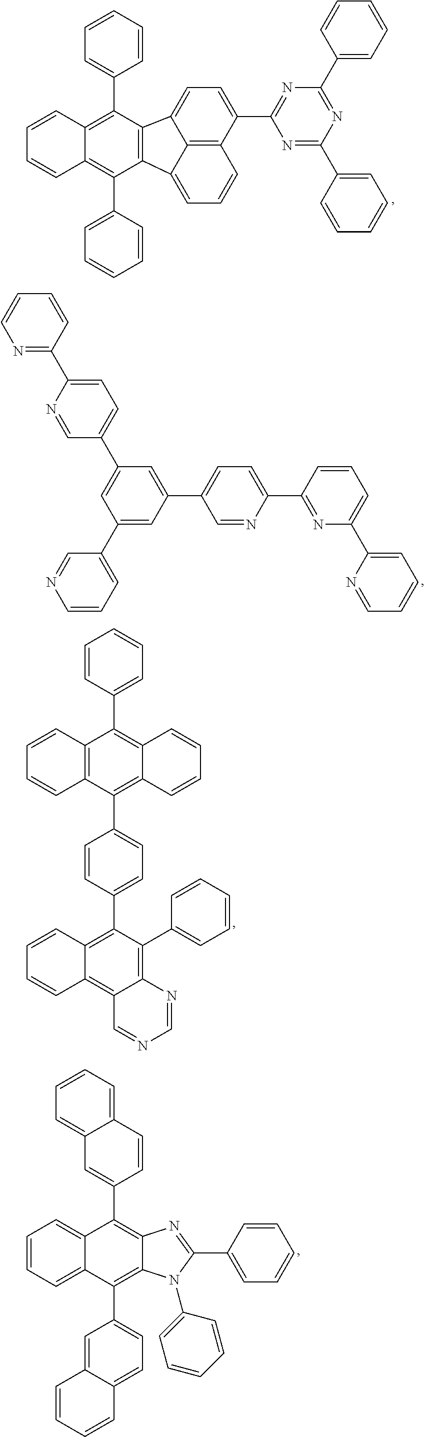

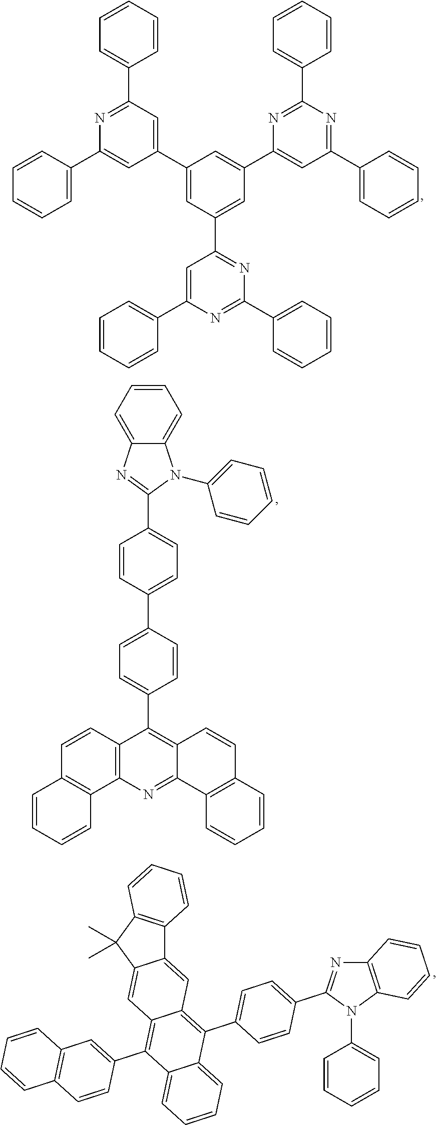

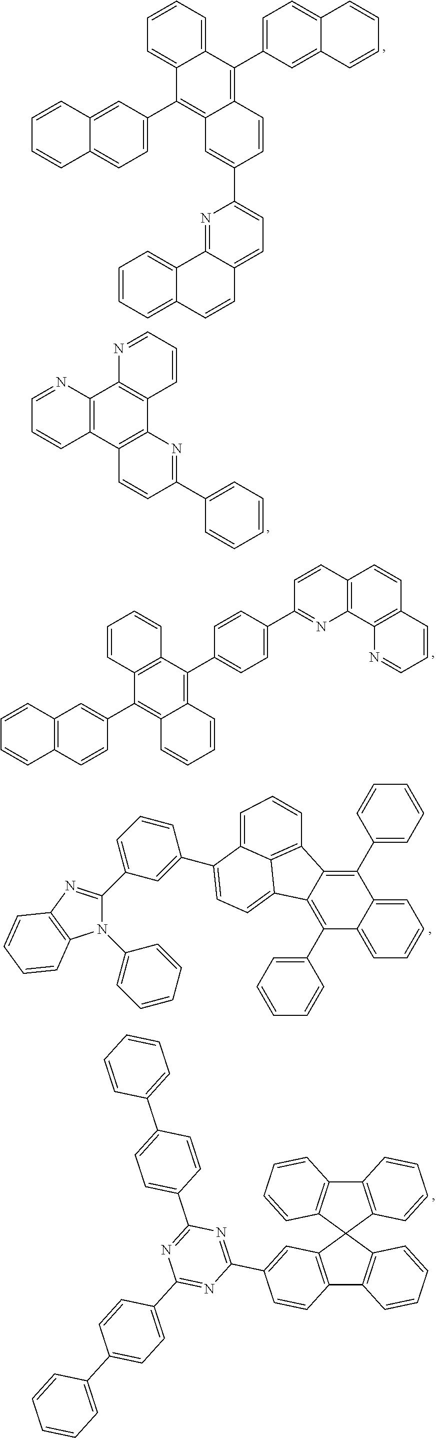

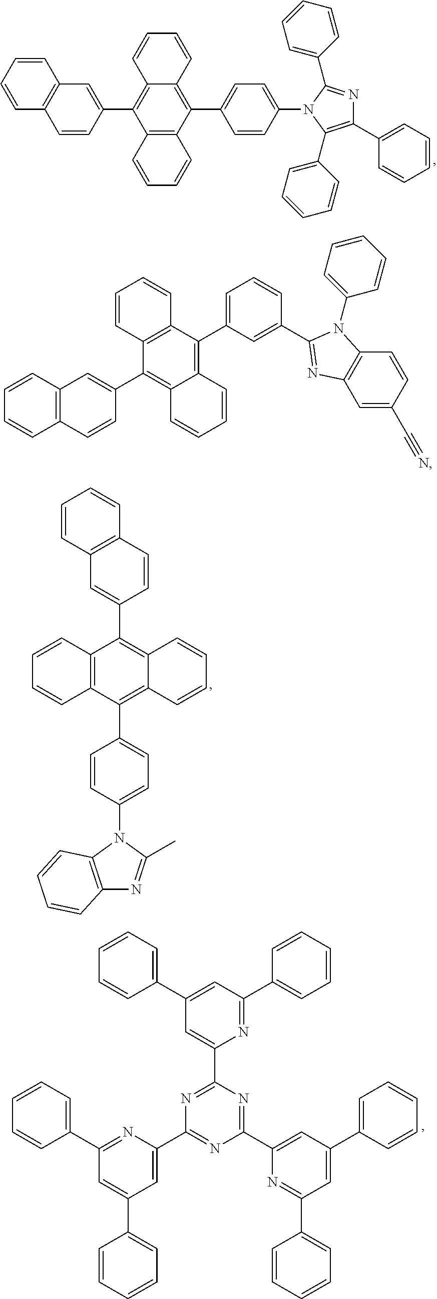

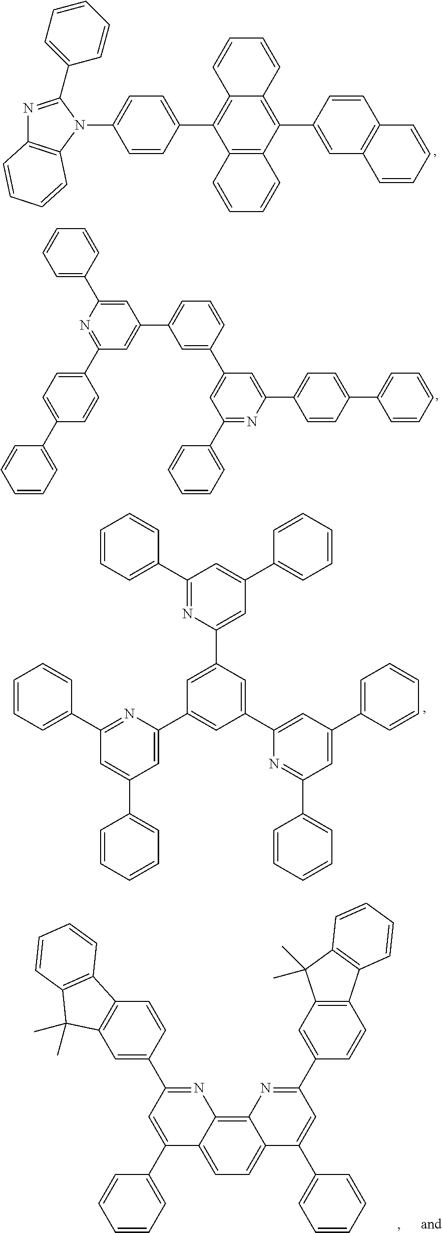

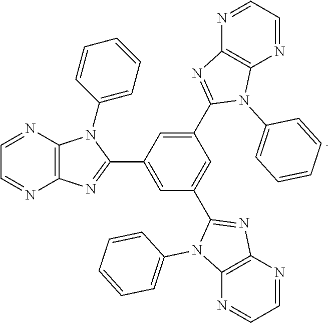 [SMILES: c1ccc(-n2c(-c3cc(-c4nc5nccnc5n4-c4ccccc4)cc(-c4nc5nccnc5n4-c4ccccc4)c3)nc3nccnc32)cc1]

Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

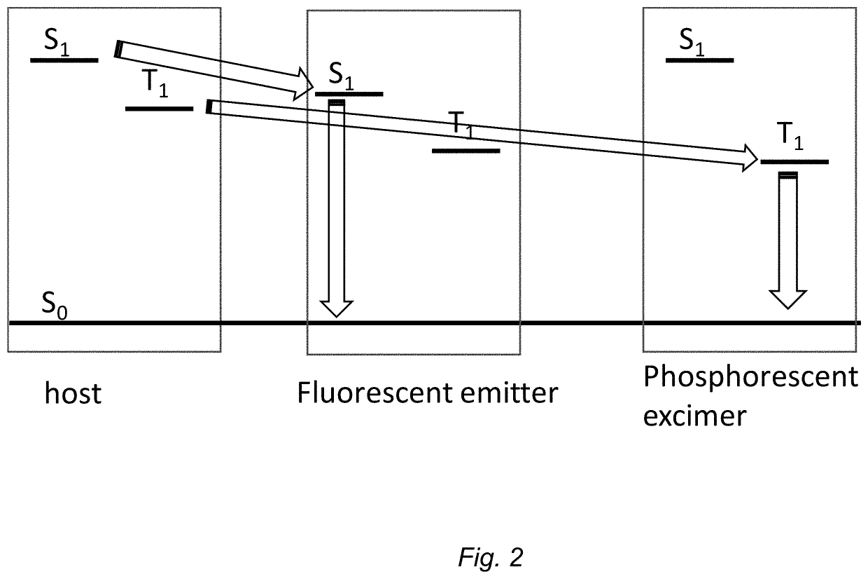

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the composite materials of the present invention and practice the claimed methods. The following working examples therefore, specifically point out the preferred embodiments of the present invention, and are not to be construed as limiting in any way the remainder of the disclosure.

### Example 1: White OLEDs Employing Blue Fluorescent Emitters and Orange Phosphorescent Emitters

The development of efficient white OLED can have significant applications for general lighting purpose. However, the current short operational lifetime of blue phosphorescent emitters will limit the overall performance of white OLED consisting of all phosphorescent emitters. There is a potential alternate to such efficient white OLED if we can use blue fluorescent emitter to harvest host singlet exciton and use green and red phosphorescent emitters to harvest host triplet excitons exclusively. But the use of two phosphorescent emitters could complicate the device structures and red phosphorescent emitters could receive the energy transfer from blue fluorescent emitter, which could result in a color instability for white OLEDs at various driving conditions.

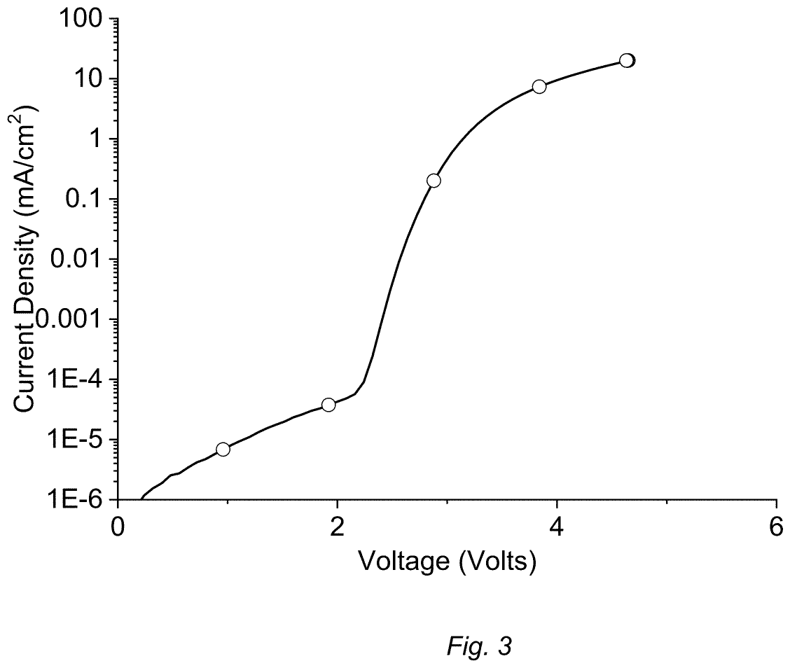

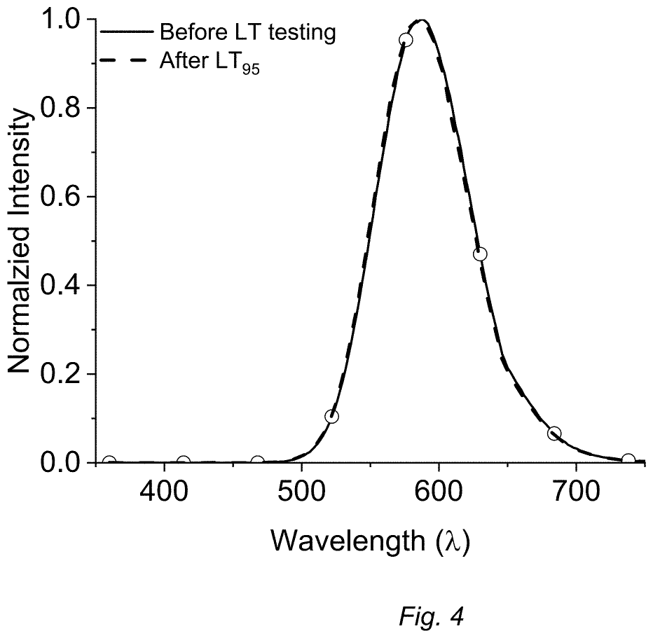

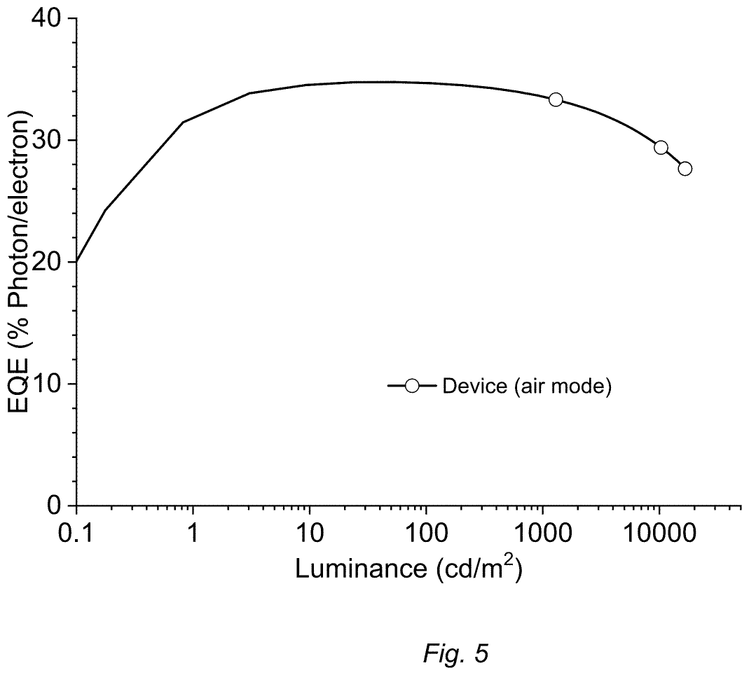

A white OLED can be constructed using orange-emitting phosphorescent excimers which have weak absorption in the wavelength of (450-550 nm) and could also be efficient and stable in the device settings. Pd3O8-p and Pd3O3 are exemplary orange phosphorescent excimer emitters. FIG. 3, FIG. 4, and FIG. 5 represent the characterization of Device 1, in which a neat Pd3O8-P thin film serves as the emitting layer. The configuration of Device 1 is below. Device 1, in which neat Pd3O8-p is employed as the sole component of the emitting layer, demonstrated a peak EQE of over 34%, a peak emission wavelength of around 580 nm and a long device operational lifetime with LT95 of over 15000 hrs at 1000 nits.

Device 1: ITO (100 nm)/HATCN (10 nm)/NPD (70 nm)/Tris-PCZ (10 nm)/Pd3O8-P (20 nm)/BAlq (10 nm)/BPyTP (50 nm)/Liq (2 nm)/Al (100 nm); the device active area is 2×2 mm.

A reasonably efficient and stable white OLED based on blue fluorescent emitters (TBPe) and orange emitting phosphorescent excimers (Pd303) can be constructed. The configuration of exemplary Device 2 and Device 3 are presented below.

Device 2: ITO/HATCN (10 nm)/NPD (40 nm)/2% TBPe:mCBP (2 nm)/10% Pd303:mCBP (25 nm)/BAlq (10 nm)/BPyTP (40 nm)/Liq (2 nm)/Al.

Device 3: ITO/HATCN (10 nm)/NPD (40 nm)/4% TBPe:mCBP (2 nm)/10% Pd303:mCBP (25 nm)/BAlq (10 nm)/BPyTP (40 nm)/Liq (2 nm)/Al.

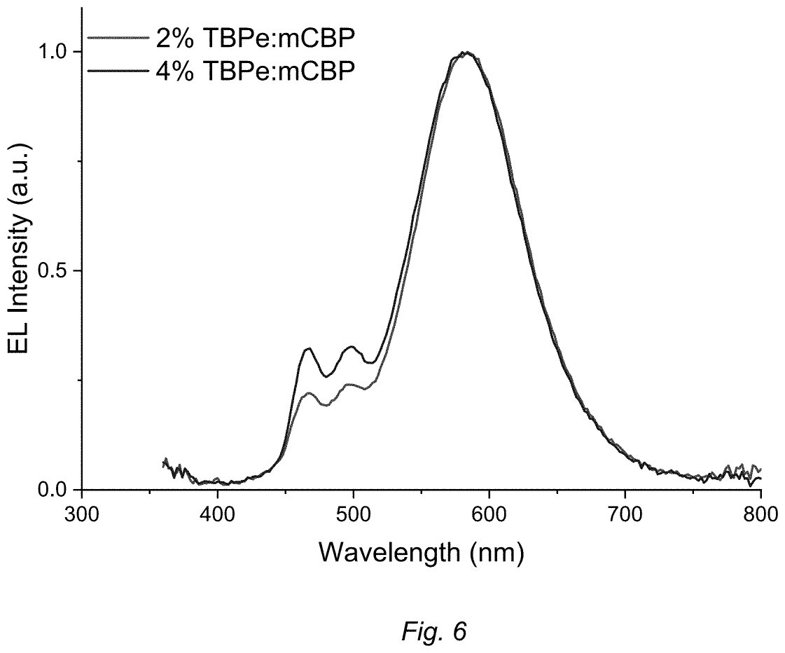

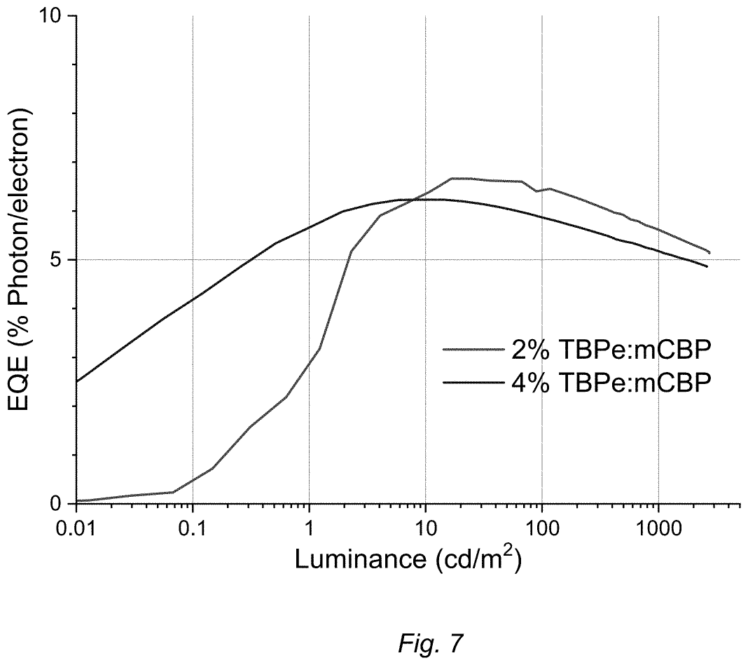

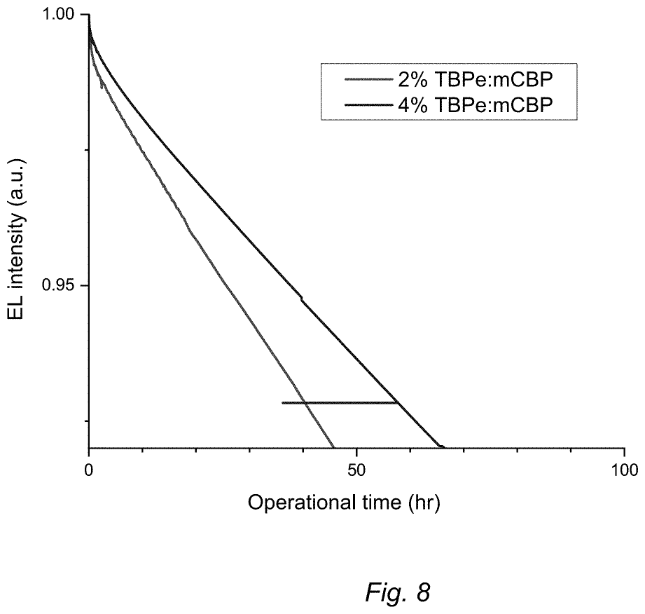

Exemplary Devices 2 and 3 are characterized in FIG. 6, FIG. 7, and FIG. 8. The structures of the emitters utilized in these devices are presented below.

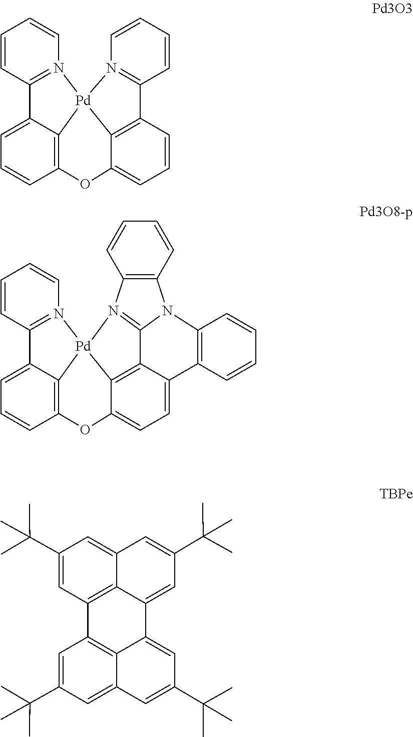

### Example 2: Planar Phosphorescent Excimers as Horizontally Emitting Dipole Aligned Phosphorescent Emissive Materials for PLED Applications

A series of planar phosphorescent excimers, i.e. Pd3O8-p, Pd3O8-py5 and Pd3O8-py2, have been developed for potential horizontally emitting dipole aligned phosphorescent emissive materials for OLED applications. Blue fluorescent emitters (e.g., FLB2) and amber phosphorescent excimers Pd3O8-p, Pd3O8-py5, and Pd3O8-py2 can be used to fabricate efficient and stable white OLEDs. Devices using these compounds were produced with varying thickness of the phosphorescent emitter layer:

Device 1: ITO (60 nm)/HATCN (10 nm)/NPD (40 nm)/Tris-PCz (10 nm)/Pd3O8-py5 (5 nm)/2% FLB2:BH (20 nm)/2% FLB2:BH2 (20 nm)/BPyTP (40 nm)/LiF (1 nm)/AL (100 nm)

Device 2: ITO (60 nm)/HATCN (10 nm)/NPD (40 nm)/Tris-PCz (10 nm)/Pd3O8-py5 (4 nm)/2% FLB2:BH (20 nm)/2% FLB2:BH2 (20 nm)/BPyTP (40 nm)/LiF (1 nm)/AL (100 nm)

Device 3: ITO (60 nm)/HATCN (10 nm)/NPD (40 nm)/Tris-PCz (10 nm)/Pd3O8-py5 (3 nm)/2% FLB2:BH (20 nm)/2% FLB2:BH2 (20 nm)/BPyTP (40 nm)/LiF (1 nm)/AL (100 nm)

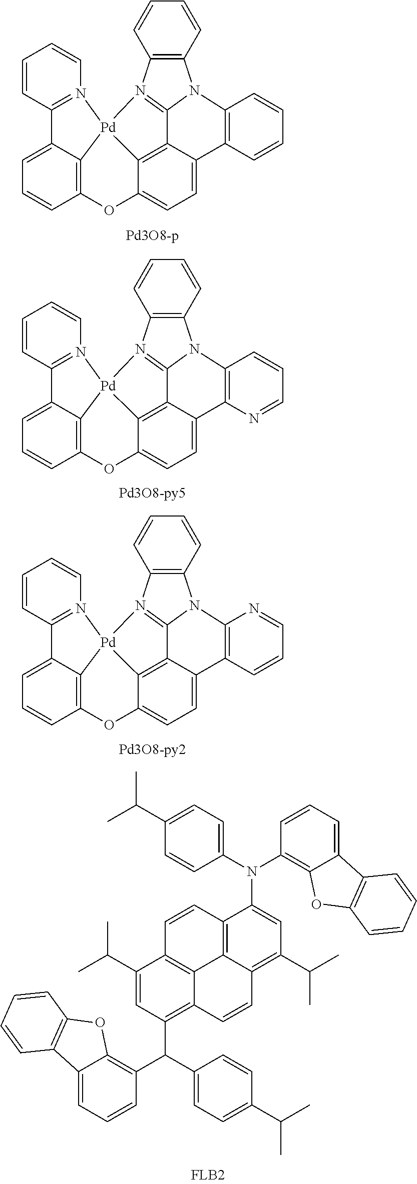

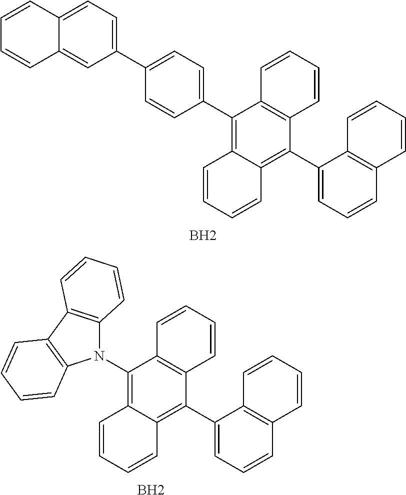

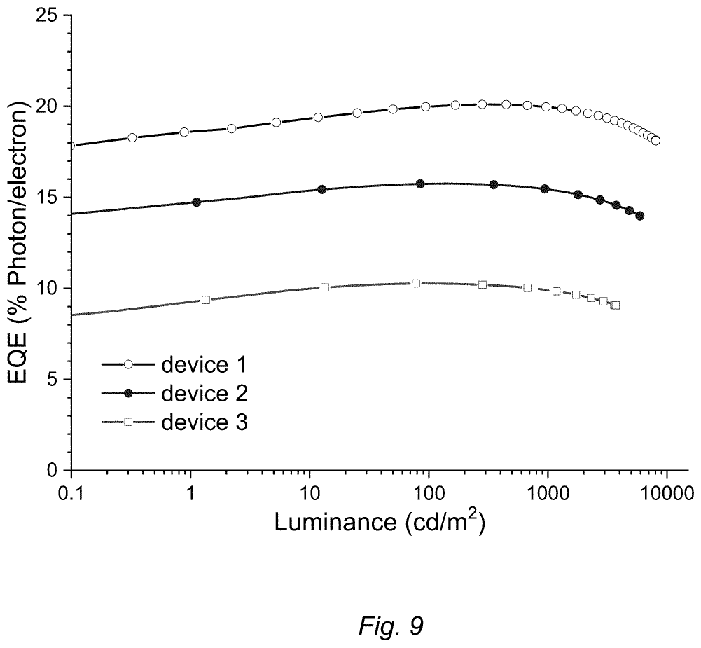

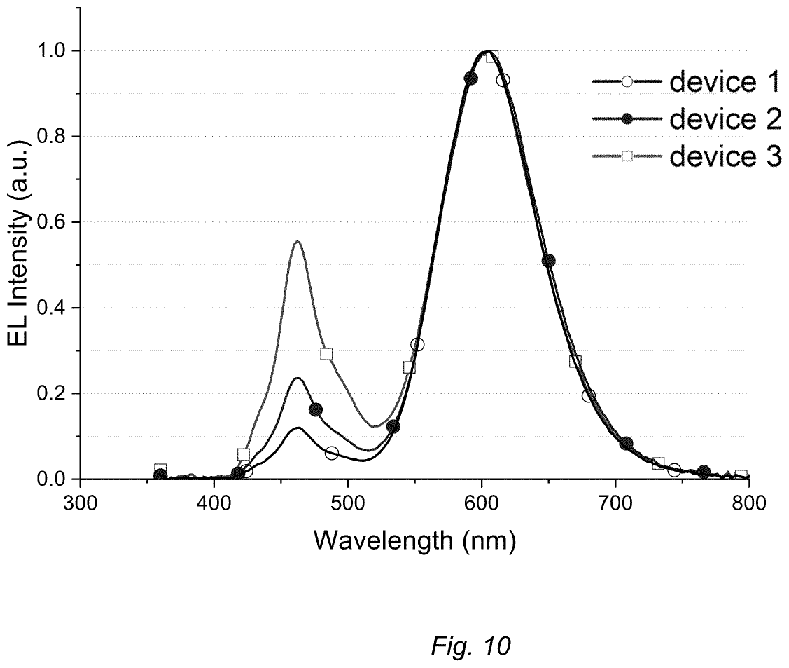

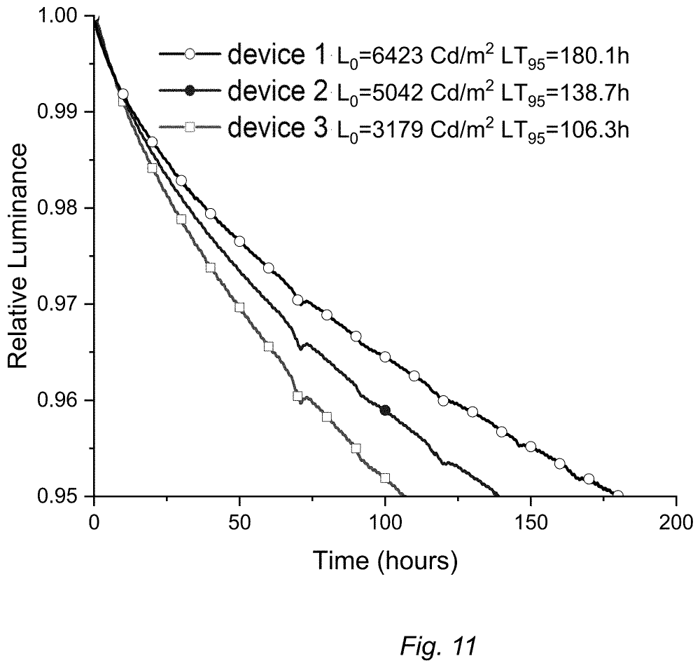

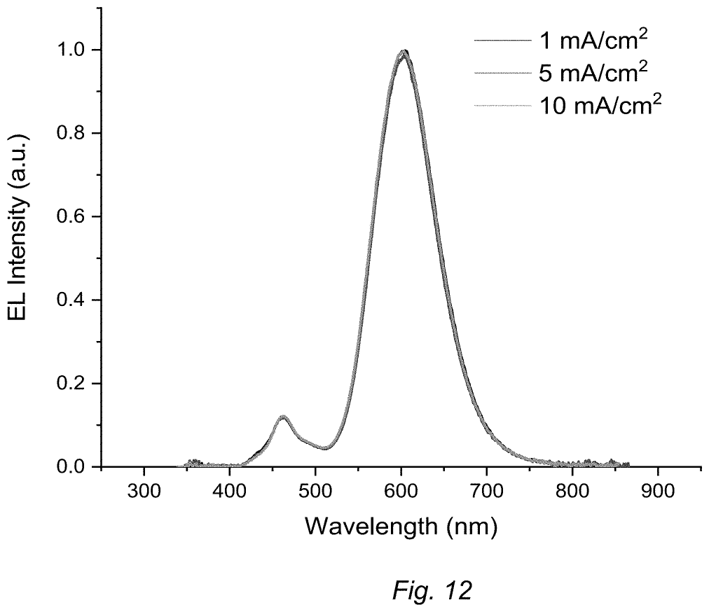

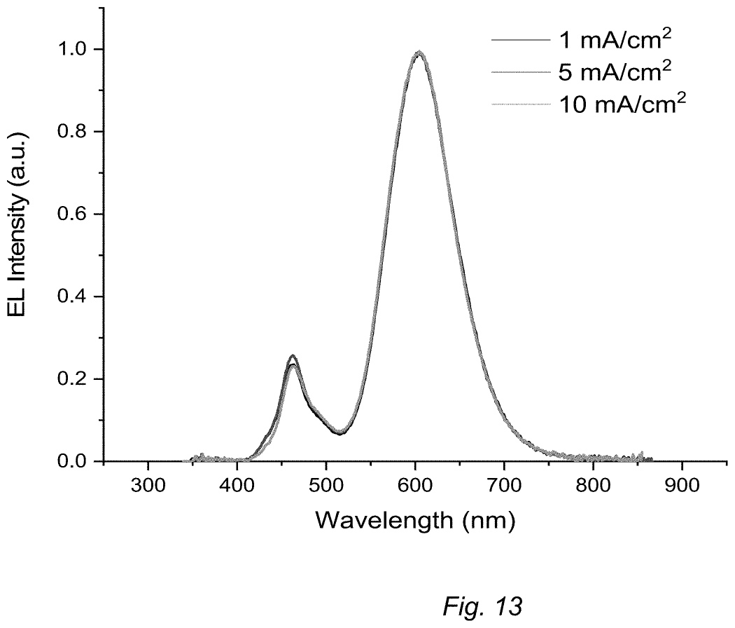

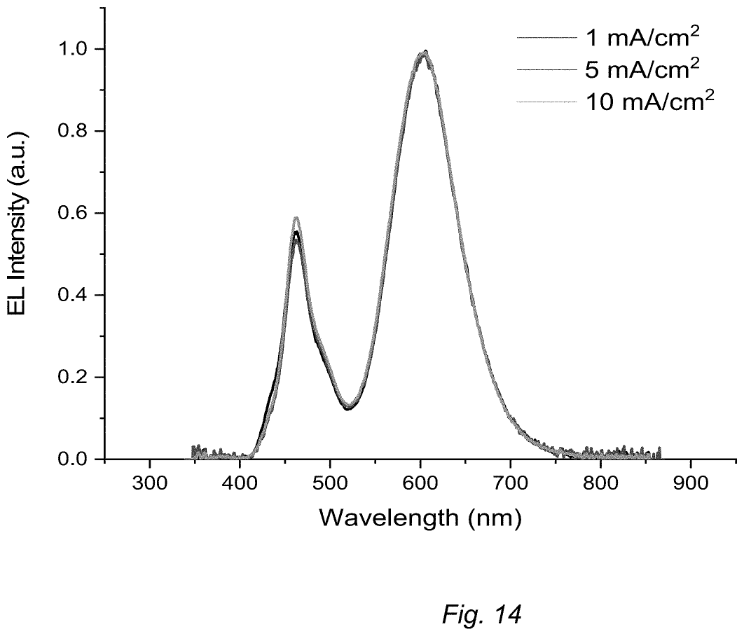

FIG. 9 is a plot of the EQE vs Luminance of Devices 1, 2, and 3. FIG. 10 is a plot of the electroluminescent (EL) spectra of Devices 1, 2, and 3. FIG. 11 is a plot of normalized EL intensity vs device operational time at the constant current of 20 mA cm⁻² for Devices 1, 2, and 3. The EL spectra of Device 1 at driving currents of 1, 5, and 10 mA cm⁻² is presented in FIG. 12. The EL spectra of Device 2 at driving currents of 1, 5, and 10 mA cm⁻² is presented in FIG. 13. The EL spectra of Device 3 at driving currents of 1, 5, and 10 mA cm⁻² is presented in FIG. 14.

Notably, warm white OLED Device 1 exhibited an EQE of close to 20% and estimated LT95 of over 175 hrs at the brightness of over 8000 cd/m². The device operational stability is extremely encouraging that such a single-stack white OLED could achieve that device operational lifetime requirement even for high brightness application to reduce the unit expense of OLED lighting products.

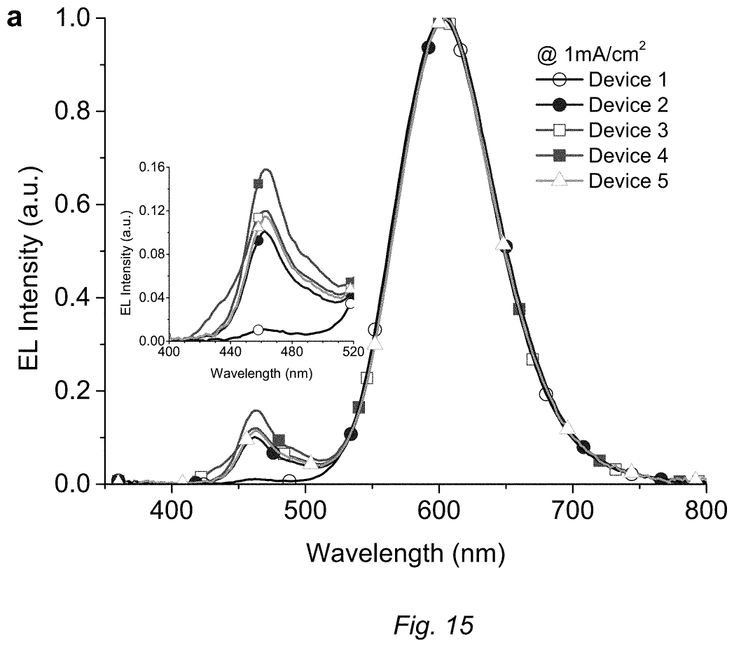

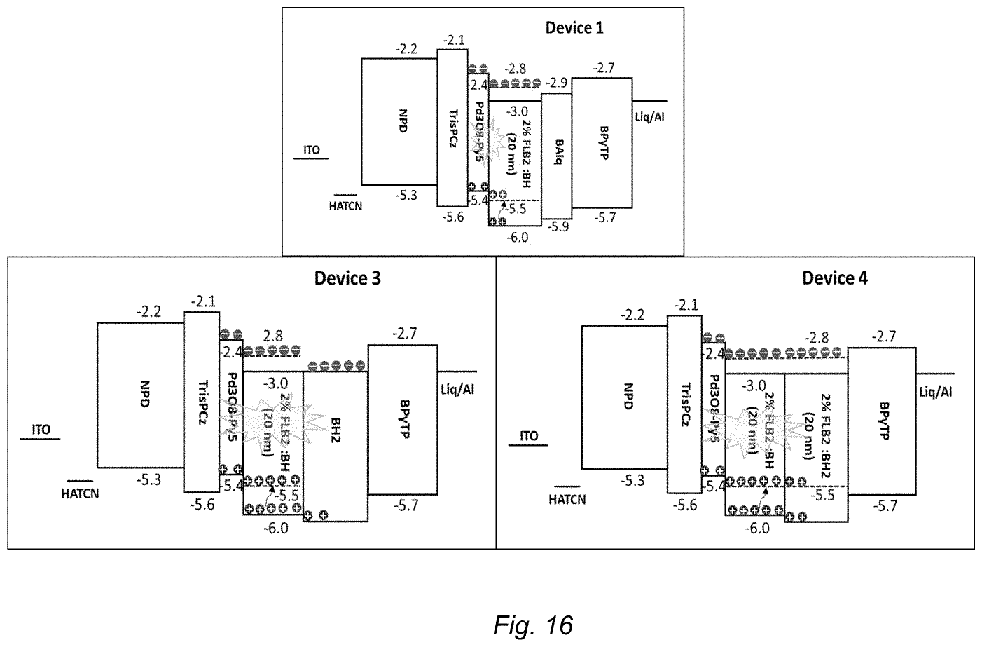

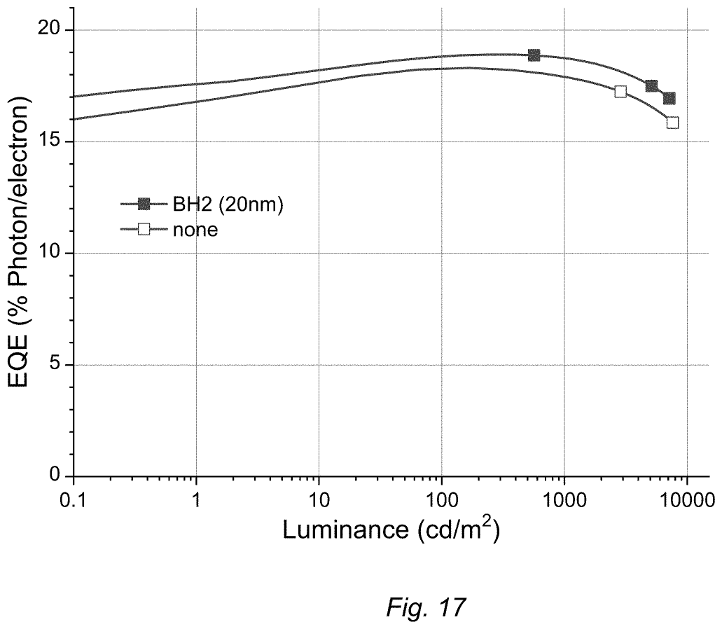

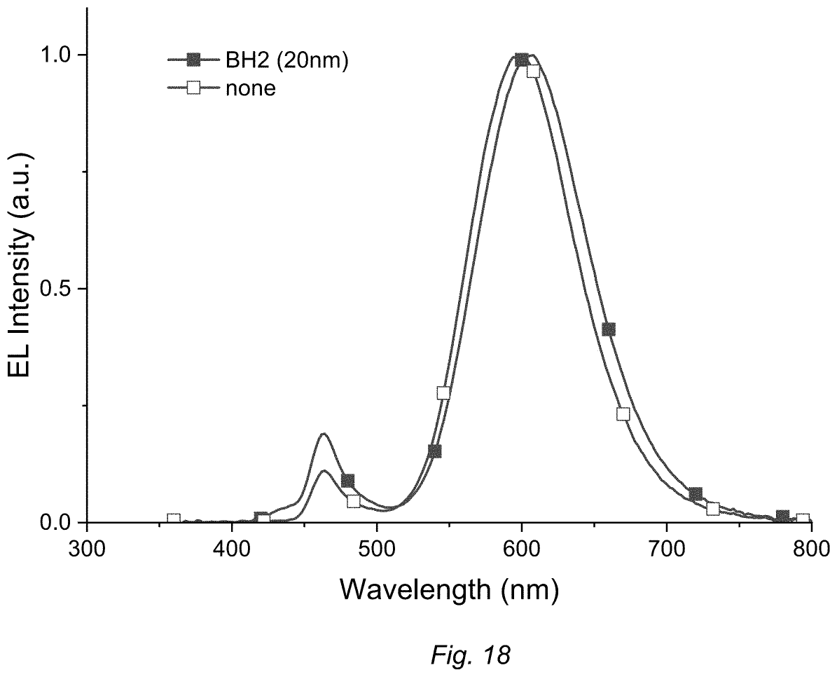

Additional hole-blocking materials modify the fluorescent emission component and device operational lifetime while maintaining the same interface between amber emitters and blue fluorescent emissive layers (FIG. 15). For example, three exciton recombination schemes are depicted in FIG. 16. A variety of HBL materials can be used to great effect on WOLED performance. FIG. 17 compares the EQE vs Luminance for devices including and not including a 20 nm BH2 layer. FIG. 18 compares the EL spectra for the devices. The configuration of these devices is below. Also shown below is the structure of t-DABNA

BH2 device: ITO (100 nm)/HATCN (10 nm)/NPD (70 nm)/Tris-PCz (10 nm)/Pd3O8-py5 (5 nm)/2% t-DABNA:BH (20 nm)/BH2 (20 nm)/BPyTP (40 nm)/LiF (1 nm)/AL (100 nm).

No BH2 device: ITO (100 nm)/HATCN (10 nm)/NPD (70 nm)/Tris-PCz (10 nm)/Pd3O8-py5 (5 nm)/2% t-DABNA:BH (20 nm)/BPyTP (40 nm)/LiF (1 nm)/AL (100 nm).

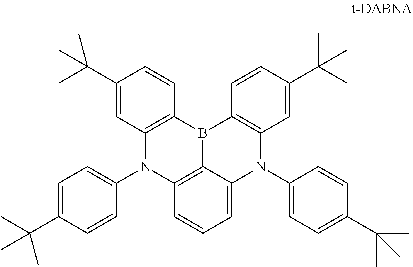 [SMILES: CC(C)(C)c1ccc(N2c3cc(C(C)(C)C)ccc3B3c4ccc(C(C)(C)C)cc4N(c4ccc(C(C)(C)C)cc4)c4cccc2c43)cc1]

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

We claim:

1. A white organic light emitting device comprising:
a first electrode;
a hole transporting layer in contact with the first electrode;
a second electrode;
an electron transporting layer in contact with the second electrode; and
an emissive layer between the hole transporting layer and the electron transporting layer, the emissive layer comprising a host, a fluorescent emitter, and a phosphorescent emitter, wherein the fluorescent emitter harvests singlet excitons and emits blue light and wherein the phosphorescent emitter harvests triplet excitons and emits yellow-amber light.

2. The device of claim 1, wherein the phosphorescent emitter is an excimer emitter.

3. The device of claim 1, wherein the phosphorescent emitter is a square planar complex.

4. The device of claim 1, wherein the phosphorescent emitter is a tetradentate platinum or palladium complex.

5. The device of claim 1, wherein the phosphorescent emitter emits light in the range of about 480 nm to about 700 nm.

6. The device of claim 1, wherein the phosphorescent emitter emits yellow, amber, or orange light.

7. The device of claim 1, wherein the phosphorescent emitter is a compound of General Formula I: 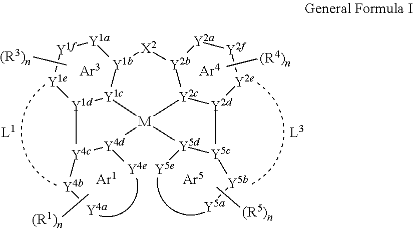
wherein, in General Formula I:
M represents Pt(II) or Pd(II);
R¹, R³, R⁴, and R⁵ each independently represents hydrogen, halogen, hydroxyl, nitro, cyanide, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;
X² represents NR, PR, CRR′, SiRR′, CRR′, SiRR′, O, S, S═O, O=S═O, Se, Se═O, or O=Se═O, wherein R and R′ each independently represents hydrogen, halogen, hydroxyl, nitro, cyanide, thiol, or optionally substituted C₁-C₄ alkyl, alkoxy, amino, aryl, or heteroaryl;
each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;
Ar³ and Ar⁴ each independently represents a 6-membered aryl group; and
Ar¹ and Ar⁵ each independently represents a 5- to 10-membered aryl, heteroaryl, fused aryl, or fused heteroaryl.

8. The device of claim 7, wherein M is Pd(II).

9. The device of claim 1, wherein the phosphorescent emitter is a compound of General Formula II; 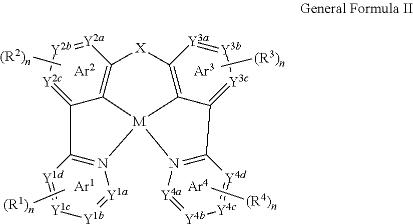
wherein, in General Formula II:
M represents Pt(II) or Pd(II);
R¹, R², R³, and R⁴ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{2c}, Y^{3a}, Y^{3b}, Y^{3c}, Y^{4a}, Y^{4b}, Y^{4c}, and Y^{4d} each independently represents C, N, or Si; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

10. The device of claim 1, wherein the phosphorescent emitter is a compound of General Formula III: 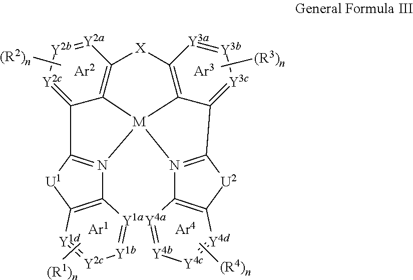
wherein, in General Formula III:
M represents Pt(II) or Pd(II);
R¹, R², R³, and R⁴ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{2c}, Y^{3a}, Y^{3b}, Y^{3c}, Y^{4a}, Y^{4b}, Y^{4c}, and Y^{4d}, each independently represents C, N, or Si;
U¹ and U² each independently represents NR, O or S, wherein R represents hydrogen, halogen, hydroxyl, nitro, nitrile, thiol, or optionally substituted C₁-C₄ alkyl, alkoxy, amino, or aryl; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

11. The device of claim 1, wherein the phosphorescent emitter is a compound of General Formula IV; 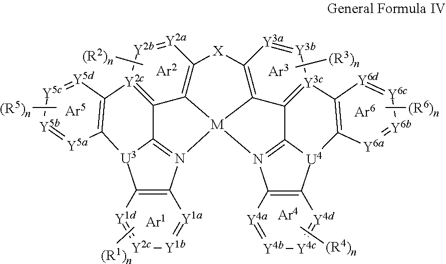
wherein, in General Formula IV:
M represents Pt(II) or Pd(II);
R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{3a}, Y^{3b}, Y^{3c}, Y^{4a}, Y^{4b}, Y^{4c}, Y^{4d}, Y^{5a}, Y^{5b}, Y^{5c}, Y^{5d}, Y^{6a}, Y^{6b}, Y^{6c}, and Y^{6d} each independently represents C, N, or Si;
Y^{2c} and Y^{3c} each independently represents C or Si;
U³ and U⁴ each independently represents N or P; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

12. The device of claim 1, wherein the phosphorescent emitter is a compound of General Formula V; 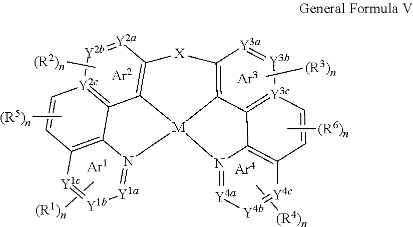
wherein, in General Formula V:
M represents Pt(II) or Pd(II);
R¹, R², R³, R⁴, R⁵, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{2a}, Y^{2b}, Y^{3a}, Y^{3b}, Y^{4a}, Y^{4b}, and Y^{4c} each independently represents C, N, or Si;
Y^{2c} and Y^{3c} each independently represents C or Si; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

13. The device of claim 1, wherein the phosphorescent emitter is a compound of General Formula VI; 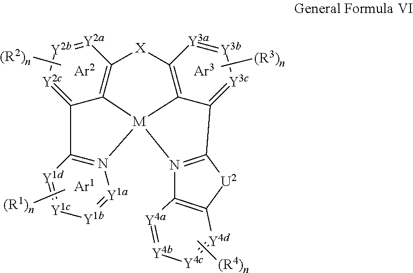
wherein, in General Formula VI:
M represents Pt(II) or Pd(II);
R¹, R², R³, and R⁴ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{2c}, Y^{3a}, Y^{3b}, Y^{3c}, Y^{4a}, Y^{4b}, Y^{4c}, and Y^{4d} each independently represents C, N, or Si;
U² represents NR, O or S, wherein R represents hydrogen, halogen, hydroxyl, nitro, nitrile, thiol, or optionally substituted C₁-C₄ alkyl, alkoxy, amino, or aryl;
U³ and U⁴ each independently represents N or P; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

14. The device of claim 1, wherein the phosphorescent emitter is a compound of General Formula VII; 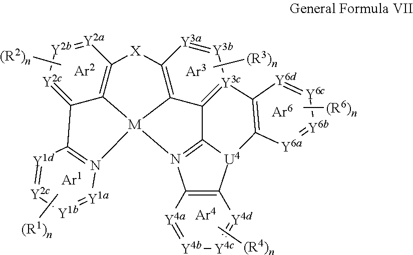
wherein, in General Formula VII:
M represents Pt(II) or Pd(II);
R¹, R², R³, R⁴, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{2c}, Y^{3a}, Y^{3b}, Y^{4a}, Y^{4b}, Y^{4c}, Y^{4d}, Y^{6a}, Y^{6b}, Y^{6c} and Y^{6d} each independently represents C, N, or Si;
Y^{3c} represents C or Si;
U⁴ represents N or P; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

15. The device of claim 1, wherein the phosphorescent emitter is a compound of General Formula VIII; 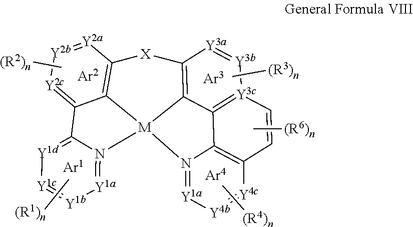
wherein, in General Formula VIII:
M represents Pt(II) or Pd(II);
R¹, R², R³, R⁴, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{2a}, Y^{2b}, Y^{2c}, Y^{3a}, Y^{3b}, Y^{4a}, Y^{4b}, Y^{4c}, and Y^{4d} each independently represents C, N, or Si;
Y^{3c} represents C or Si; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

16. The device of claim 1, wherein the phosphorescent emitter is a compound of General Formula IX; 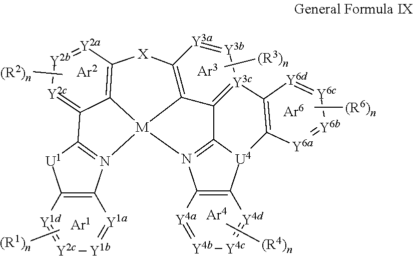
wherein, in General Formula IX:
M represents Pt(II) or Pd(II);
R¹, R², R³, R⁴, and R⁶ each independently represents hydrogen, halogen, hydroxyl, nitro, nitrile, thiol, or optionally substituted C₁-C₄ alkyl, alkoxy, amino, or aryl;
each n is independently an integer, valency permitting;
Y^{1a}, Y^{1b}, Y^{1c} Y^{1d} Y^{2a} Y^{2b}, Y^{2c}, Y^{3a}, Y^{3b}, Y^{4a}, Y^{4b}, Y^{4c}, Y^{4d}, Y^{6a}, Y^{6b}, Y^{6c}, and Y^{6d} each independently represents C, N, or Si;
Y^{3c} represents C or Si;
U¹ represents NR, O or S, wherein R represents hydrogen, halogen, hydroxyl, nitro, nitrile, thiol, or optionally substituted C₁-C₄ alkyl, alkoxy, amino, or aryl;
U⁴ represents N or P; and
X represents O, S, NR, CRR′, SiRR′, PR, BR, S═O, O=S═O, Se, Se═O, or O=Se═O, where R and R′ each independently represents hydrogen, halogen, hydroxyl, nitro, nitrile, thiol, or optionally substituted C₁-C₄ alkyl, alkoxy, amino, aryl, or heteroaryl.

17. The device of claim 1, wherein the phosphorescent emitter is represented by one of the following compounds:

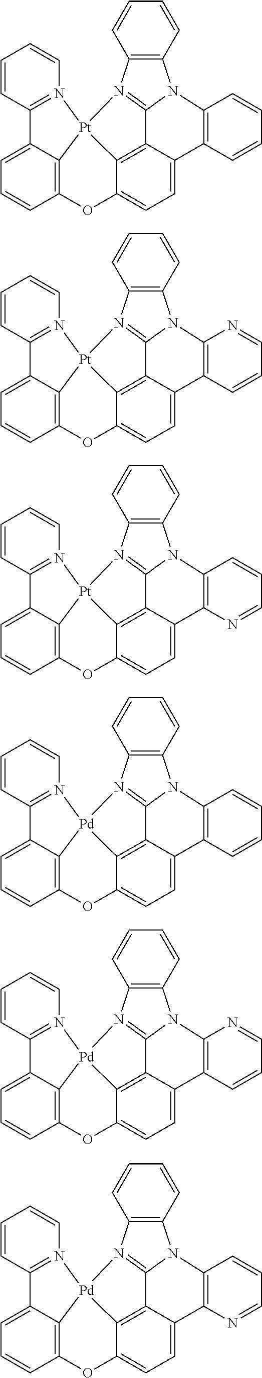

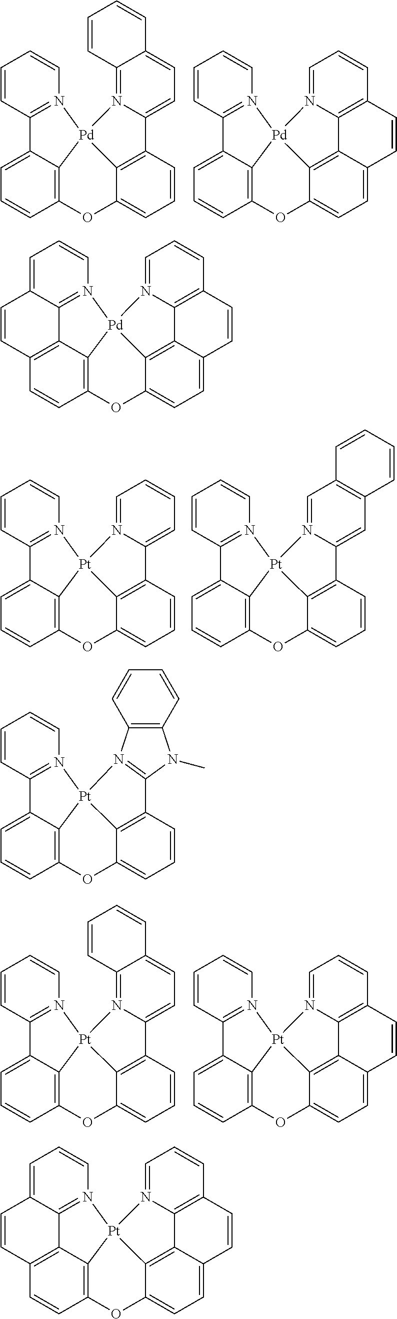

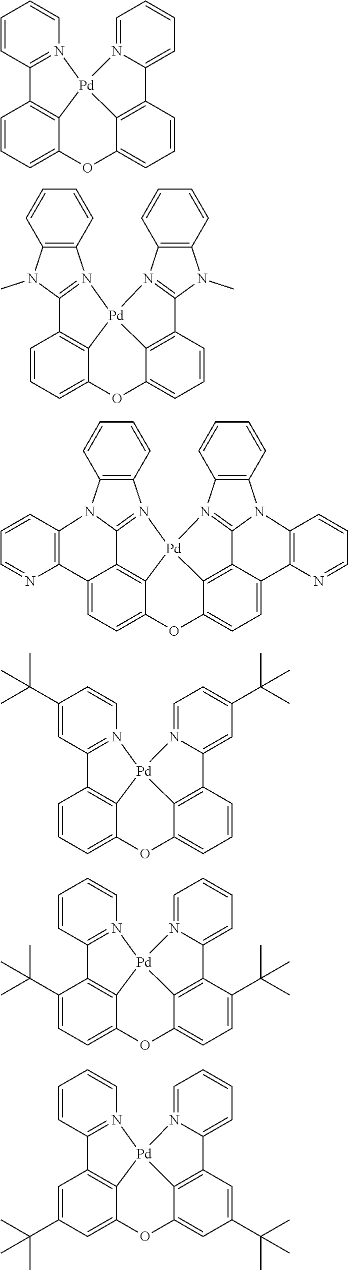

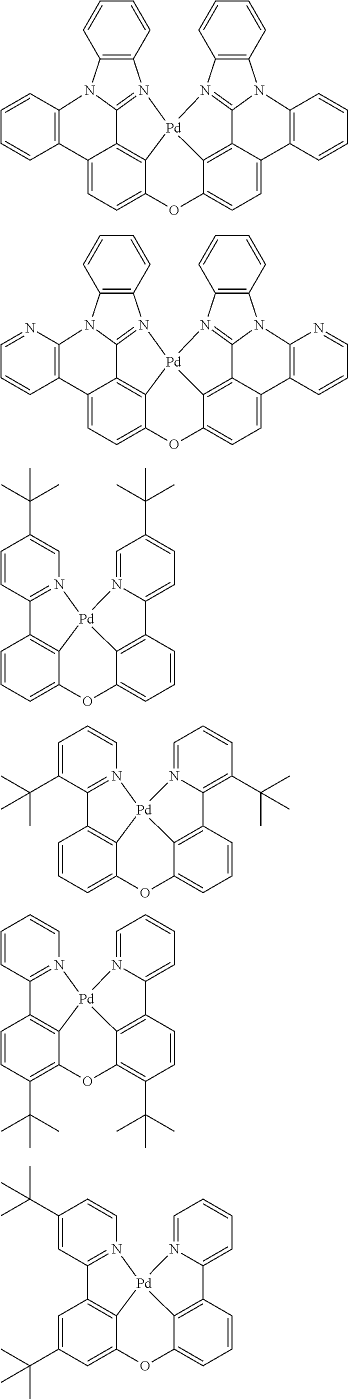

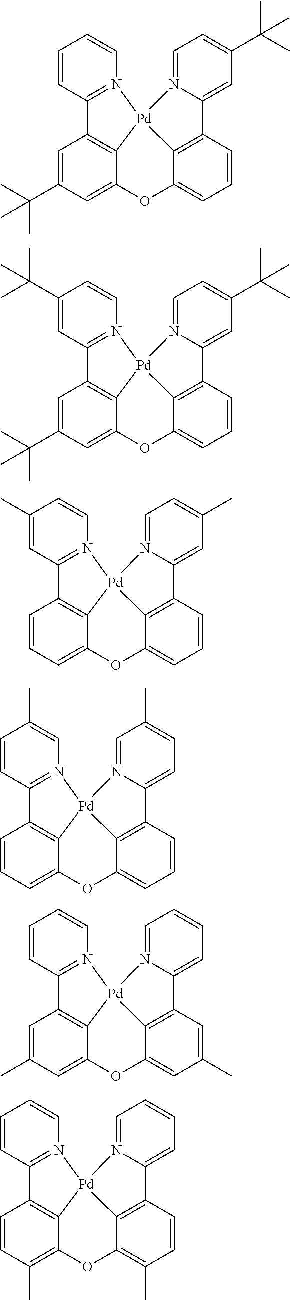

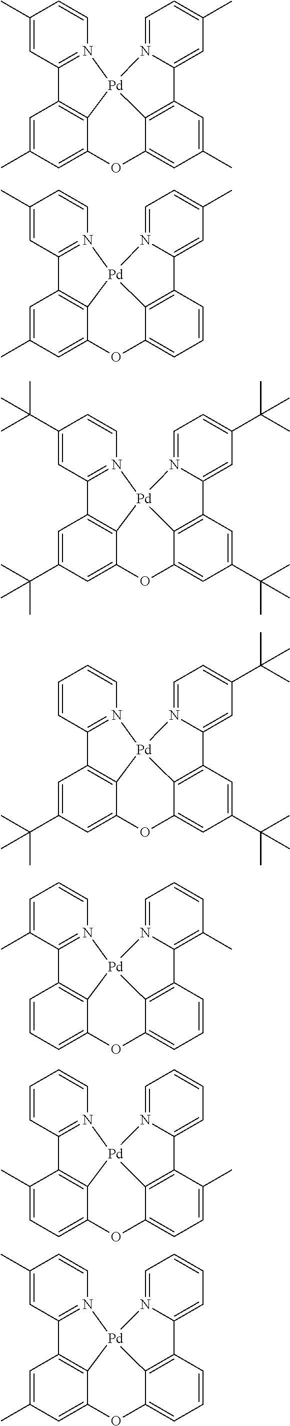

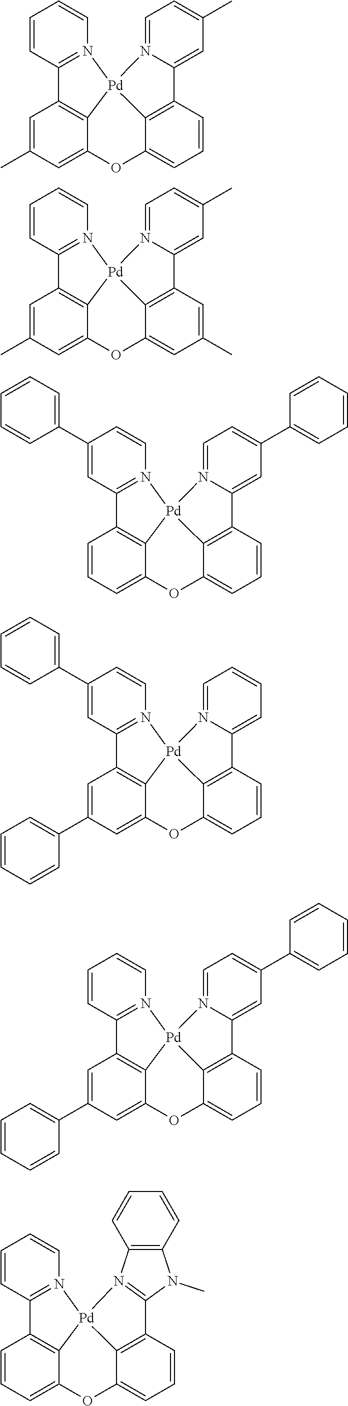

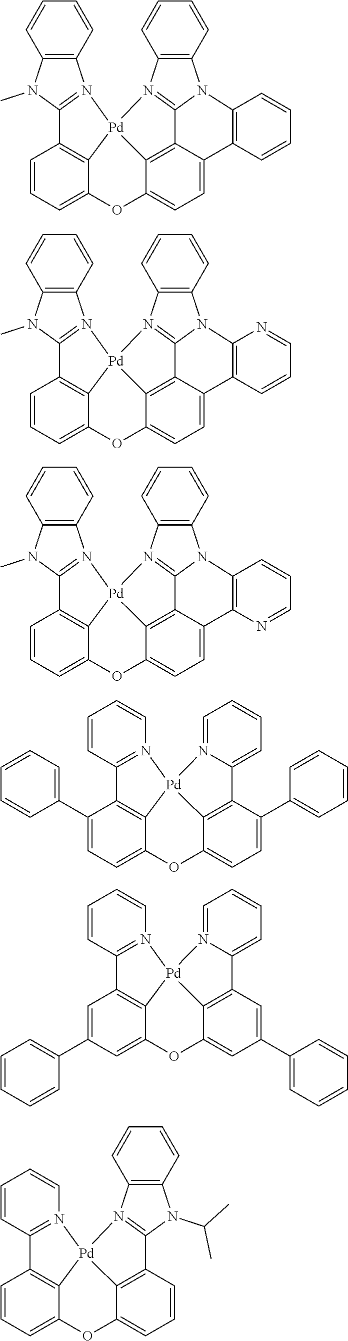

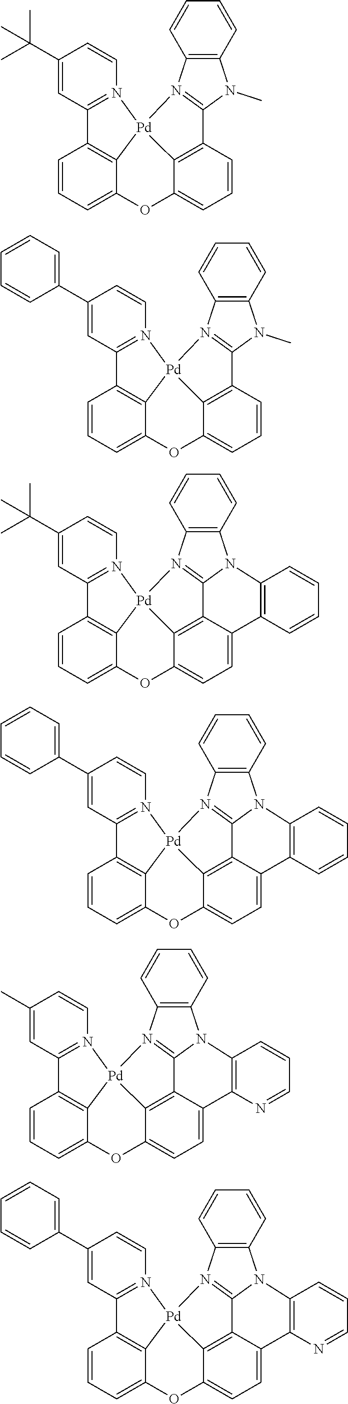

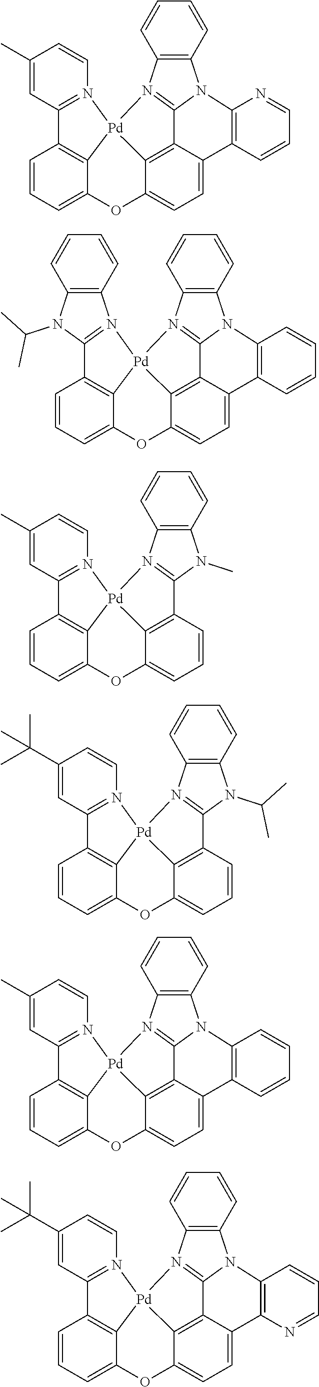

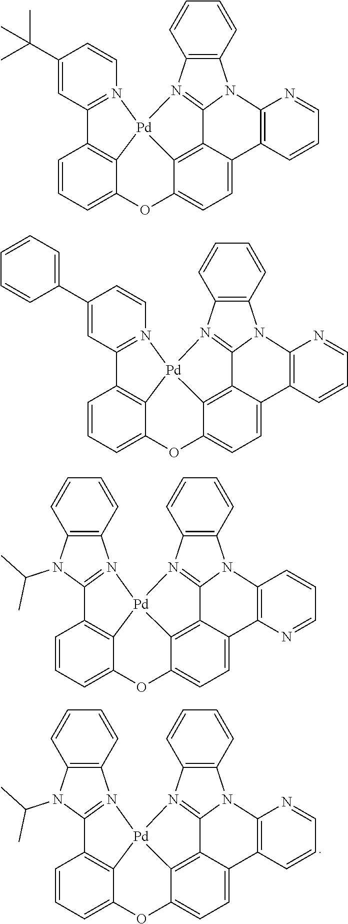

18. The device of claim 1, wherein the fluorescent emitter comprises one of the following compounds:
1. Aromatic Hydrocarbons and Their Derivatives 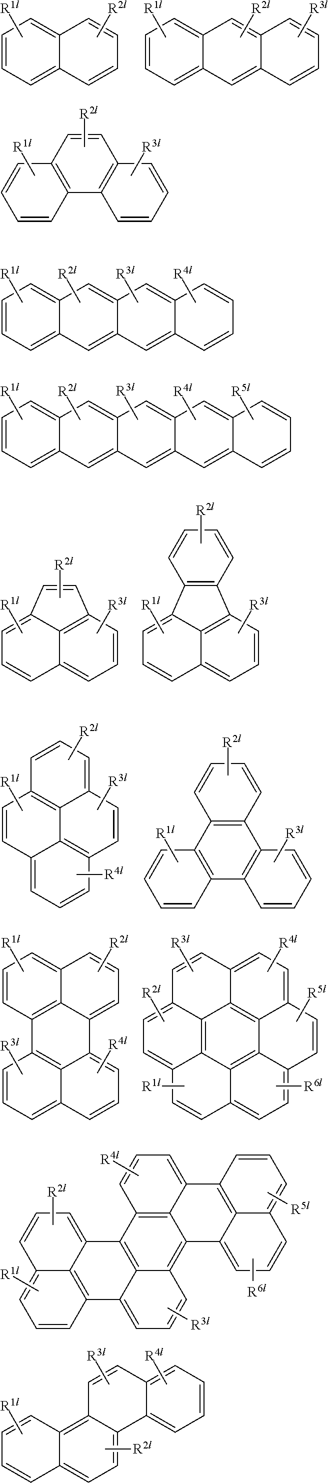 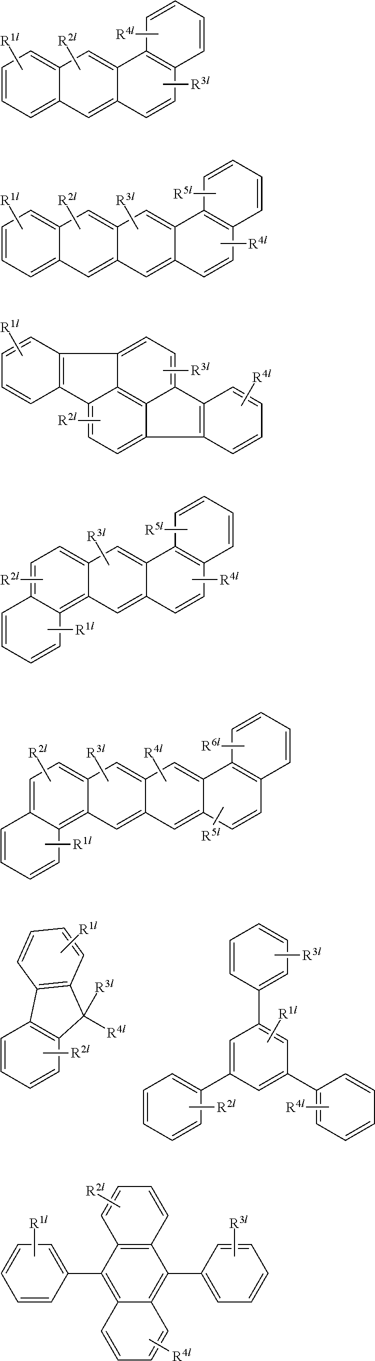 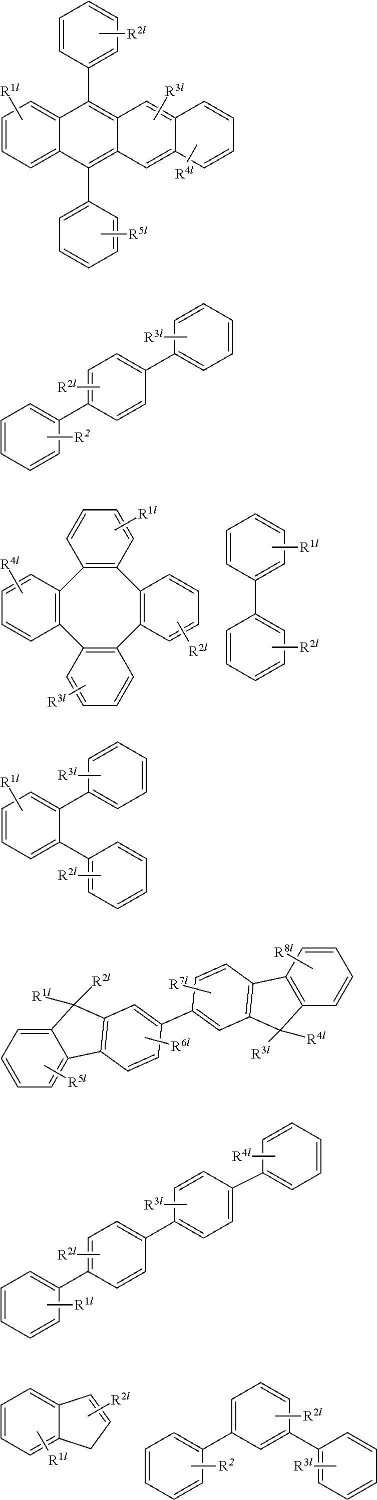 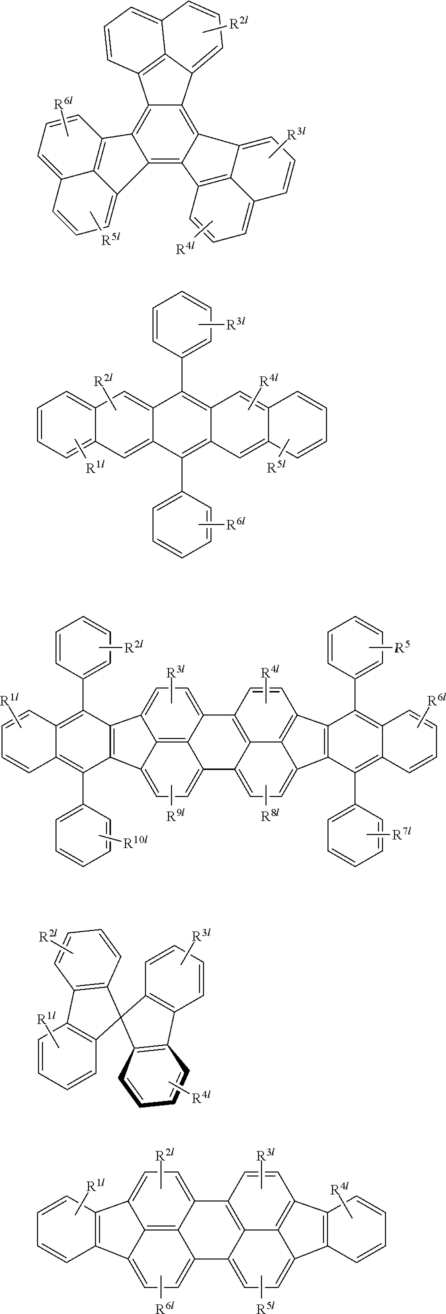 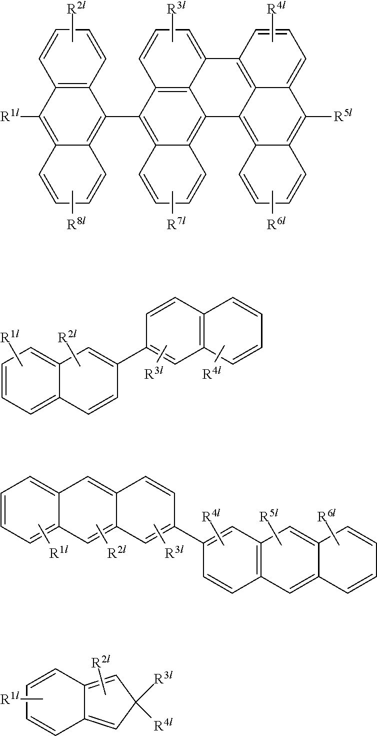
2. Arylethylene, Arylacetylene and Their Derivatives 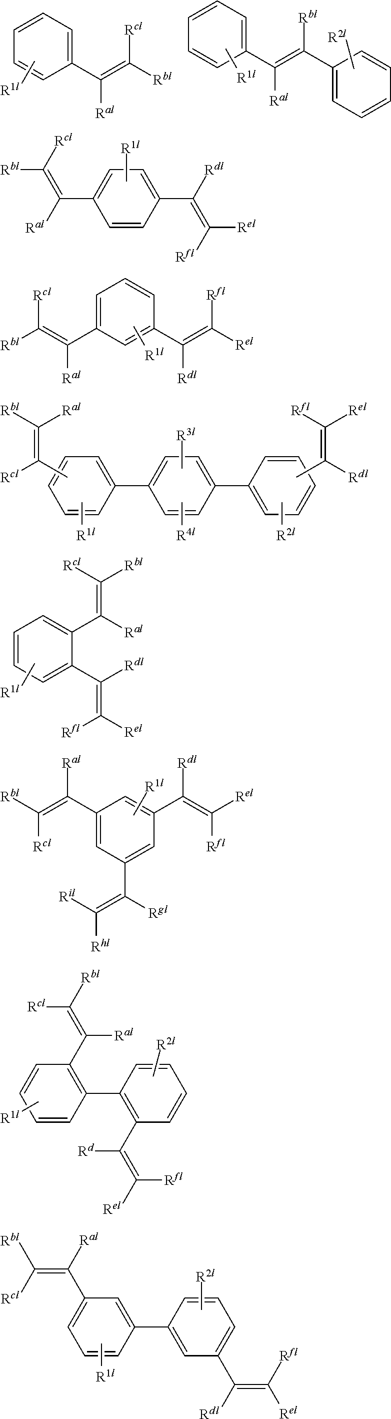 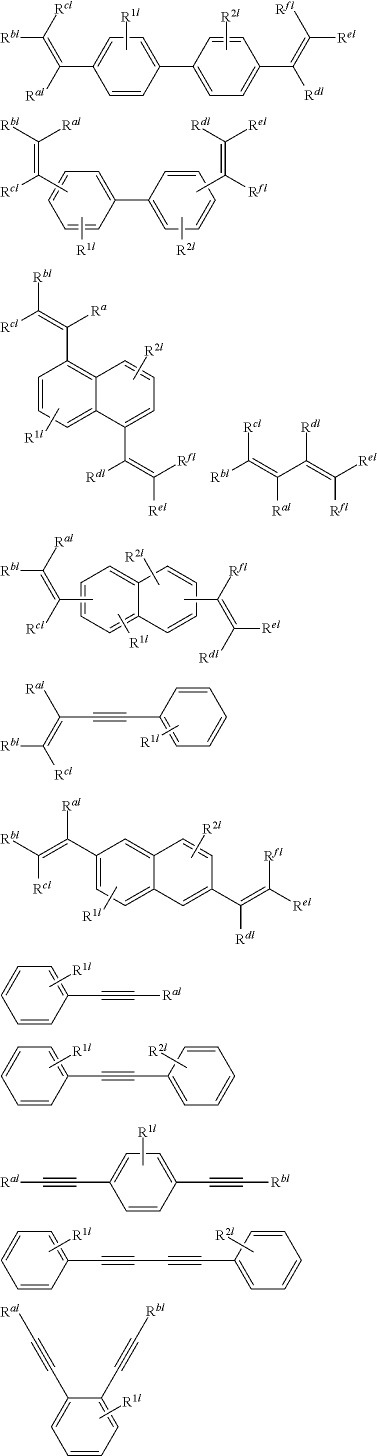 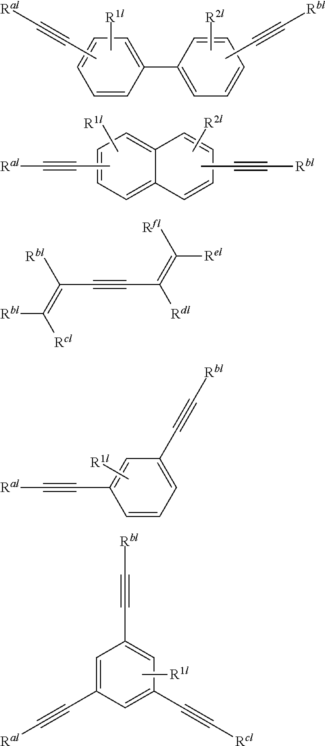
wherein R^{al}, R^{bl}, R^{cl}, R^{dl}, R^{el}, R^{fl}, R^{gl}, R^{hl} and R^{il}
can be one of the following structure: 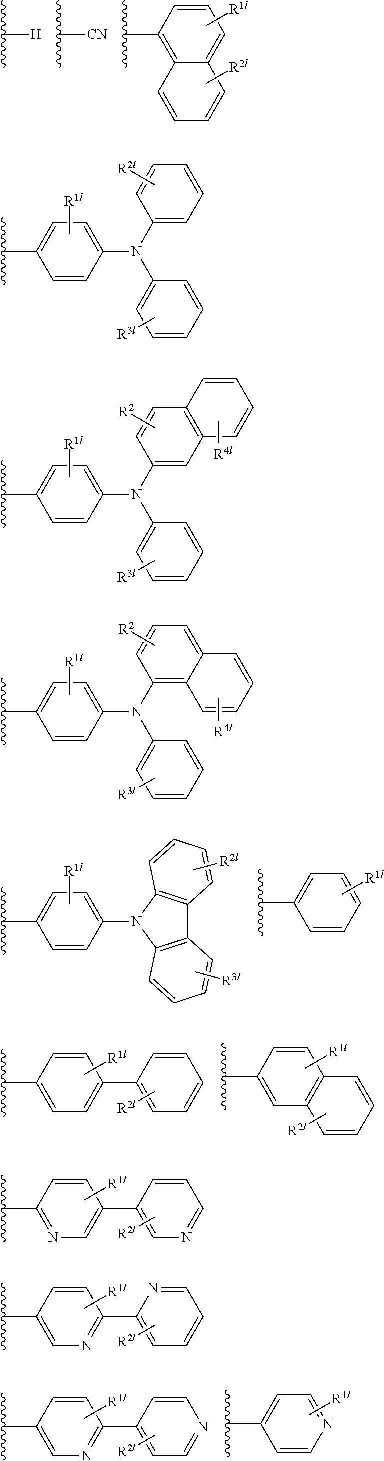 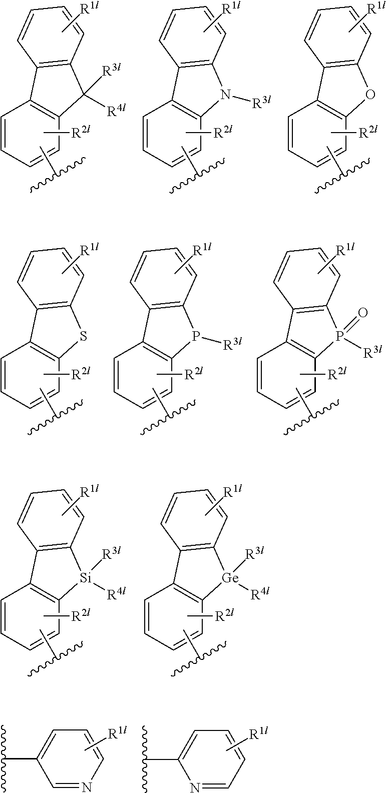
3. Heterocyclic Compounds and Their Derivatives 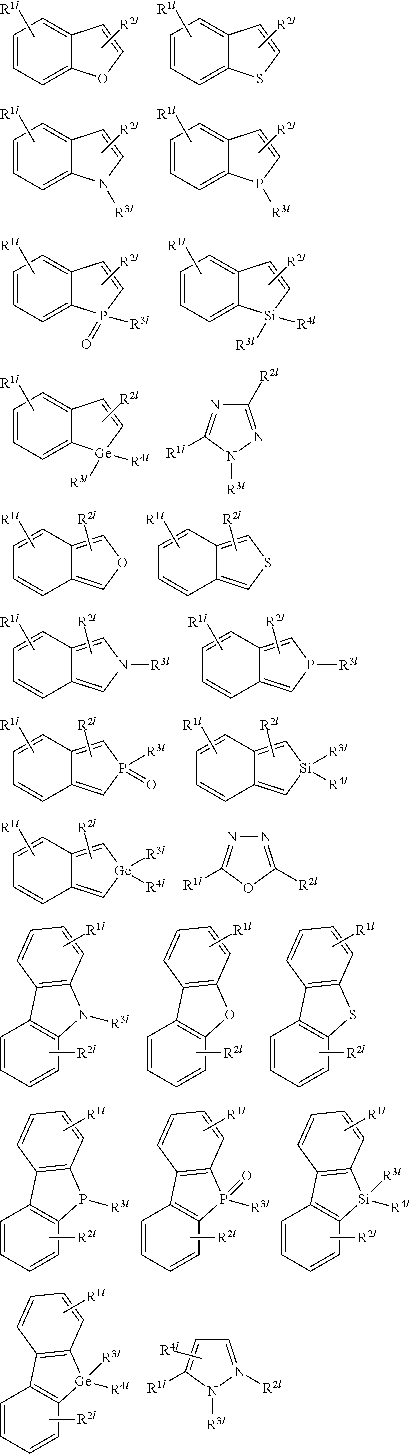 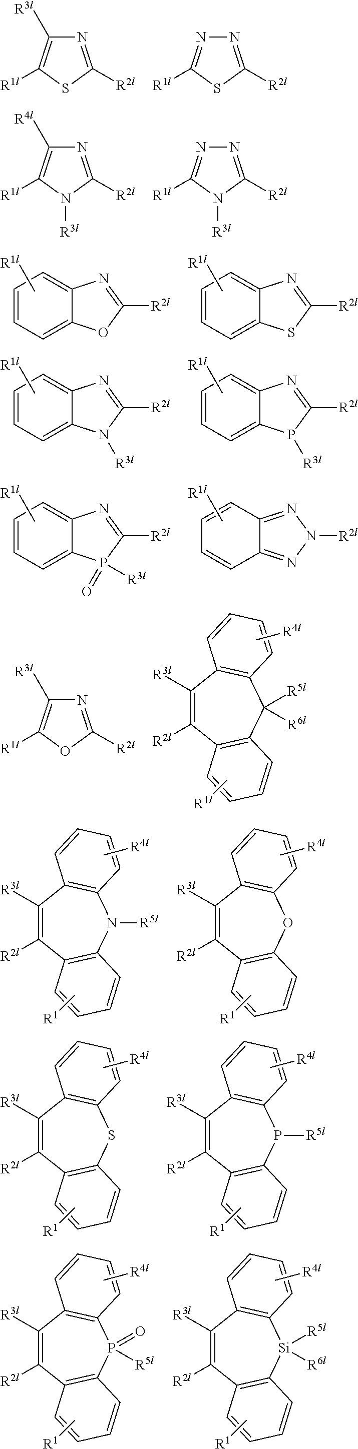 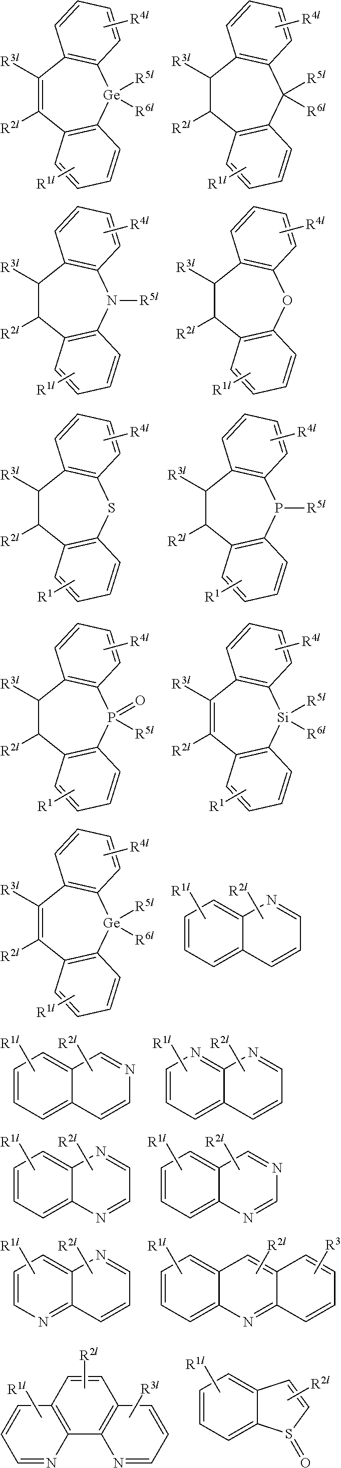 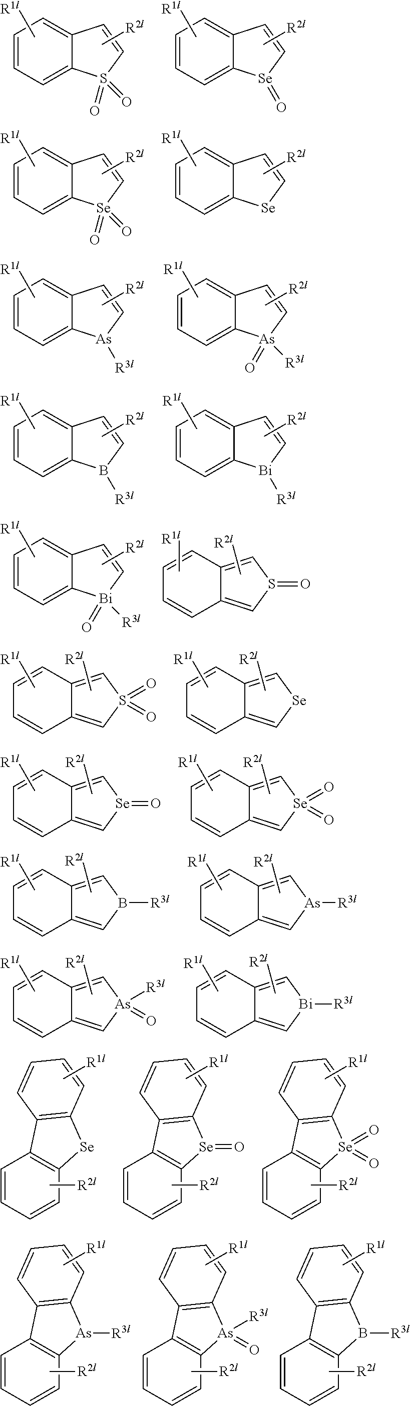 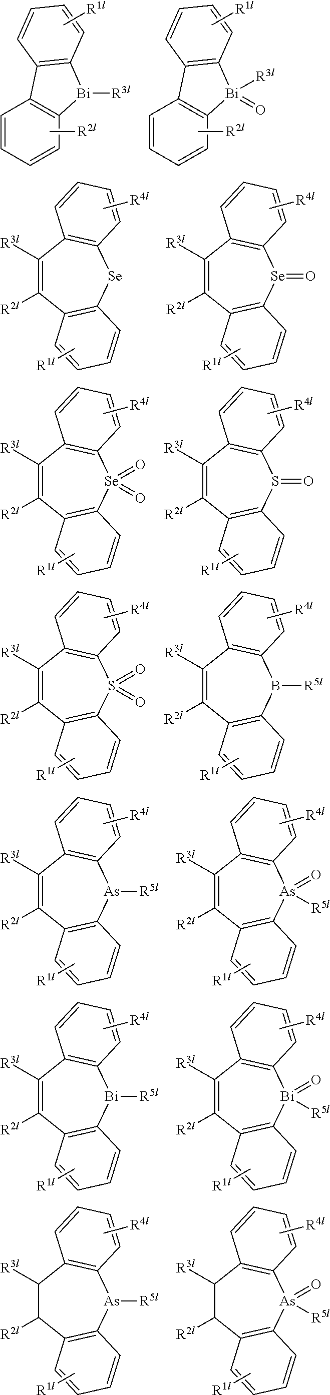 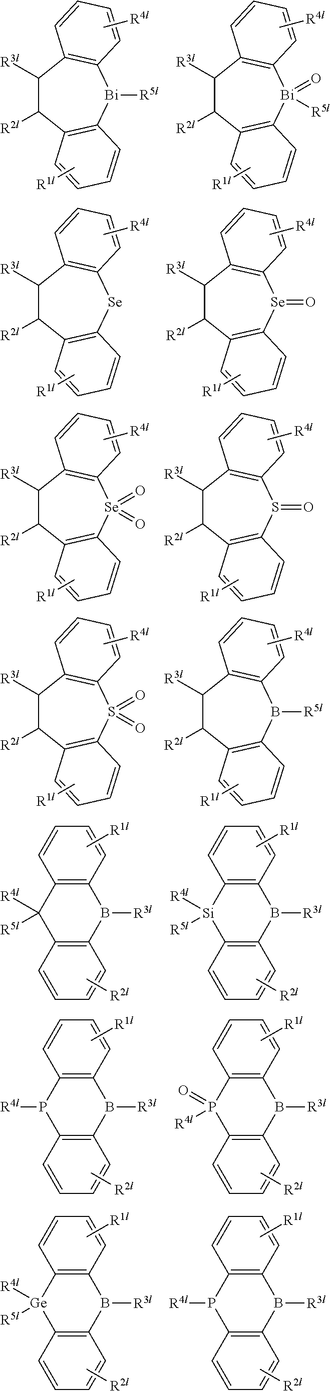 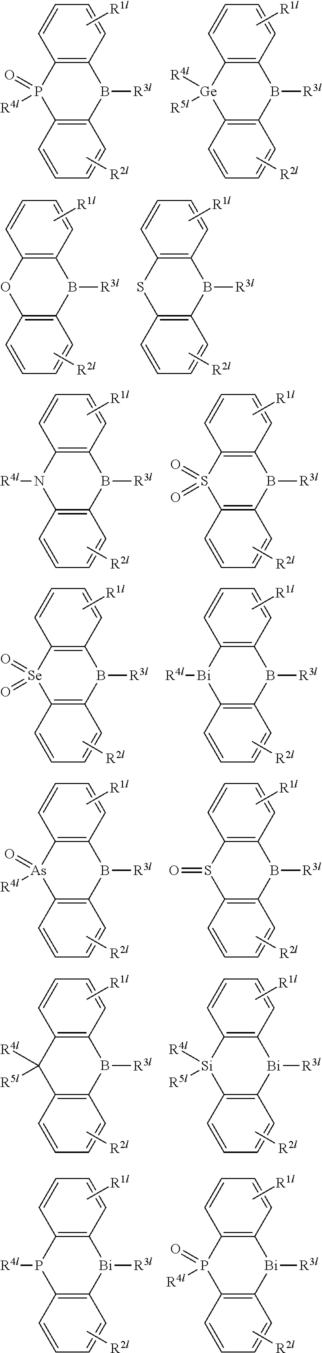 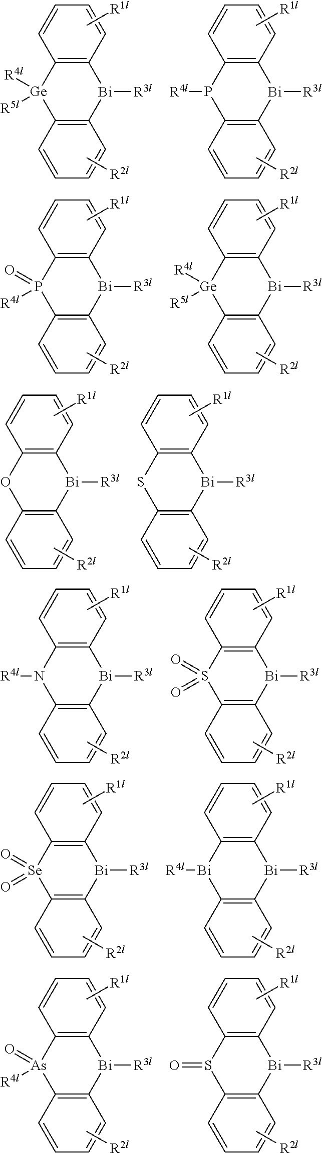 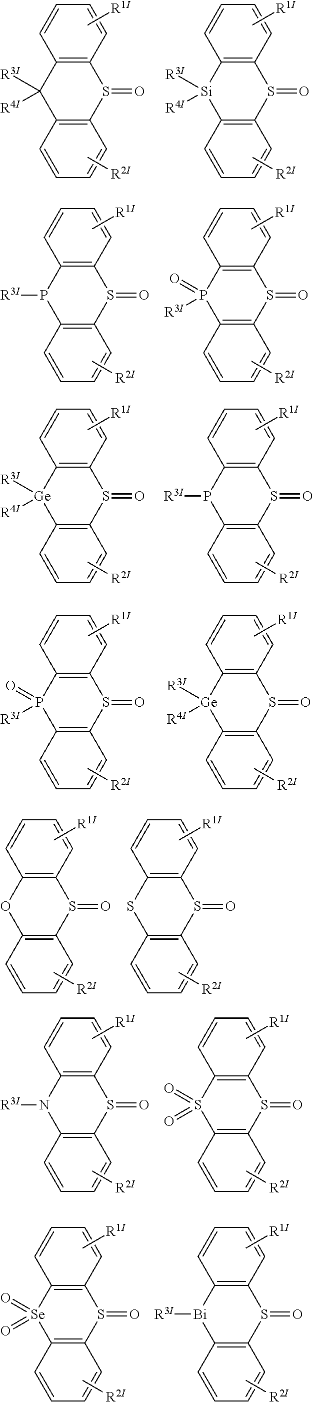 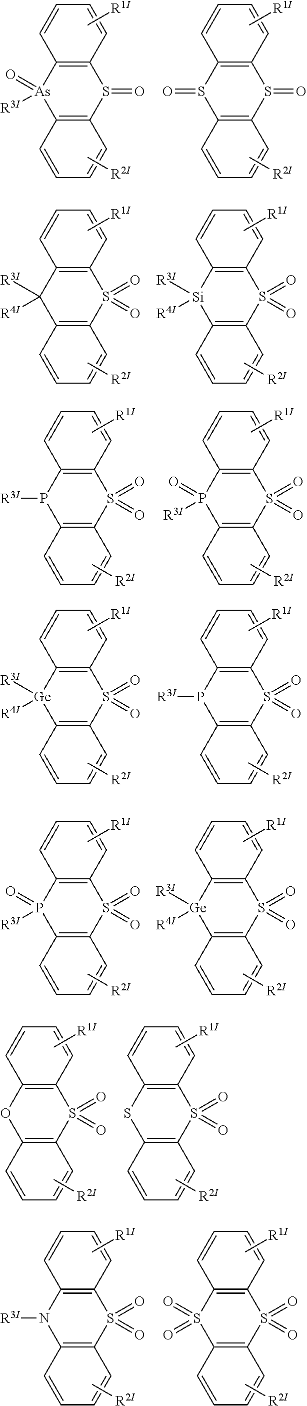 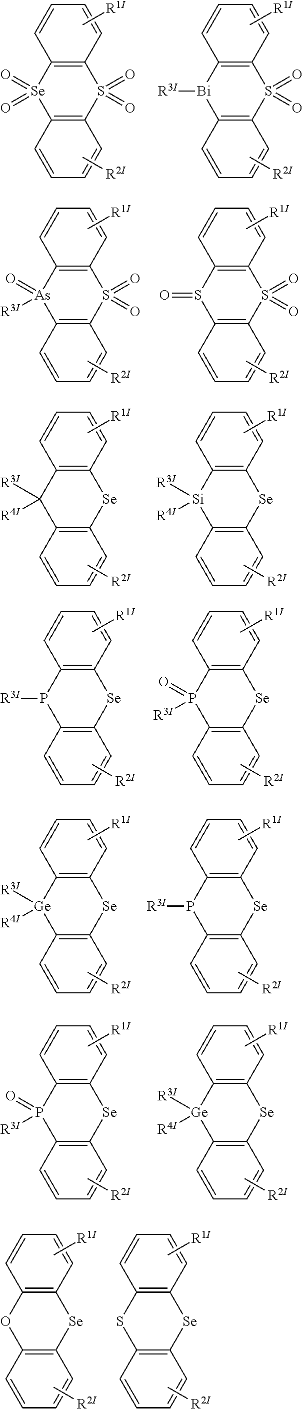 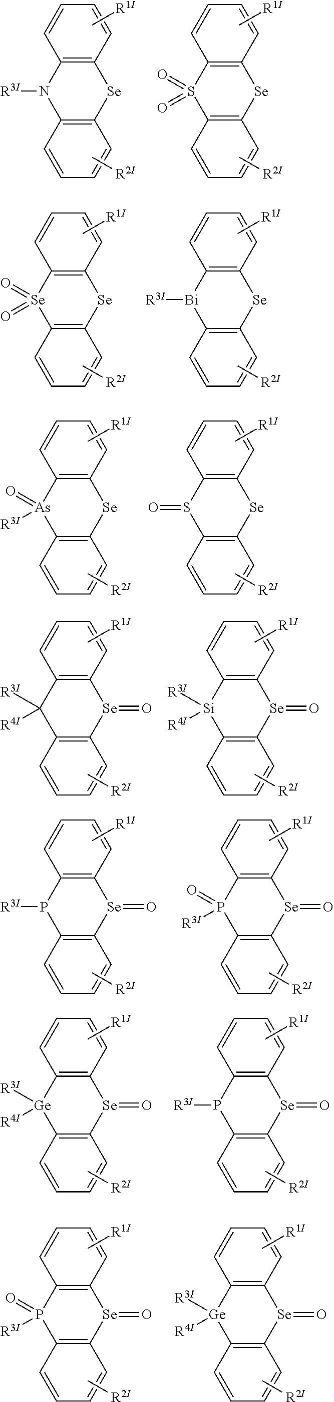 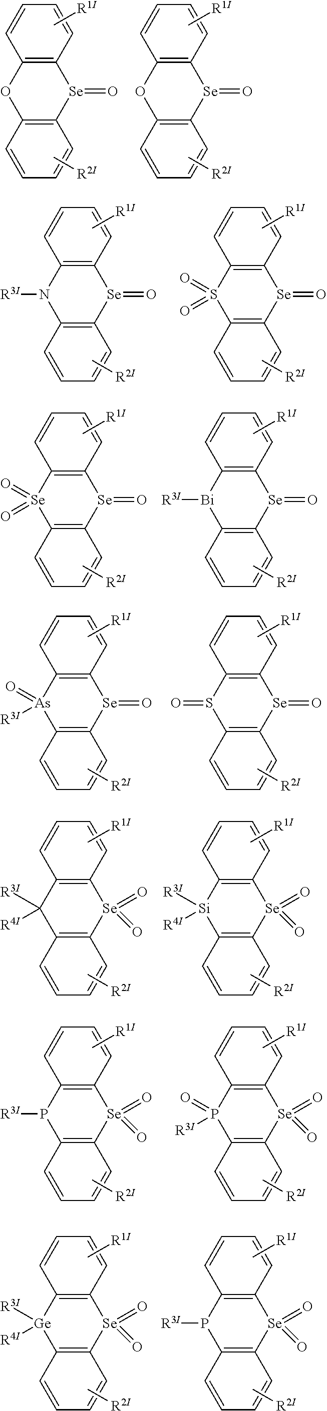 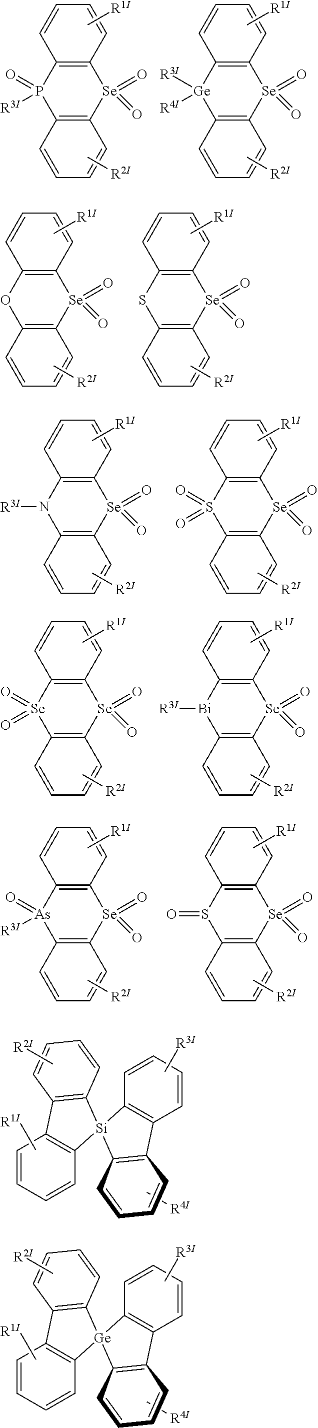 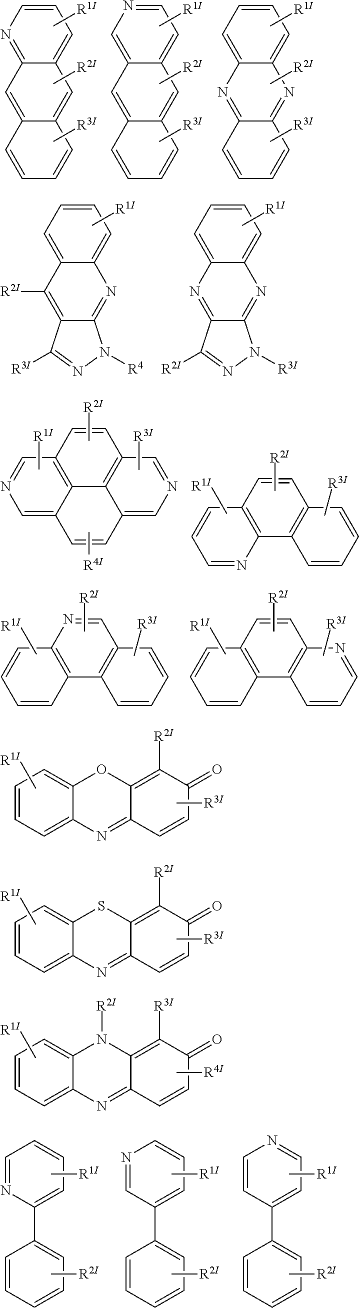 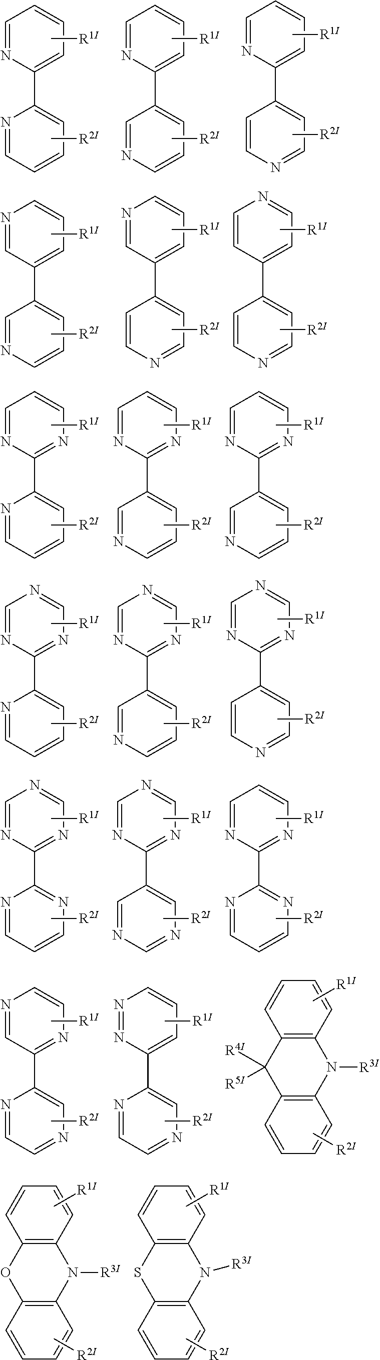 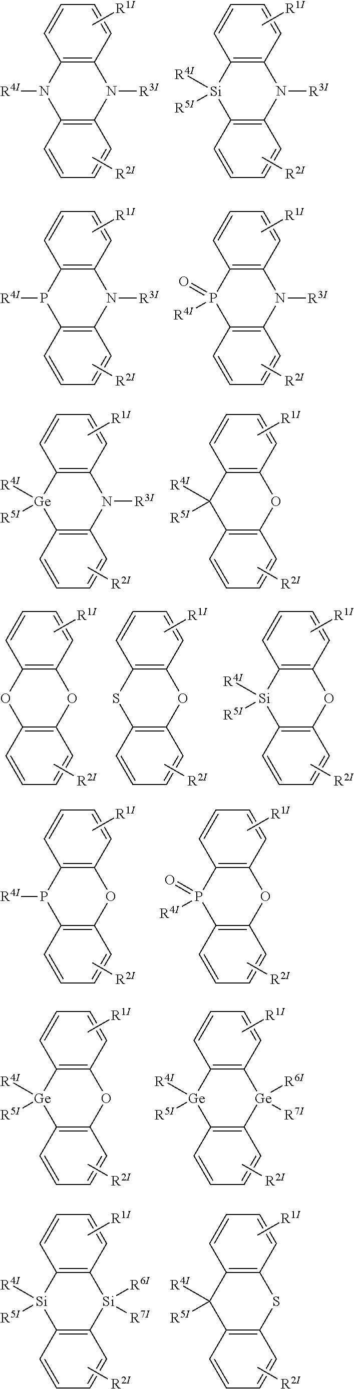 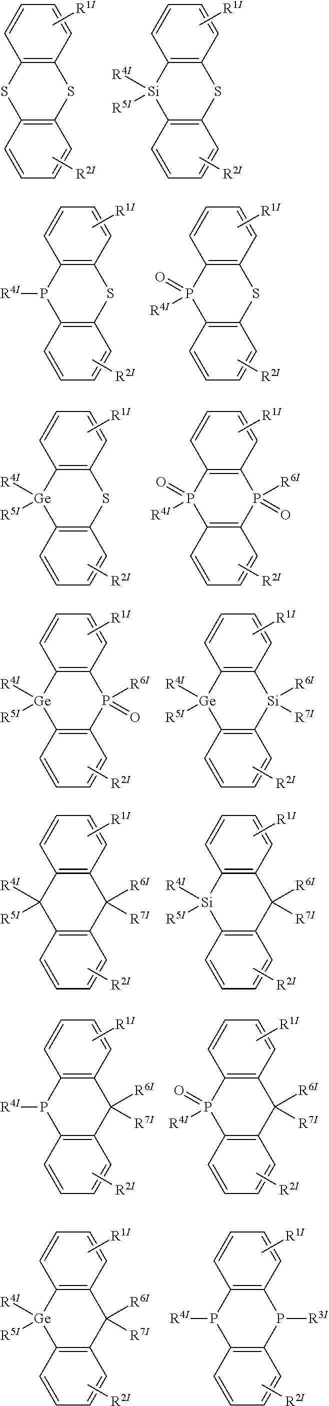 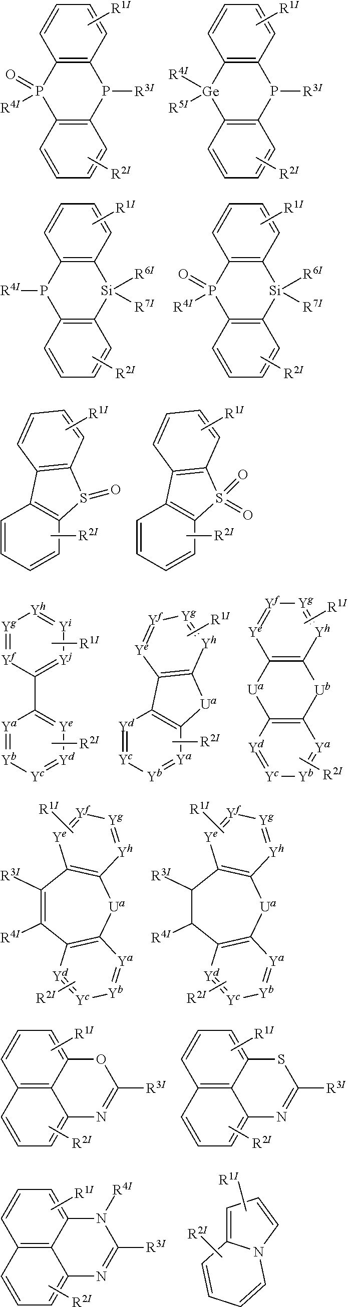 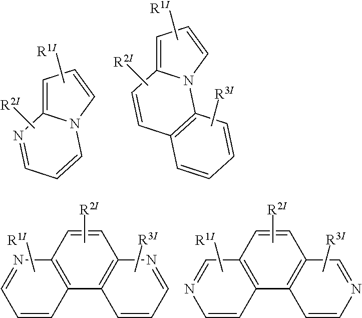
4. Other fluorescent luminophors 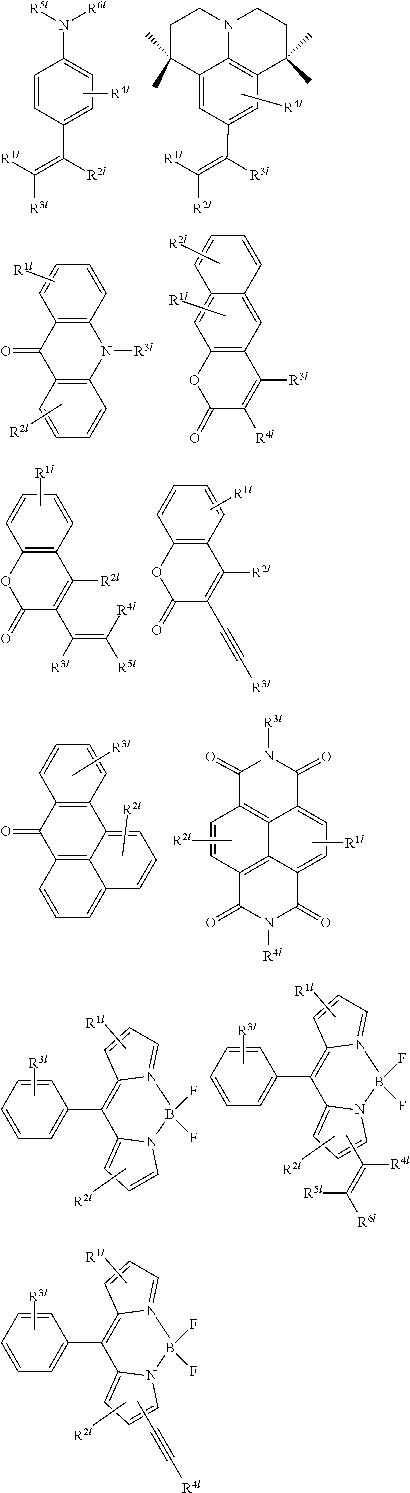 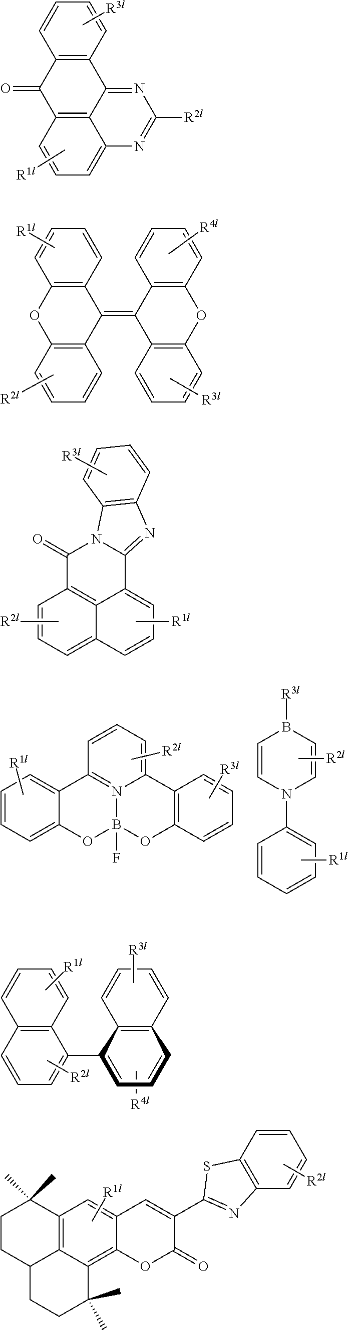 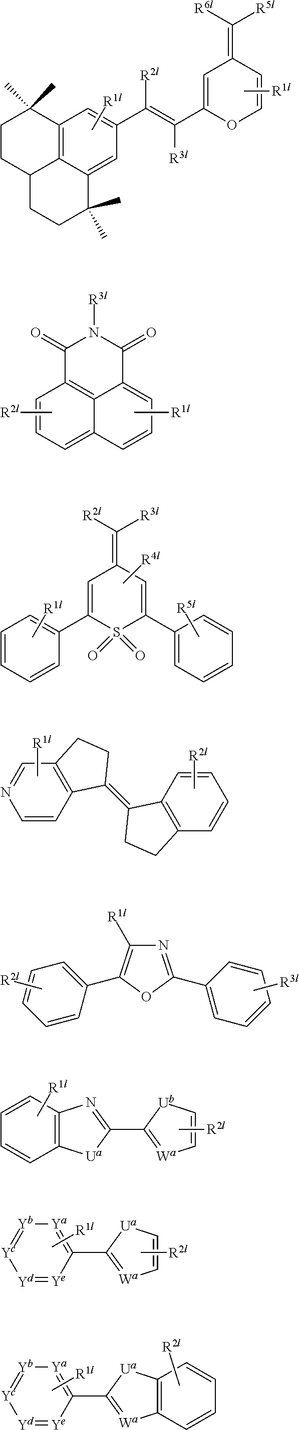 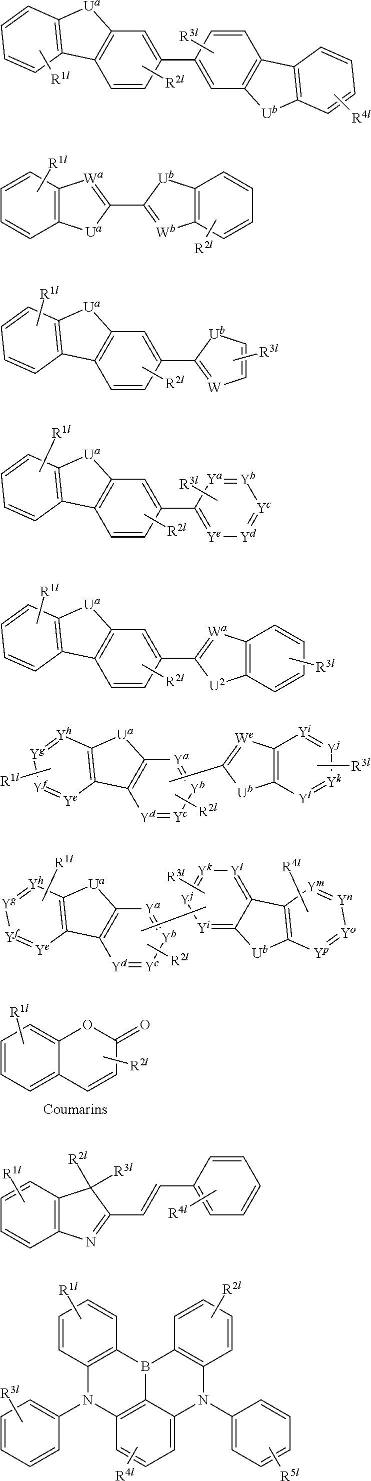
wherein each of R¹¹, R²¹, R³¹, R⁴¹, R⁵¹, R⁶¹, R⁷¹ and R⁸¹ independently are hydrogen, aryl, cycloalkyl, cycloalkenyl, heterocyclyl, heteroaryl, alkyl, alkenyl, alkynyl, deuterium, halogen, hydroxyl, thiol, nitro, cyano, amino, a mono- or di-alkylamino, a mono- or diarylamino, alkoxy, aryloxy, haloalkyl, aralkyl, ester, nitrile, isonitrile, heteroaryl, alkoxycarbonyl, acylamino, alkoxycarbonylamino, aryloxycarbonylamino, sulfonylamino, sulfamoyl, carbamoyl, alkylthio, sulfinyl, ureido, phosphoramide, mercapto, sulfo, carboxyl, hydrzino, substituted silyl, polymeric, or any conjugate or combination thereof;
wherein each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o} and Y^{p} independently are C, N or B;
wherein each of U^{a}, U^{b} and U^{c} independently represent CH₂, CR¹R², C═O, CH₂, SiR¹R², GeH₂, GeR³R², NH, NR³, PH, PR³, R³P═O, AsR³, R³As═O, O, S, S═O, SO₂, Se, Se═O, SeO₂, BH, BR³, R³Bi═O, BiH, or BiR³;
wherein each R¹, R², and R³ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoaryl amino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof.

19. The device of claim 1, wherein the fluorescent emitter is selected from the group consisting of TBPe, t-DABNA, FLB2, BH, and BH2

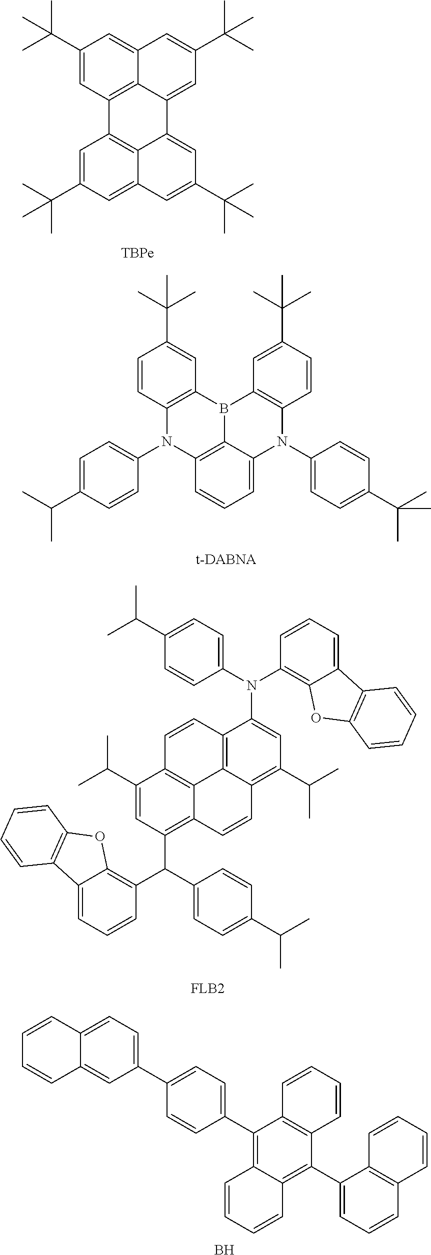

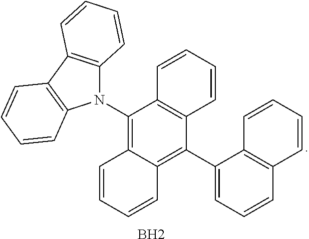

20. A consumer product comprising the device of claim 1.
